(19) United States
(12) Patent Application Publication
(10) Pub. No.: US 2026/0289030 A1
(43) Pub. Date: Sep. 24, 2026

(54) AUTOMATED WATER CLOSET COMPLIANCE ANALYSIS WITH INTERACTIVE USER FEEDBACK

(71) Applicant: CodeComply.Ai, Corp., Miami, FL (US)

(72) Inventors: Michael Sheehan, Coral Gables, FL (US); Matthew Foley, Boxborough, MA (US); Patrick E Murphy, Miami, FL (US); Johnny Maghzal, Miami, FL (US)

(73) Assignee: CodeComply.Ai, Corp., Miami, FL (US)

(21) Appl. No.: 19/480,024

(22) PCT Filed: Aug. 30, 2024
(86) PCT No.: PCT/US24/44858

§ 371 Date: Oct. 29, 2025

Related U.S. Application Data
(60) Provisional application No. 63/535,700, filed on Aug. 31, 2023.

(51) Int. Cl. G06F 30/13; G06F 30/27; G06Q 30/018; G06Q 50/08

(52) U.S. Cl. CPC G06F 30/13; G06F 30/27; G06Q 30/018; G06Q 50/08

(57) ABSTRACT

Methods and apparatus operative for analyzing water closet compliance with relevant building codes using artificial intelligence (AI). The system involves receiving design plans and representing them as dynamic components, which include various fixtures and architectural elements. Each dynamic component may include a parameter that is changeable via an interactive user interface. An AI engine identifies water closet areas, ascertains design parameters, and compares them against a set of compliance conditions. The AI engine can simulate various scenarios, such as wheelchair accessibility, and evaluate multiple design parameters like height, distance, size, and placement of fixtures. The interactive user interface allows users to view compliance status and receive automated suggestions for non-compliant features. The AI determines clearances within a water closet and assesses compliance with codes such as the Americans with Disabilities Act. Additionally, the AI provides recommendations to correct any code violations identified.

### CROSS REFERENCE TO RELATED APPLICATIONS

This application is a National Phase of International Application Number PCT/US24/44858, filed Aug. 30, 2024, and entitled AUTOMATED WATER CLOSET COMPLIANCE ANALYSIS WITH INTERACTIVE USER FEEDBACK, which claims the benefit of U.S. Provisional Application No. 63/535,700, filed on Aug. 31, 2023, and entitled ARTIFICIAL INTELLIGENCE DETERMINATION OF WATER CLOSET METRICS FOR CODE COMPLIANCE WITH USER INTERACTION, the entire disclosures of each of which are incorporated herein by reference.

### FIELD OF THE INVENTION

The present invention relates to methods and systems for analyzing architectural design plans for compliance with relevant building codes, particularly in relation to the design and layout of water closet areas, bathrooms, and associated fixtures. Specifically, the invention leverages artificial intelligence (AI) and machine learning techniques to assess that design plans meet required standards for accessibility, safety, and functionality. This includes evaluating design parameters such as fixture placement, spacing, heights, and overall spatial configuration within water closets, public restrooms, and other sanitary facilities. The invention is particularly applicable to determining compliance with regulations related to accessibility for individuals with disabilities, optimizing spatial design for user comfort and safety, and providing automated suggestions for correcting non-compliant elements within a design.

### BACKGROUND OF THE INVENTION

Building design and architecture are fundamental to the creation of safe, functional, and accessible environments where people live, work, and interact. These designs must be meticulously planned and executed to meet the diverse needs of occupants while complying with a wide range of regulatory standards and codes. Compliance with these codes is essential for ensuring that buildings are safe, accessible, and functional for all individuals, including those with disabilities. Among the many aspects of building design that require careful attention to compliance, water closets stand out as particularly important. Ensuring that water closets meet the necessary standards is required for creating spaces that are accessible to all, regardless of physical ability.

Building codes and standards serve as a framework for ensuring that buildings are constructed to meet specific criteria for safety, accessibility, and usability. These codes are developed by various government and regulatory bodies to protect the health, safety, and welfare of the public. In the United States, building codes are extensive and multifaceted, addressing a wide range of elements, from structural integrity and fire safety to electrical systems and plumbing. However, one of the most critical areas of compliance is related to accessibility, particularly in the design and placement of water closets. Water closet compliance is essential to ensure that buildings can be used by individuals with varying levels of mobility, including those who rely on wheelchairs or other assistive devices.

The need for compliance in building design extends beyond the borders of the United States. Internationally, various codes and standards exist to ensure that buildings are accessible and safe for all users. In the U.S., some of the most relevant codes include the Americans with Disabilities Act (ADA) and the American National Standards Institute (ANSI) standards. The ADA, enacted in 1990, is a comprehensive civil rights law that prohibits discrimination against individuals with disabilities in all areas of public life, including jobs, schools, transportation, and all public and private places open to the general public. The ADA sets forth specific requirements for the design and construction of accessible spaces, including water closets, to ensure that individuals with disabilities can access and use these facilities with ease and dignity.

ANSI, on the other hand, provides detailed technical standards for accessible design, ensuring that architectural features such as doorways, ramps, and restrooms are usable by individuals with disabilities. ANSI standards are widely recognized and used in conjunction with the ADA to guide the design and construction of accessible spaces. These standards outline specific requirements for the size, placement, and features of water closets to ensure that they are accessible to all users. Compliance with these standards is essential for creating spaces that are inclusive and functional for everyone, regardless of their physical abilities.

Water closet compliance is particularly important in the context of these codes. The design and placement of water closets must meet specific criteria to ensure that they are accessible to all individuals, including those with disabilities. This involves careful consideration of various factors, such as the height of the toilet seat, the placement of grab bars, the width of the doorway, and the amount of space available for maneuvering a wheelchair. These details are required for ensuring that individuals with disabilities can use the facilities independently and with dignity. Failure to meet these standards can result in significant challenges for individuals with disabilities, limiting their ability to use the facilities and participate fully in public life.

Achieving water closet compliance presents a significant challenge due to the complexity of the codes themselves. The ADA and ANSI standards are detailed and specific, necessitating a deep understanding of both the technical requirements and the practical implications of design. Architects and designers must ensure that their floor plans meet these standards while also being functional and aesthetically pleasing. This is particularly challenging in buildings with limited space or unique design requirements. Balancing compliance with other design considerations, such as user comfort, privacy, and overall aesthetics, demands a thoughtful and informed approach.

Another challenge lies in addressing the diverse needs of different user groups. Water closets must be designed to accommodate a broad spectrum of individuals, including those with mobility impairments, sensory impairments, and other disabilities. This requires careful attention to the specific needs of these individuals and an understanding of how different design elements can affect their ability to use facilities. For example, the height of the toilet seat and the placement of grab bars are required factors in ensuring that individuals with mobility impairments can use the facilities safely and independently. Similarly, appropriate lighting and signage are essential for individuals with sensory impairments to navigate the space effectively.

The importance of water closet compliance is further underscored by the potential legal and financial consequences of non-compliance. Buildings that do not meet the required standards can face significant penalties, including fines, lawsuits, and the cost of retrofitting non-compliant spaces. In some cases, non-compliance can also lead to delays in project approval, or the revocation of occupancy permits, resulting in further financial losses. Therefore, it is in the best interest of architects, designers, and building owners to ensure that their floor plans meet all relevant compliance standards from the outset.

The design and construction of water closets that comply with accessibility standards is not just a matter of meeting legal requirements; it is also a matter of social responsibility. Creating spaces that are accessible to all individuals, regardless of their physical abilities, is essential for promoting inclusivity and equality. By ensuring that water closets are accessible, architects and designers can contribute to the creation of spaces that are welcoming and usable for everyone. This is particularly important in public buildings, where the ability to access and use the facilities is essential for participation in public life.

Practical considerations also play a role in the design of accessible water closets. Designing facilities that are both accessible and functional requires careful attention to the specific needs of users and an understanding of how different design elements can impact usability. For example, the placement of grab bars and the height of the toilet seat are critical in ensuring that individuals with mobility impairments can use the facilities safely. Additionally, the width of the doorway and the amount of space available for maneuvering a wheelchair are important considerations in ensuring that the facilities are accessible to all users.

Integrating water closets that comply with accessibility standards into the broader architectural context requires careful planning. These facilities must be seamlessly incorporated into the overall design of the building, balancing functionality, aesthetics, and compliance with relevant standards. Collaboration among architects, designers, and accessibility consultants is required to ensure that the design meets all requirements while achieving the desired aesthetic and functional goals.

Achieving water closet compliance also necessitates ongoing education and training for architects and designers. Staying current with the latest standards and best practices for accessible design, as well as the latest developments in building codes and regulations, is essential. Continuous learning and professional development are key to ensuring that designs remain compliant and contribute to the creation of accessible and inclusive spaces.

The complexity of the codes and standards presents a significant challenge for architects and engineers. The ADA and ANSI standards are detailed, specifying exact measurements and placements for various elements within a restroom. Keeping up to date with these standards can be challenging, as codes are periodically updated to reflect new insights, technologies, and societal expectations. For professionals in the field, this requires a commitment to continuous learning and staying informed about the latest changes and best practices.

The vast amount of information that architects and engineers must manage during the design process increases the likelihood of errors. Human error is an inherent risk in any manual process, and in the context of code compliance, this can lead to oversights or misinterpretations. Even experienced professionals may overlook a detail or make a mistake, resulting in a design that does not fully comply with the relevant standards. Such errors can lead to significant consequences, including costly retrofits, legal liabilities, and delays in project completion.

The increasing complexity of modern building designs adds to the challenge of ensuring compliance. In large or intricately designed buildings, architects and engineers must balance aesthetic goals, functional requirements, and regulatory compliance. In such cases, the detailed requirements of accessibility standards may unintentionally be overlooked or inadequately addressed, particularly when the focus is on creating innovative or visually appealing spaces.

Moreover, the diverse needs of different user groups add another layer of complexity to the design process. Architects and engineers must consider the specific requirements of individuals with various disabilities, such as mobility impairments, sensory impairments, or cognitive disabilities. This necessitates a deep understanding of how different design elements can impact usability and accessibility. For instance, the placement of grab bars, the height of toilet seats, and the spatial layout of the restroom must be carefully planned to accommodate users with diverse needs.

The importance of water closet compliance is further highlighted by the growing emphasis on universal design. Universal design is an approach to design that seeks to create spaces that are usable by all people, to the greatest extent possible, without the need for adaptation or specialized design. This approach is particularly relevant in the context of water closets, where the goal is to create facilities that are accessible to everyone, regardless of their physical abilities. By embracing the principles of universal design, architects and designers can create spaces that are not only compliant with accessibility standards but also functional and usable for all individuals.

Given these challenges, there is a growing recognition of the need for more reliable and efficient methods of ensuring code compliance. Traditional manual review processes, which involve architects and engineers painstakingly checking floor plans against code requirements, are not only time-consuming but also prone to errors. The increasing complexity of codes and the demand for high levels of precision make it difficult for human professionals to manage compliance without assistance.

In addition to the challenges of achieving water closet compliance, there are also opportunities for innovation in this area. Advances in technology, particularly in the field of building information modeling (BIM) and artificial intelligence (AI), offer new possibilities for improving the design and construction of accessible spaces. These technologies can be used to automate the compliance checking process, identify potential issues early in the design process, and provide valuable insights and recommendations for improving accessibility. By leveraging these technologies, architects and designers can create more efficient and effective design processes, where compliance is seamlessly integrated into the overall design workflow.

### SUMMARY OF THE DISCLOSURE

Accordingly, the present disclosure provides methods and apparatus for analyzing water closet compliance with relevant building codes through the use of artificial intelligence (AI) and dynamic design plan analysis. The processes and functionalities of the system facilitate a thorough evaluation of architectural design plans, focusing on water closet compliance with accessibility and safety standards. This attention to detail in the design and placement of water closets contributes to the creation of inclusive and safe environments.

In some embodiments of the present invention, the system comprises a controller, which serves as the central processing unit for analyzing the design plan. The controller is configured to receive a design plan of at least a portion of a building. The design plan, provided in a digital format compatible with the system, includes architectural details such as the layout of rooms, positioning of fixtures, and spatial arrangements. The controller processes this information to enable further analysis and interaction.

The controller then represents at least a portion of the design plan as multiple dynamic components. Each dynamic component corresponds to specific architectural or structural elements within the design plan, such as walls, doors, fixtures (e.g., toilets, sinks, grab-bars), and clearances. Dynamic components may be configured to interact with each other within the digital environment, accurately simulating the spatial and functional relationships present in the real-world design. For example, the system may dynamically adjust the positioning of a door or the dimensions of a clear space when a user modifies related elements (e.g., lines, polygons, dimensions, or placements), maintaining consistency among all components within the design.

The system generates a first interactive user interface that visually represents the portion of the design plan using these dynamic components. The interface allows users, such as architects, engineers, or compliance officers, to interact with the design in a highly intuitive manner. Each dynamic component within the interface is associated with parameters that can be modified by the user. For example, users can adjust the dimensions of a water closet, move fixtures such as toilets or grab bars, or change the width of doorways directly within the interface. These adjustments are immediately reflected in the design, allowing for real-time visualization of changes.

The controller is further configured to identify specific areas within the design plan, such as water closets. Upon identification, the system isolates the water closet area, recognizing the boundaries, fixtures, and critical design elements within this space. The identification process involves detecting key features like the toilet, sink, grab bars, and doorways, and establishing the relevant spatial relationships among these features.

Once the water closet has been identified, the controller (or the AI engine within the controller) ascertains various design parameters that are required for compliance. These parameters include, but are not limited to, the spatial dimensions of the water closet, the positioning and height of the water closet and surrounding fixtures, the available maneuvering space, and the installation of accessibility features such as grab bars. The system may also consider door width and clearance, providing that these elements meet the specific criteria set forth by applicable building codes.

The controller then compares the ascertained design parameters against a predefined set of conditions derived from relevant building codes. These conditions may include detailed requirements from standards such as the Americans with Disabilities Act (ADA) and the American National Standards Institute (ANSI). Additional examples of building codes that govern construction practices may include the International Building Code (IBC), which provides guidelines for safety and accessibility; the National Fire Protection Association (NFPA) Codes, focusing on fire safety and prevention; the International Residential Code (IRC) for one- and two-family dwellings; the Uniform Plumbing Code (UPC) for safe plumbing practices; the National Electrical Code (NEC) for electrical safety; and various local building codes that may address specific regional concerns, such as seismic or hurricane safety. The comparison process involves evaluating whether the design parameters meet, exceed or fall short of the minimum requirements specified by these codes. The controller is capable of detecting any discrepancies or areas where the design plan does not comply with the required standards.

Following this analysis, the system provides an indication of compliance within a first interactive user interface. This indication is presented in a clear and accessible format, using visual markers, text, or graphical elements to communicate whether the design is in compliance or not. For example, compliant areas may be highlighted in green, while non-compliant areas may be flagged in red, with accompanying textual explanations outlining the specific issues. The system may also provide suggestions for corrective actions, such as repositioning a grab bar or adjusting the height of a toilet, to help users achieve compliance.

The user is further empowered to modify the design directly within the interface. The system supports dynamic re-evaluation, allowing users to make iterative changes to the design parameters and immediately re-check compliance. This iterative process allows users to refine the design until it fully meets the relevant standards. The system updates the compliance status in real time, reflecting any changes made by the user.

Moreover, the system is equipped with a storage mechanism that records the results of the compliance analysis, along with any modifications made by the user. These records are stored in a database associated with the controller, providing that the history of design changes and compliance evaluations is preserved. This feature may particularly be useful for documentation, regulatory review, and future reference, as it provides a comprehensive log of the design process and the steps taken to achieve compliance. Additionally, this feature can be utilized by the AI engine to enhance its continuous learning processes.

The present disclosure also provides methods and apparatus for analyzing two-dimensional (sometimes referred to as “2D”) documents (e.g., design plans) relating to water closets with the aid of artificial intelligence (sometimes referred to herein as “AI”) to make sure that water closets are in compliance with relevant codes or requirements set forth by an Authority Having Jurisdiction (“AHJ”) in situ of the building, particularly in relation to the actual building location where the construction is proposed. In some embodiments, the relevant codes may be set by the Authority Having Jurisdiction (AHJ) based on standards such as the Americans with Disabilities Act (ADA), American National Standards Institute (ANSI), International Building Code (IBC), National Fire Protection Association (NFPA) Codes, International Residential Code (IRC), Uniform Plumbing Code (UPC), National Electrical Code (NEC), and local building codes addressing specific regional concerns.

Specifically, the present invention uses AI to auto-detect, measure, and classify components of water closet designs, and ascertain whether requirements relating to water closets are in compliance with a relevant code according to the AHJ, such as, but not limited to code for the placement, clearance and dimensions of: water closets, toilettes, lavatories, door openings, flush controls, toilette paper dispensers, urinals, and grab bars. All of these regulations may be required to make water closets physically accessible to people including persons with disabilities. The AI system may further be configured to assess compliance not only with the current regulatory standards but also with potential updates to the codes, providing future-proof design recommendations. Additionally, the AI can cross-reference multiple codes, such as international standards and local building regulations, providing a comprehensive compliance analysis tailored to specific jurisdictions.

The present invention reduces inconsistencies in code compliance analysis and mistakes. It also provides consistent feedback on the reasons why a water closet is in or out of compliance with AHJ. Furthermore, according to some embodiments, suggestions may be made on how to cure non-compliance or to adopt a best practice, and whether or not the best practice is required to meet an obligation dictated by a relevant code. For example, the ADA does not require grab bars in residential dwellings. However, if a disabled person resides in the dwelling grab bars may need to be added to assist in a water closet. Such grab bars need to be attached in the most advantageous place for the disabled person to prevent falling. Suggested recommendations for grab bars may include height, shape length, whether to place them vertically, horizontally, or diagonally, where to place them, and how many are needed. In addition, the system may provide customizable recommendations based on the specific needs of the user, allowing for personalized solutions that go beyond standard code requirements. For instance, the AI can suggest specific types of grab bars that best fit the user's physical abilities or the spatial constraints of the water closet.

A two-dimensional reference such as a water closet floorplan and AHJ codes are input into an AI engine and the AI engine converts aspects of the floorplan into components that may be processed by the AI engine, such as, for example, a rasterized version of the floorplan. The floorplan is then processed with machine learning to specify portions that may be specified as discernable components. Discernable components may include dimensions and placement of toilette lavatories, door openings, flush controls, toilette paper dispensers, urinals, and grab bars or other discrete aspects of a water closet. The AI engine may further refine these components by applying advanced image recognition techniques to distinguish between similar elements, such as diverse types of grab bars or varying fixture models, so that each component is accurately classified and evaluated.

A scaling process may be applied to the floorplan and size descriptors are assigned to the discernible components. In addition, distances, such as placement of fixtures are calculated. The scaling process may address potential distortions in the original design documents, normalizing the dimensions so that all components are evaluated on an accurate and consistent scale. The AI also assesses the proportional and spatial relationships between components, such as the distance between a toilet and a grab bar, to determine whether the design supports functional accessibility.

Variables are specified that will be used to assess compliance and a compliance determination is made based upon values for the specified variables. In some embodiments, the variables may include some or all of: clearance around a water closet, height of the toilette, overlap of lavatory clearance or other factors on which a determination of compliance and/or lack of compliance may be based. The AI engine will generate values for some, or all of the variables referenced to determine compliance. Additionally, the AI can simulate user interactions with the water closet design, modelling how different users with varying physical abilities may engage with the space. This simulation provides a dynamic assessment of accessibility, offering insights that static measurements alone may not reveal.

In some embodiments, a controller will also set forth materials and conditions required to be in compliance with water closet codes and where, in the water closet, such materials and fixtures. are required. Some embodiments may also include, in the case where the materials and fixtures were in violation of the code, the portions of a floorplan referenced in determining non-compliance, and/or a portion of a set of conditions required by a code that is not met by a floorplan. Still further, some embodiments may include suggested changes, and/or options for sets of changes, to a floorplan and/or a water closet in consideration that may be implemented in order to achieve compliance. Moreover, the system may offer cost analysis for the proposed modifications, providing users with an estimate of the financial impact of bringing a design into compliance. The cost analysis can help decision-makers prioritize modifications based on budget constraints while still achieving necessary compliance.

Using the methods and apparatus described herein, a user may deploy AI specialized AI engines and machine learning to determine whether a water closet is compliant for use by people with disabilities. In some embodiments, a GPT type interface between an AI engine and a user may further facilitate the analysis of a set of floorplans to determine whether the floorplans are in compliance with an applicable code in a particular location (jurisdiction). The present invention indicates how AI may be used in the design, construction, and compliance of water closets meant for use by people to bring about profoundly important advances in safety and accessibility for the handicapped community and to mitigate risk from falling or other adverse conditions. Additionally, the AI system can include a feedback loop that allows users to input real-world performance data after the water closet has been built, enabling the AI to refine its future recommendations based on actual outcomes. This feature provides that the AI's analysis continues to improve over time, adapting to emerging trends and evolving best practices.

In general, the present invention provides for apparatus and methods related to receiving as input design plans (either physical or electronic) and generating one or more-pixel patterns based upon automated processing of the water closet plans. The pixel patterns are analyzed using computerized processing techniques to mimic the perception, learning, problem-solving, and decision-making formerly performed by human workers (sometimes referred to herein as artificial intelligence or “AI”).

Based upon AI analysis of pixel patterns derived from the two-dimensional references and knowledge accumulated from increasing volumes of analyzed two dimensional references, interactive user interfaces may be generated that allow for a user to modify dynamic design plans of features gleaned from the two-dimensional reference. AI processing of the pixel patterns, based upon the two-dimensional references, may include mathematical analysis of polygons formed by joining select vectors included in the two-dimensional reference. The analysis of pixel patterns and manipulatable vector interfaces and/or polygon-based interfaces is advantageous over human processing in that AI analysis of pixel patterns, vectors and polygons is capable of leveraging knowledge gained from one or both of: selected groups and learnings derived from similar previous bodies of work, whether or not a human requesting a current analysis was involved in the previous learnings. The AI's ability to integrate learnings from past analyses enables it to recognize subtle patterns that may indicate potential compliance issues, even in complex or unconventional design plans. This predictive capability helps in proactively addressing compliance risks before they manifest in the final construction.

In still another aspect, in some embodiments, enhanced interactive interfaces may include one or more of: user definable and/or editable lines; user definable and/or editable vectors; and user definable and/or editable polygons. The interactive interface may also be referenced to generate diagrams based upon the lines, vectors and polygons defined in the interactive interface. Still further, various embodiments include values for variables that are definable via the interactive interface with AI processing and human input.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind-including learning from examples and experience, recognizing patterns and/or objects, understanding and responding to patterns in positions relative to other patterns, making decisions, solving problems. The analysis also combines these and other capabilities to perform functions the skilled labor force traditionally performed. Furthermore, the AI system may utilize ensemble learning techniques, combining the outputs of multiple AI models to enhance accuracy and robustness in its compliance assessments. By cross-validating results across different models, the system minimizes the likelihood of errors and delivers more reliable recommendations.

The present invention reduces inconsistencies in design compliance analysis and mistakes. It also provides consistent feedback on the reasons why a building design is in compliance, or which aspects of a design plan place the building design in a state of non-compliance. In addition, the system tracks changes made during the design process, offering a version history that allows users to review past decisions and their impact on compliance. This feature supports more informed decision-making and facilitates collaboration among multiple stakeholders involved in the design process.

Furthermore, according to some embodiments of the present invention, automated systems generate proposed modifications to achieve compliance with an applicable code, or to adopt a best practice whether or not the best practice is required to meet an obligation dictated by a relevant code.

A two-dimensional reference, such as a design floorplan is input into an AI engine and the AI engine converts aspects of the floorplan into components that may be processed by the AI engine, such as, for example, a rasterized version of the floorplan. The floorplan is then processed with machine learning to specify portions that may be specified as discernable components. Discernable components may include, for example, rooms, residential units, hallways, stairs, dead ends, windows, or other discrete aspects of a building. To enhance the accuracy of component detection, the AI engine can utilize advanced image segmentation techniques, which allow it to separate and identify individual elements within complex floorplans more effectively.

The scaling process is applied to the floorplan and size descriptors are assigned to the discernable components. In addition, distances, such as, for example, a distance to an exit from the furthest point in a residential unit are calculated. The scaling process can be adjusted dynamically based on user input or specific code requirements, allowing for the consideration of various building types and sizes.

Variables are specified that will be used to assess compliance and a compliance determination is made based upon values for the specified variables. In some embodiments, the variables may include some or all of: occupancy load; travel distance (e.g., from a specified point to the water closet); travel distance from a furthest point from a point of egress; egress capacity; common path; dead end; a function of space; or other factor on which a determination of compliance and/or lack of compliance may be based. The AI engine will generate values for some, or all of the variables referenced to determine compliance. In cases where design variables conflict with one another (e.g., maximizing egress capacity while minimizing travel distance), the AI can provide trade-off analyses, helping users to make informed decisions that balance safety, functionality, and compliance.

In some embodiments, a controller will also set forth one or both of: components and conditions required to be in compliance with a set of rules or codes and where in the floorplan the components/conditions were included. Some embodiments may also include, in the case where the conditions/components were not met by a floorplan, the portions referenced in determining non-compliance. Still further, some embodiments may include suggested changes and/or options for sets of changes to the floor plan that may be implemented in order to achieve compliance. Additionally, the controller may generate automated reports summarizing the compliance status of each component, including detailed explanations for any deviations from code requirements. These reports can be exported in various formats (e.g., PDF, XML) for easy sharing and documentation.

Using the methods and apparatus described herein, a determination of whether a building is conducive for use by people with disabilities is generated. The present invention indicates how AI may be used in the design, construction and compliance of buildings meant for use by people to bring about profoundly important advances in safety and accessibility for the handicapped community and to mitigate risk from fire or other adverse conditions. By integrating with other building management systems, the AI can also monitor ongoing compliance throughout the building's lifecycle, providing alerts if any modifications or wear-and-tear compromise the originally compliant design.

In general, the present invention provides for apparatus and methods related to receiving as input design plans (either physical or electronic) and generating one or more pixel patterns based upon automated processing of the design plans. The pixel patterns are analyzed using computerized processing techniques to mimic the perception, learning, problem-solving, and decision-making formerly performed by human workers (sometimes referred to herein as artificial intelligence or “AI”).

Based upon AI analysis of pixel patterns derived from the two-dimensional references and knowledge accumulated from increasing volumes of analyzed two dimensional references, interactive user interfaces may be generated that allow for a user to modify dynamic design plans of features gleaned from the two-dimensional reference. AI processing of the pixel patterns, based upon the two-dimensional references, may include mathematical analysis of polygons formed by joining select vectors included in the two-dimensional reference. Analysis of pixel patterns and manipulatable vector interfaces and/or polygon-based interfaces is advantageous over human processing in that AI analysis of pixel patterns, vectors and polygons is capable of leveraging knowledge gained from one or both of: a select group and learnings derived from similar previous bodies of work, whether or not a human requesting a current analysis was involved in the previous learnings.

In still another aspect, in some embodiments, enhanced interactive interfaces may include one or more of: user definable and/or editable lines; user definable and/or editable vectors; and user definable and/or editable polygons. The interactive interface may also be referenced to generate diagrams based upon the lines, vectors and polygons defined in the interactive interface. Still further, various embodiments include values for variables that are definable via the interactive interface with AI processing and human input. The interface may also support collaborative features, allowing multiple users to work on the same design simultaneously while the AI system tracks and integrates input from all participants, providing consistency and compliance across the board.

According to the present invention, analysis of pixel patterns and enhanced vector diagrams and/or polygon based diagrams may include one or more of: neural network analysis, opposing (or adversarial) neural networks analysis, machine learning, deep learning, artificial-intelligence techniques (including strong AI and weak AI), forward propagation, reverse propagation and other method steps that mimic capabilities normally associated with the human mind-including learning from examples and experience, recognizing patterns and/or objects, understanding and responding to patterns in positions relative to other patterns, making decisions, solving problems. The analysis also combines these and other capabilities to perform functions the skilled labor force traditionally performed.

### BRIEF DESCRIPTION OF THE DRAWINGS

The accompanying drawings, which are incorporated into and constitute a part of this specification, illustrate several embodiments of the present invention. Together with the description, these drawings serve to illustrate some aspects of the present invention.

FIG. 1A illustrates method steps that may be implemented in some embodiments of the present invention.

FIG. 1B illustrates a high-level diagram of components included in a system that uses AI to generate an interactive user interface.

FIG. 1C illustrates an exemplary design plan comprising multiple dwelling units and one or more water closet areas.

FIGS. 1D-1H illustrate various exemplary views of water closet areas extracted by the controller from two-dimensional design plans for compliance determination in some embodiments of the present invention.

FIG. 1I illustrates an exemplary simulation method used by the AI engine for compliance analyses in some embodiments of the present invention.

FIGS. 2A, 2B, 2C and 2D illustrate a two-dimensional representation of a floor plan and an AI analysis of the same to assess boundaries and identify space types and locations of various spaces (e.g., water closet area) within the floor plan.

FIG. 2E illustrates an exemplary portion of a design plan comprising a public toilet having a plurality of water closets in some embodiments of the present invention.

FIG. 2F illustrates an exemplary portion of a design plan including a water closet area for compliance analysis in some embodiments of the present invention.

FIG. 2G-2L illustrate various exemplary designs of water closets and hand wash basins that can be used in a water closet area and by the AI engine for compliance analyses.

FIG. 2M illustrates an exemplary view of a water closet with backflow as determined by the AI engine in compliance analyses in some embodiments of the present invention.

FIG. 2N illustrates an exemplary view of a water closet having improper fittings and uneven floor type as determined by the AI engine in compliance analyses in some embodiments of the present invention.

FIGS. 3A-3D show various views of the AI-analyzed boundaries overlaid on the original floorplan including a table illustrated to contain hierarchical dominance relationships between area types.

FIGS. 4A-4B illustrate various aspects of dominance-based area allocation.

FIGS. 5A-5D illustrate various aspects of region identification and area allocation.

FIGS. 6A-6C illustrate various aspects of boundary segmentation and classification.

FIG. 7 illustrates aspects of correction protocols.

FIG. 8 illustrates exemplary processor architecture for use with the present disclosure.

FIG. 9 illustrates exemplary mobile device architecture for use with the present disclosure.

FIGS. 10A-10B illustrate exemplary method steps that may be executed in some embodiments of the present invention.

FIG. 11 illustrates additional method steps that may be executed in some embodiments of the present invention.

FIGS. 12A-12B illustrate diagrams of paths of egress to or from different spaces in a design plane (including a water closet).

FIG. 13 illustrates a conceptual framework showing multiple layers involved in the AI-powered collaborative system for compliance analyses of design plans in accordance with the present invention.

FIG. 14 illustrates a block diagram of exemplary aspects that may be used in building or refining design models.

FIG. 15 illustrates exemplary method steps that may be included in some embodiments of the present invention.

FIGS. 16A and 16B illustrate exemplary method steps that may be included in some embodiments of the present invention.

FIG. 17 illustrates additional method steps that may be performed in some implementations of the present invention.

FIG. 18 illustrates a multi-story residential building that may be analyzed using the methods and apparatus described herein.

FIGS. 19A-19D illustrate exemplary method steps that may be practiced in some embodiments of the present invention.

### DETAILED DESCRIPTION

The present invention provides improved methods and apparatus for artificial intelligence-based conversion of a two-dimensional reference, such as a design plan, into an interactive interface for indicating whether the design plan is compliant with a set of requirements related to a water closet. The interactive interface is designed not only to highlight compliance but also to offer real-time feedback and suggestions to architects and designers, enabling them to make informed decisions during the design process.

In some embodiments of the present invention, the methods and system are configured to analyze the compliance of water closet areas within a building design by leveraging advanced artificial intelligence (AI) techniques. The AI engine first recognizes various fixtures within the water closet area, including toilets, urinals, hand wash basins, showers, bathtubs, grab bars, soap dispensers, mirrors, ventilation fixtures, toilet paper dispensers, bidets, water jets, and drainage pipes. Each of these fixtures is identified and mapped within the design plan, allowing the AI engine to understand the layout and spatial configuration of the water closet area.

The AI engine then ascertains critical design parameters for each recognized fixture, such as its location, orientation, and height relative to the floor level. This includes determining the distance of each fixture from adjacent walls and other fixtures within the water closet area. For example, the AI engine may measure the distance between a toilet and a nearby wall to determine if it meets the minimum clearance requirements specified by relevant building codes. In addition to evaluating distances from walls, the AI engine may also assess the relative distances between fixtures, such as the spacing between a toilet and a hand wash basin or between a shower and a grab bar.

To further enhance the analysis, the AI engine may simulate the movement of a virtual person with disabilities within the water closet area. This simulation may include varying the size and type of wheelchairs used by the virtual person to evaluate whether the space is accessible and whether the design meets the requirements of standards like the Americans with Disabilities Act (ADA). The simulation helps to identify potential obstacles and areas where the design may need to be adjusted to accommodate users with different needs.

The AI engine also calculates the clearance distance around the water closet, for determining if there is adequate space for safe and comfortable use. This includes determining the front clearance space in front of the water closet and comparing it to the minimum clearance requirements specified by the relevant building codes. If an obstruction is detected within this clearance space, the AI engine can automatically suggest repositioning or modifying nearby fixtures to achieve compliance.

Furthermore, the system allows users to interactively modify design parameters within the user interface. For example, a user can input a command to adjust the clearance distance around the water closet, e.g., setting it to a minimum of 60 inches wide and 56 inches long, as required by certain accessibility standards. The AI engine then re-analyzes the design based on these modifications to determine compliance.

The AI engine may also determine the centerline of the water closet and assess whether any other fixtures, such as a lavatory or wash basin, are within a specified distance from this centerline. If a lavatory or another fixture is found within 18 inches of the centerline, the AI engine evaluates the impact on compliance and suggests any necessary adjustments. Additionally, the AI engine can identify the geopolitical locality and the authority having jurisdiction over the building's location. It then includes the relevant code requirements specific to that jurisdiction in the compliance analysis, for determining if the water closet area meets all local regulations.

The present invention includes methods and apparatus to analyze a building (or other structure) design based upon automated AI analysis of a two-dimensional reference and applying machine learning to determine if the design adequately supports water closet metrics, requirements and/or suggestions set forth by an authority having jurisdiction. The system is capable of processing various formats of design plans, including but not limited to CAD files, PDFs, and scanned images, providing compatibility with a wide range of design tools used in the industry.

AI and machine learning may follow a design analysis to recognize and/or recommend aspects of a building to bring the building into compliance with the requirements of the authority having jurisdiction. The process may include identification of critical compliance factors such as accessibility standards, spatial configurations, and safety regulations, with the AI engine capable of prioritizing recommendations based on the severity of non-compliance issues and potential impacts on overall building safety and functionality.

The interactive interface is operative to generate values of variables useful to ascertain whether the submitted design plan meets or exceeds a designated building code pertaining to a geographic and/or geopolitical area. The interactive interface may also include specific requirements of a building code and indications of whether some or all of the requirements are met. In addition, the interface may include pictorial indications of portions of a design plan that have been associated with specific requirements of the building code during the AI analysis. The pictorial indications may include description of why a particular portion meets, exceeds, or does not meet a compliance code requirement. Furthermore, the interface can be customized to reflect different levels of detail based on the user's expertise, providing high-level summaries for quick assessments or in-depth analysis for thorough evaluations.

As described herein, a design plan may be associated with an existing building or a proposed project that includes construction of a building (or other structure, herein collectively referred to as a “building”). Generation of documentation quantifying compliance or non-compliance of a design plan with specific building codes is also within the scope of the present invention. In some embodiments, automated suggested revisions to the design plan to bring the design plan into conformity with the code are also within the scope of the invention. The system is further capable of generating detailed reports that document the entire compliance assessment process, including initial analysis, identified issues, proposed solutions, and any subsequent revisions made to the design. These reports can be exported in various formats for easy sharing with stakeholders and regulatory bodies.

According to the present invention, a controller is operative to execute artificial intelligence (AI) processes and analyze one or more design plans of at least a portion of a building (or other structure) for which a compliance determination will be generated and provides values for variables used to ascertain a state of compliance based upon descriptive content included in the design plans. The controller is also equipped to handle real-time updates and re-analysis, allowing users to make changes to the design and immediately see how those changes affect compliance.

In some embodiments, the design plan may include technical drawings such as blueprints, floor plans, design plans and the like. The AI analysis may include determination of boundaries and/or features indicated in the design plan. The design plan may be a two-dimensional static reference, or a two-dimensional or three-dimensional dynamic reference, such as a Revit compatible file. This boundary determination may be used to provide useful information about a building such as, one or more of: rooms that comprise a residential unit; an area of an individual room or other area; a distance of travel to a point of egress, a width of a doorway; a width of a path or egress; a dead end path; a perimeter of a defined area; a point furthest from another point (e.g. ; a point furthest from a point of egress); a common path; and the like. Based upon values of parameters derived from a two-dimensional reference, the AI engine may generate additional values related to code compliance, such as one or more of: an egress capacity; an occupancy load; a function for a space; alternative paths of egress; dead end double back distances; or other parameters. Moreover, the system can integrate data from multiple design versions, tracking changes over time and analyzing how these changes impact overall compliance and safety metrics.

In some embodiments, the present invention may analyze a two-dimensional reference and generate one or both of compliant paths from a defined room to a point of egress and suggested modifications to a building described in the two-dimensional reference. In addition, the system may simulate various emergency scenarios, such as fire or earthquake conditions, to evaluate the effectiveness of the egress paths under stress, so that the design not only meets code requirements but also provides practical safety in real-world situations.

Some preferred embodiments include an interface that describes a condition for compliance and illustrates a portion of the two-dimensional reference that indicates a state of compliance or non-compliance associated with the condition. For example, an interface may require a path for egress that is less than a proscribed minimum distance and of sufficient width. The present invention provides for an interface illustrating a suggested path integrated into the design plan. A user may accept a path laid out by automated processes or input a specific path into a user interactive interface. The user interactive interface may also indicate whether the path supports a determination of compliance with a particular code or a state of non-compliance. Furthermore, the interface may support interactive 3D visualization, allowing users to virtually explore the suggested paths and modifications, providing a more intuitive understanding of how the design meets or fails to meet compliance standards.

Similarly, the AI engine may apply machine learning to a design plan to determine values for variables that relate to other conditions for compliance, such as, by way of non-limiting example: dining accommodations; swimming pool access; locker rooms accommodations; door widths; parking space availability and surrounding area; widths of accessible routes to equipment; number of points of entry into a pool; number of points of egress; width of path of egress; width of stairways; and the like. The system can also account for regional variations in code requirements, automatically adjusting its analysis based on the specific regulations of the geographic area where the building is located or proposed to be constructed.

AI generated values for parameters may also be useful in a variety of estimation elements, such as (without limitation): flooring (wood, ceramic, carpet, tile, etc.), structural (poured concrete, steel), walls (gypsum, masonry blocks, glass walls, wall base, exterior cladding), doors and frames (hollow metal, wood, glass), windows glazing, insulation, paint (ceilings and walls), acoustical ceilings, code compliance, stucco (ceilings and walls), mechanical, plumbing, and electrical aspects. The estimation elements may be used to calculate the cost of construction to implement a modification to a building design in order to become compliant with a building code. The cost may be calculated based upon AI determination of architectural aspects, such as doorways, windows, angles in walls, curves in walls, plumbing fixtures, piping, wiring, electrical equipment or boxes; duct work; HVAC fixtures and/or equipment; or other component or aspect included in an estimate for work to cause a building to be compliant. Additionally, the system may generate alternative cost estimates based on different compliance strategies, allowing users to choose the most cost-effective solution that still meets all regulatory requirements. These estimates can be updated in real-time as design modifications are made, providing users with immediate feedback on the financial implications of their decisions.

In the following sections, detailed descriptions of examples and methods will be given. The description of both preferred and alternative examples, though thorough, are exemplary only. It is understood that, to those skilled in the art, various modifications and alterations may be apparent and within the scope of the present invention. Unless otherwise indicated by the language of the claims, the examples do not limit the broadness of the aspects of the underlying invention as defined by the claims.

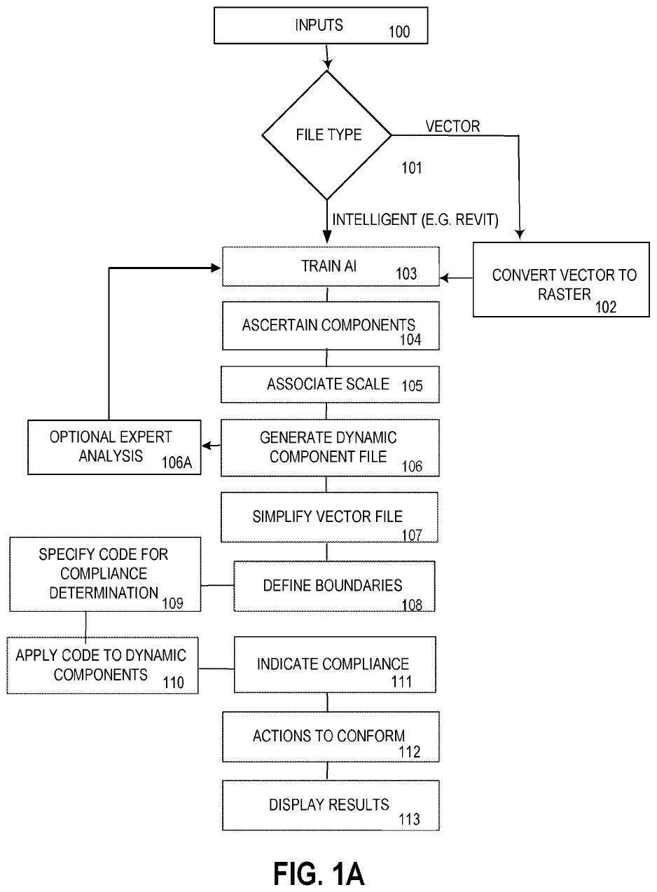

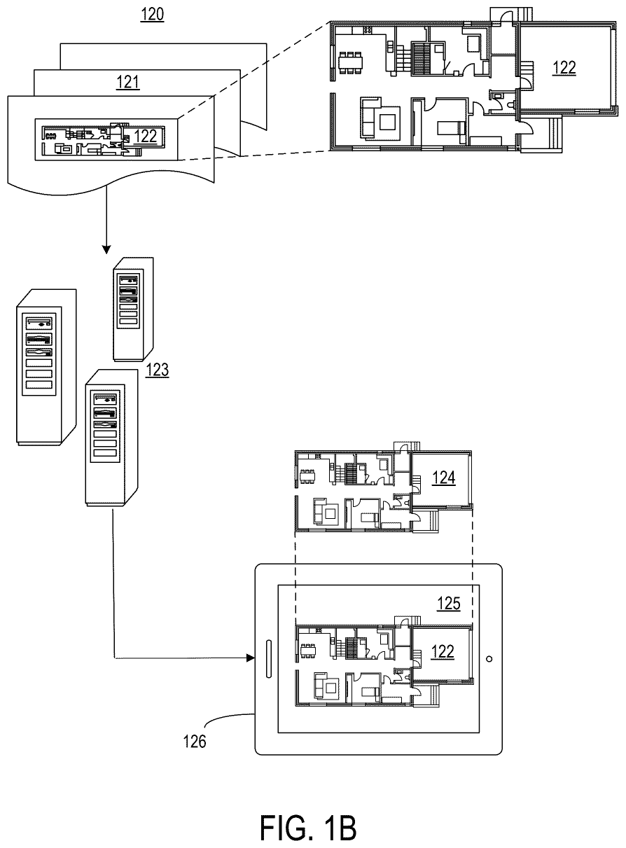

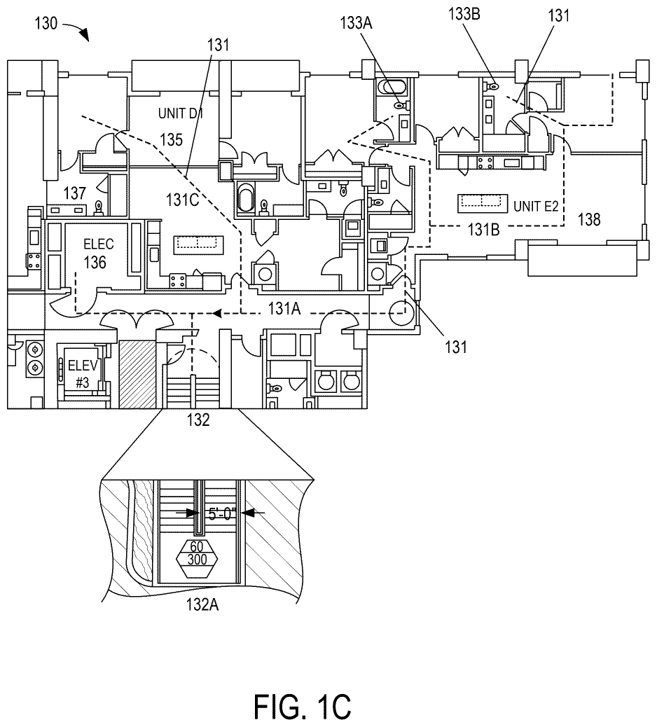

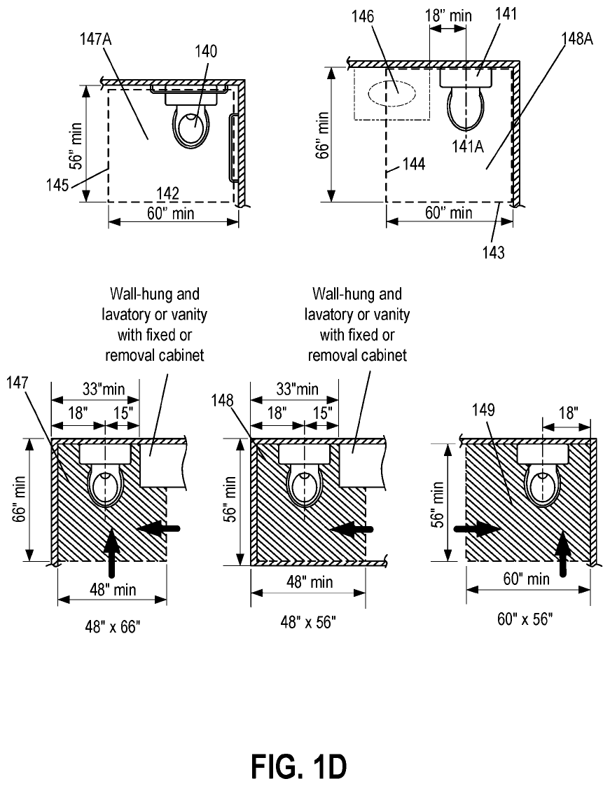

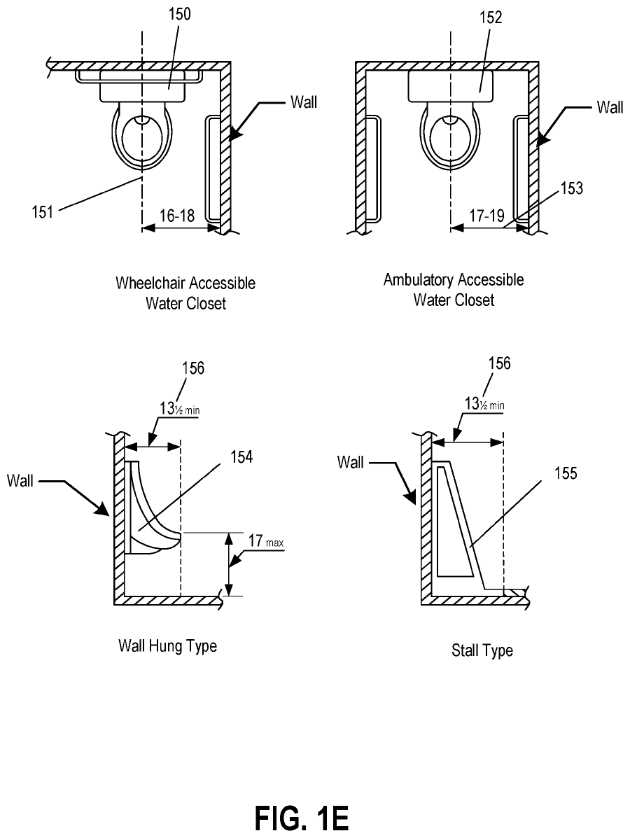

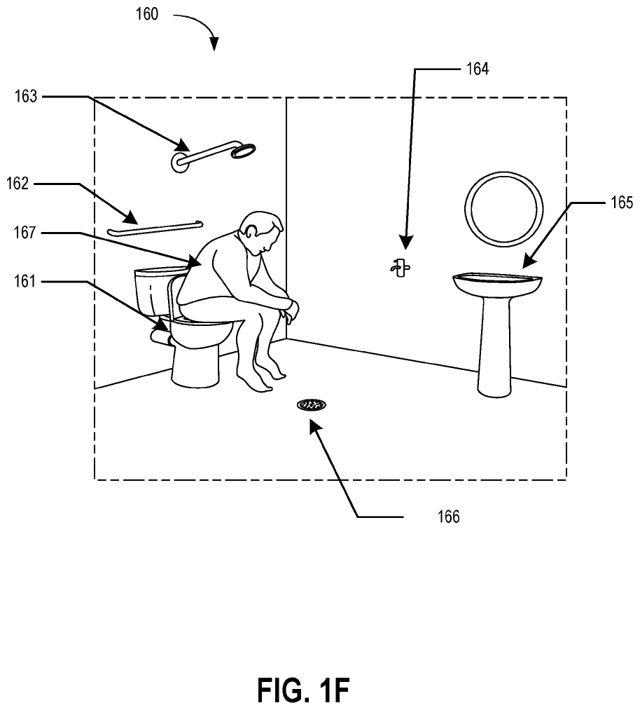

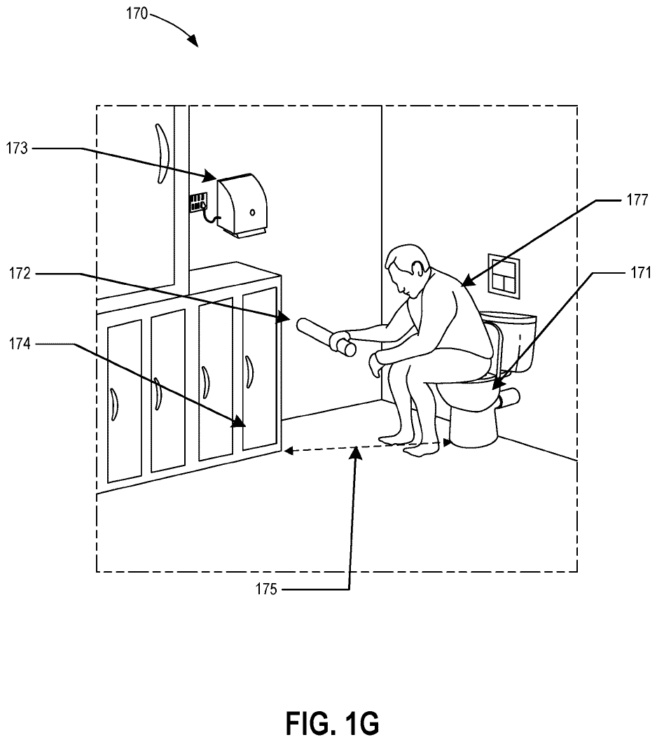

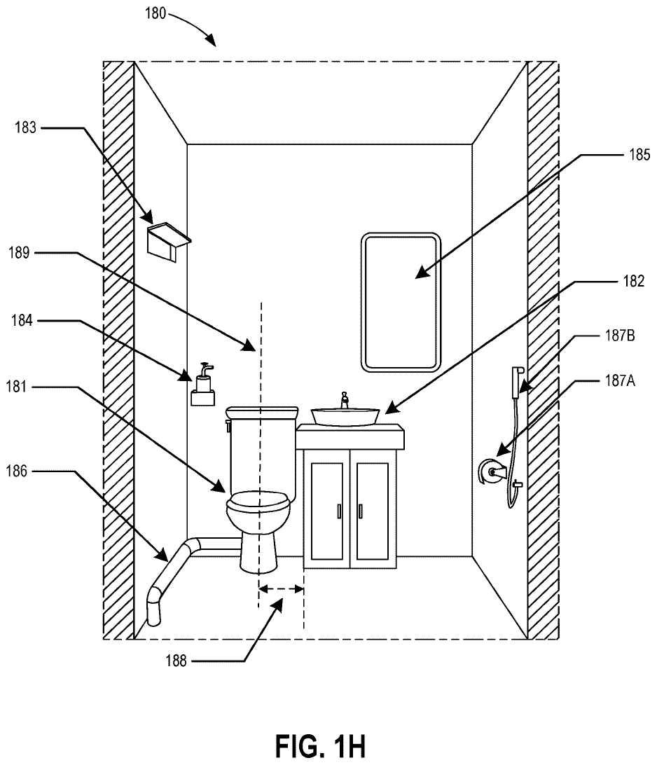

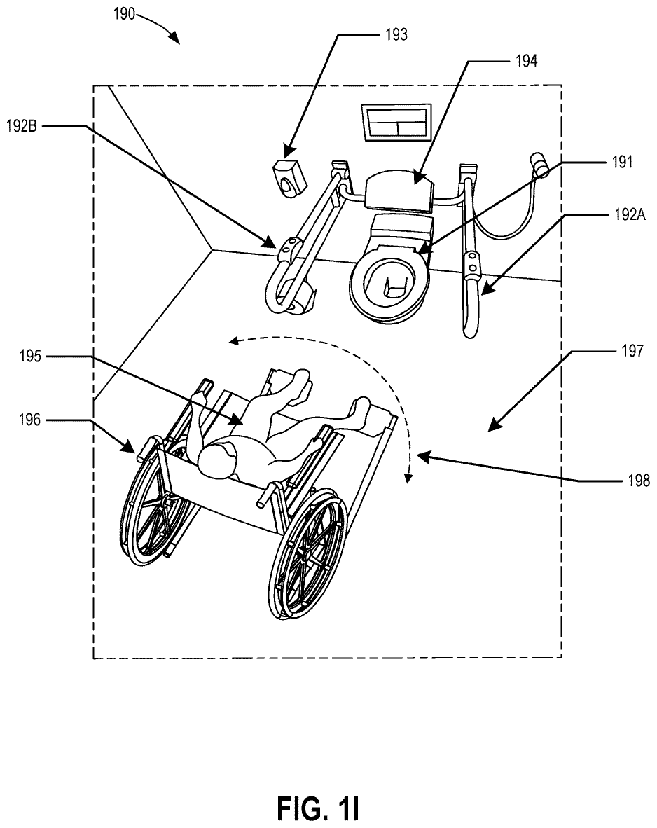

Referring now to FIG. 1A, a general flow diagram showing some preferred embodiments of the present invention is illustrated. At step 100, a design plan (which may be design plan or dynamic architectural design file (e.g., a Revit® compatible file) indicating aspects of a building; is input into a controller or other data processing system using a computing device. The design plan may include an item of a known size, such as, by way of a non-limiting example, a scale bar that allows a user to obtain a scale of the drawing (e.g., 1″=100′ etc.) or an architectural aspect of a known dimension, such as a wall or doorway of a known length (e.g., a doorway known to be three feet wide). The controller is configured to recognize and utilize these scale indicators to accurately process and analyze the dimensions of the design plan.

Input of the two-dimensional reference into the controller may occur, for example, via known ways of rendering an image as a vector diagram, such as via a scan of paper-based initial drawings; upload of a vector image file (e.g., encapsulated postscript file (epf file); adobe illustrator file (ai file); or portable document file (pdf file). In other examples, a starting point for estimation may be a drawing file in an electronic file containing a model output for an architectural floor plan. In still further examples, other types of images stored in electronic files such as those generated by cameras may be used as inputs for automated processes that determine compliance with requirements of a code. The system is designed to handle diverse file formats and sources, making it adaptable to various input methods commonly used in architectural design.

In some embodiments, the design plan may be files extensions that include but are not limited to: DWG, DXF, PDF, TIFF, PNG, JPEG, GIF, or other type of files based upon a set of engineering drawings. Some design plans may already be in a pixel format, such as, by way of a non-limiting example, a two-dimensional reference in a JPEG, GIF or PNG file format. The engineering drawings may be hand drawings, or they may be computer-generated drawings, such as may be created as the output of CAD files associated with software programs such as AutoDesk™, Microstation™ etc. In other examples, such as for older structures, a drawing or other design plan may be stored in paper format or digital version or may not exist or may never have existed. The input may also be in any raster graphics image or vector image format. The system's flexibility in accepting various file formats, allows it to accommodate both modern and legacy design plans, providing a comprehensive solution for compliance analysis.

The input process may occur with a user creating, scanning into, or accessing such a file containing a raster graphics image or a vector graphics image. The user may access the file on a desktop or standalone computing device or, in some embodiments, via an application running on a smart device. In some embodiments, a user may operate a scanner or a smart device with a charge coupled device to create the file containing the image on the smart device. The controller can seamlessly integrate these diverse input methods, so that the transition from physical to digital formats is efficient and accurate.

In some embodiments, a degree of the processing as described herein may be performed on a controller, which may include a cloud server, a standalone computing device or a smart device. In many examples, the input file may be communicated by the smart device to a controller embodied in a remote server. In some embodiments, the remote server, which is preferably a cloud server, may have significant computing resources that may be applied to AI algorithmic calculations analyzing the image. This distributed processing approach allows for scalability, enabling the system to handle large and complex design files without compromising performance.

In some embodiments, dedicated integrated circuits tailored for deep learning AI calculations (AI Chips) may be utilized within a controller or in concert with a controller. Dedicated AI chips may be located on a controller, such as a server that supports a cloud service or a local setting directly. These AI chips are optimized for high-speed processing, so that even complex AI calculations can be performed in real-time, enhancing the system's responsiveness.

In some embodiments, an AI chip tailored to a particular artificial intelligence calculation may be configured into a case that may be connected to a smart device in a wired or wireless manner and may perform a deep learning AI calculation. Such AI chips may be configurable to match a number of hidden levels to be connected, the manner of connection, and physical parameters that correspond to the weighting factors of the connection in the AI engine (sometimes referred to herein as an AI model). In other examples, software only embodiments of the AI engine may be run on one or more of: local computers, cloud servers, or on smart device processing environments. The modularity of these AI chips allows for customization based on the specific needs of the project, providing that the system can be tailored to different scales and complexities of architectural design analysis.

At step 101, a controller may determine if a design received into the controller includes a vector diagram. If a file type of the received design plan, such as an input architectural floor plan technical drawing, includes at least a portion that is not already in raster graphics image format (for example, that it is in vector format), then the input architectural floor plan technical drawing may be transformed to a pixel or raster graphics image format in step 102. Vector-to-image transforming software may be executed by the controller, or via a specialized processor and associated software. This conversion may be useful for standardizing the input data, allowing the subsequent AI analysis to be consistent and accurate across different file types.

In some embodiments, the controller may determine a pixel count of a resulting rasterized file. The rasterized file will be rendered suitable for a controller hosting an artificial intelligence engine (“AI engine”) to process, the AI engine may function best with a particular image size or range of image size and may include steps to scale input images to a pixel count range in order to achieve a desired result. Pixel counts may also be assigned to a file to establish the scale of a drawing—for example, 100 pixels equals 10 feet.

In various examples, the controller may be operative to scale up small images with interleaved average values with superimposed gaussian noise as an example, or the controller may be operative to scale down large images with pixel removal. A desired result may be detectable by one or both of the controller and a user. For example, a desired result may be a most efficient analysis, a highest quality analysis, a fastest analysis, a version suitable for transmission over an available bandwidth for processing, or other metric. The system's ability to adjust the image scale dynamically provides that it can optimize performance based on the specific requirements of the analysis, whether prioritizing speed, accuracy, or resource efficiency.

At step 103, training (and/or retraining) of the AI engine is performed. Training may include, for example, manual identification of patterns in a rasterized version of an image included in a design plan that corresponds with architectural aspects, walls, fixtures, piping, duct work, wiring or other features that may be present in the two-dimensional reference. The training may also include one or more of: identification of relative positions and/or frequencies and sizes of identified patterns in a rasterized version of the image included in the design plan. This continuous training process allows the AI engine to improve over time, adapting to new design trends and increasingly complex architectural layouts.

In some embodiments, and in a non-limiting sense, an AI engine used to analyze the design plan may be based on a deep learning artificial neural network framework. The AI engine image processing may extract different aspects of an image included in the design plan that is under analysis. At a high level, the processing may perform segmentation to define boundaries between important features. In engineering drawings defined boundaries may be based upon the presence of architectural features, such as walls, doorways, windows, stairs, and the like. These boundaries are useful for accurate analysis, as they delineate the areas that need to be assessed for compliance with relevant building codes.

In some embodiments, a structure of the artificial neural network may include multiple layers, such as input layers and hidden layers with designed interconnections with weighting factors. For learning optimization, the input architectural floor plan technical drawings may be used for artificial intelligence (AI) training to enhance the AI's ability to detect what is inside a boundary. A boundary is an area on a digital image that is defined by a user and tells the software what needs to be analyzed by the AI. Boundaries may also be automatically defined by a controller executing software during certain process steps, such as a user query. Using deep artificial neural networks, original architectural floor plans (along with any labeled boundaries) may be used to train AI models to make predictions about what is inside a boundary. In exemplary embodiments, the AI model may be given over ~50,000 similar architectural floor plans to improve boundary-prediction capabilities.

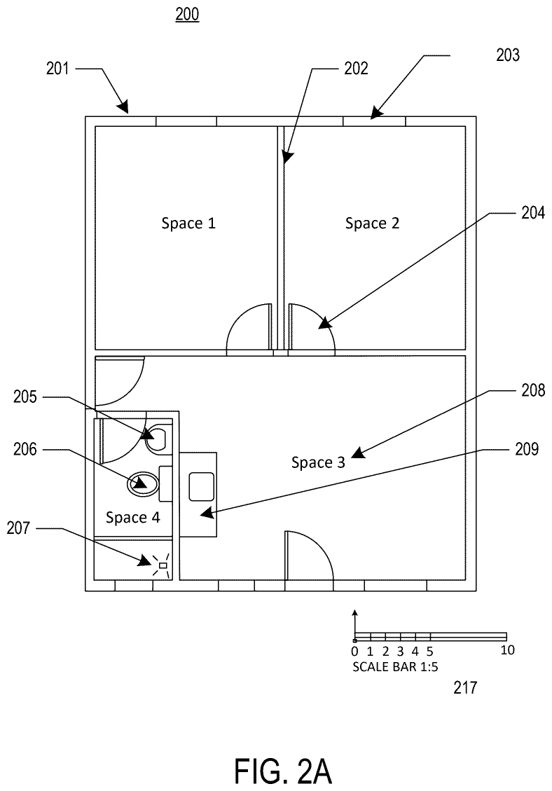

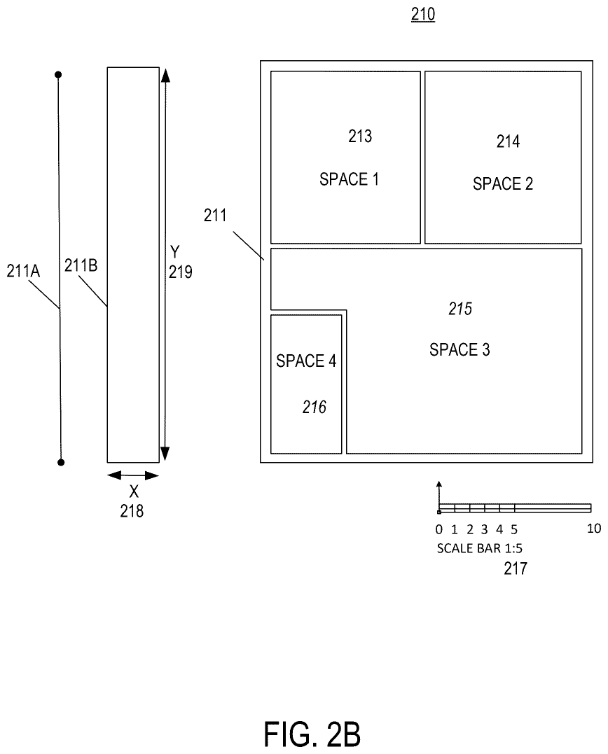

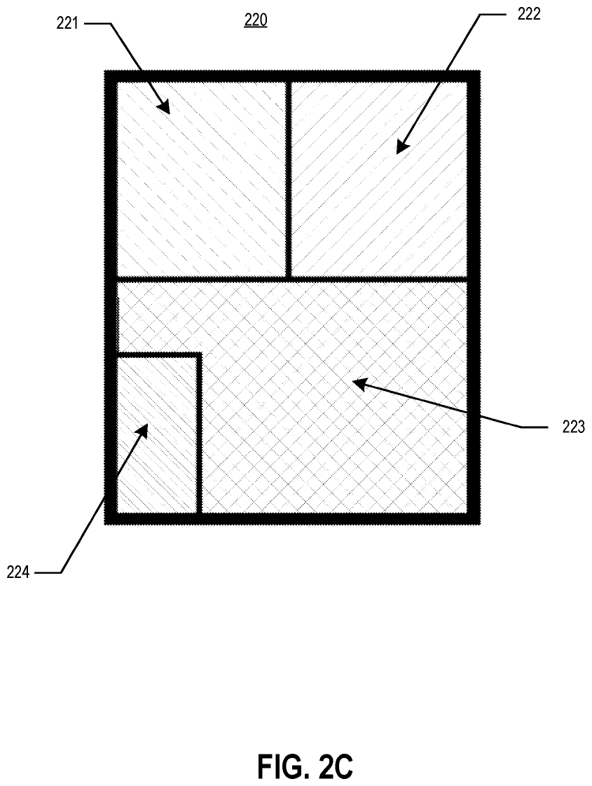

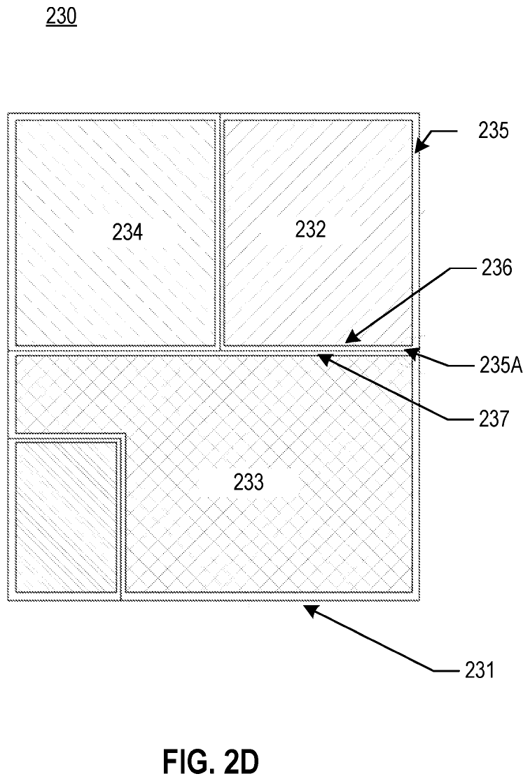

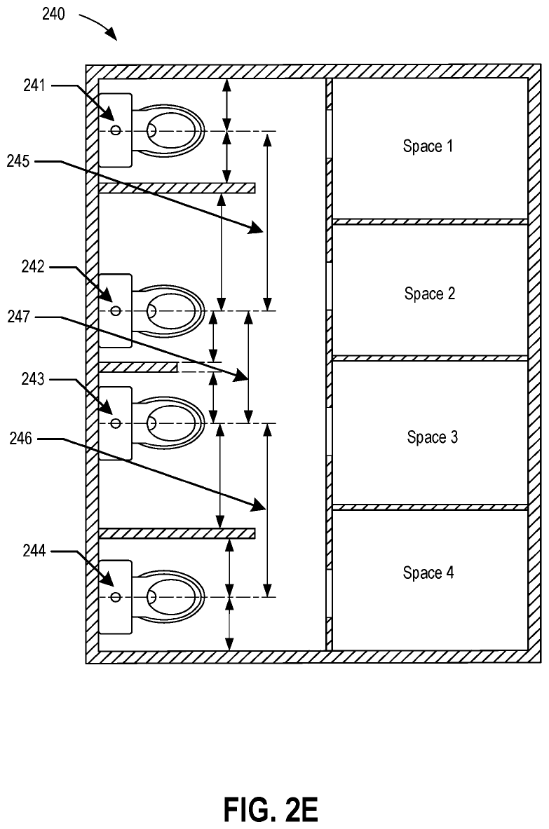

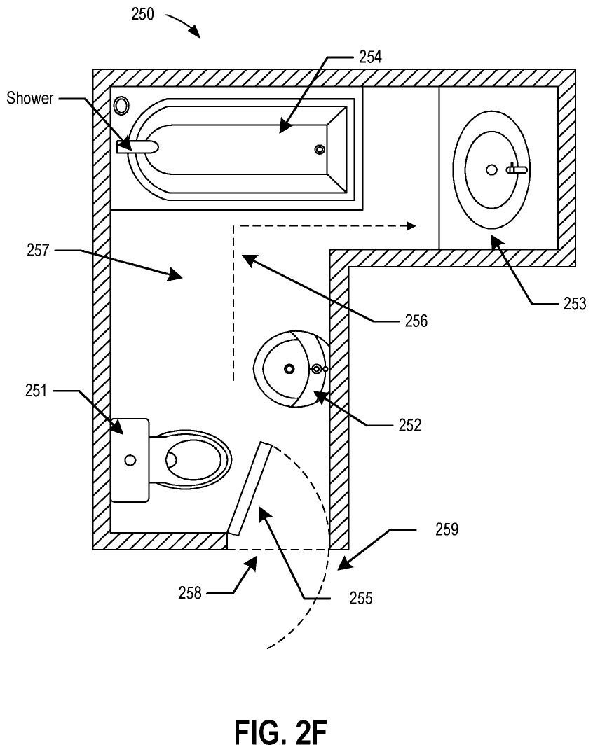

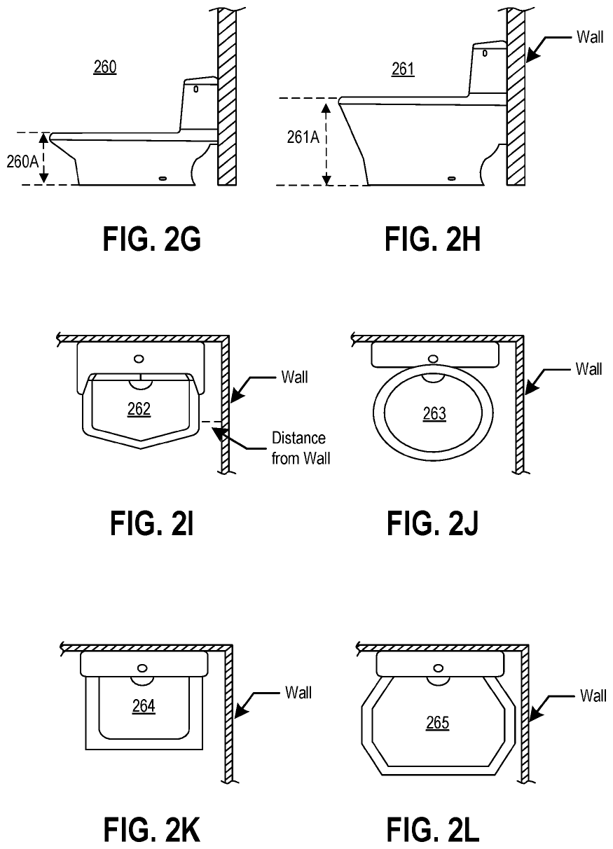

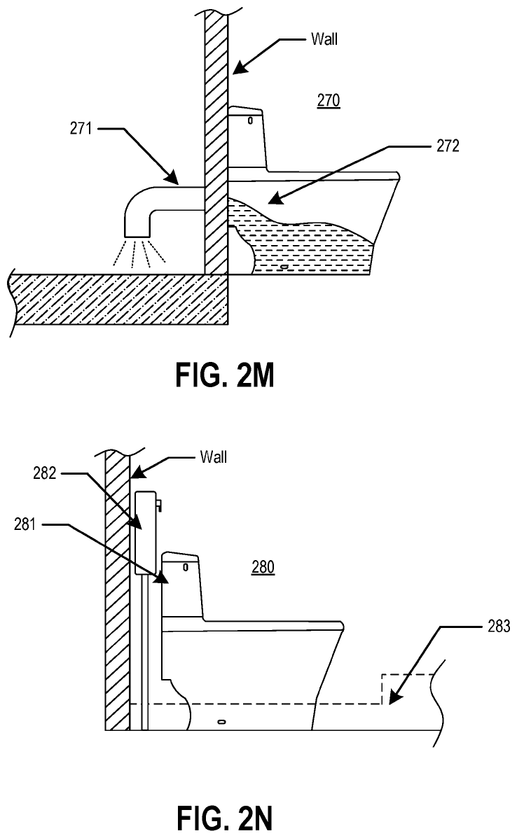

In some embodiments, a training database may utilize a collection of design data that may include one or more of: a combination of a vector graphic two-dimensional references such as floor plans and associated raster graphic version of the two-dimensional references; raster graphic patterns associated with features; and a determination of boundaries may be automatically or manually derived. An exemplary AI-processed two-dimensional reference that includes a design plan and/or a floorplan 210, with boundaries 211 predicted, is shown in FIG. 2B, based on the floorplan of FIG. 2A. The training database is continually updated with new design data, allowing the AI model to remain current with the latest architectural practices and regulatory standards.

In still another aspect, in some embodiments, a controller may access data from various types of BIM and Computer Aided Drafting (CAD) design programs and import dimensional and shape aspects of select spaces or portions of the designs as they related to a design plan.

At step 104, an AI engine may ascertain features included in the design plan, the AI engine may additionally ascertain that a feature is located within a particular set of boundaries or external to the set of boundaries. Features may include, by way of non-limiting example, one or more of: architectural aspects, fixtures, duct work, wiring, piping, or other items included in a two-dimensional reference submitted to be analyzed. The features and boundaries may be determined, for example, via algorithmically processing an input design plan image with a trained AI model. As a non-limiting example, the AI engine may process a raster file that is converted for output as an image file of a floorplan (as illustrated in FIG. 2B, a boundary is represented as a line, a boundary may also be represented as a polygon, which may be a patterned polygon or other user discernable representation, such as a colored line etc.). Features may also be designated on a user interface. A feature may be represented via an artifact, such as, for example, one or more of: a point, a polygon, an icon, or other shapes. The AI engine's ability to accurately identify and categorize these features is useful for subsequent compliance analysis, so that all relevant elements are considered in the assessment. The AI engine can also ascertain, type of spaces (e.g., kitchen, bathroom rest room, office space, stairwell, etc. ,) within the design plans.

At step 105, a scale (e.g., FIG. 2B item 217) is associated with the two-dimensional reference. In preferred embodiments, the scale is based upon a portion of the two-dimensional reference dedicated for indicating a scale, such as a ruler of a specific length relative to features included in a technical drawing included in the two-dimensional reference. The software then performs a pixel count on the image and applies this scale to the bitmapped image. Alternatively, a user may input a drawing scale for a particular image, drawing or other two-dimensional reference. The drawing scale may, for example, be in inches: feet, centimeters: meters, or any other appropriate scale.

In some embodiments, a scale may be determined by manually measuring a room, a component, or other empirical basis for assessing a scale (including the ruler discussed above). Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length.

At step 106, a controller is operative to generate a user interface with dynamic components that may be manipulated by one or both of: user interaction and automated processes. Any or all of the components in a user interface may be converted to a version that allows a user to modify an attribute of the component, such as the length, size, beginning point, end point, thickness, or other attribute. In some embodiments, a boundary may be treated as a component and manipulated in like manner. The dynamic user interface allows for real-time interaction with the design plan, enabling users to make adjustments and immediately see the impact of those changes on the overall compliance assessment.

Other components included in the user interface may include, one or more of: AI engine predicted components, user training aspects, and AI training aspects. In some non-limiting examples of the present invention, a generative adversarial network may include a controller with an AI engine operative to generate a user interface that includes dynamic components. In some embodiments, a generative adversarial network may be trained based on a training database for initial AI feature recognition processes.

An interactive user interface may include one or more of: lines, arcs, or other geometric shapes and/or polygons. In some embodiments, the geometric shapes and/or polygons may comprise boundaries. The components may be dynamic in that they are further definable via user and/or machine manipulation. Components in the interactive user interface may be defined by one or more vertices. In general, a vertex is a data structure that can describe certain attributes, like the position of a point in a two-dimensional or three-dimensional space. It may also include other attributes, such as normal vectors, texture coordinates, colors, or other useful attributes.

At step 107, some embodiments may include a simplification or component refinement process that is performed by the controller. The component refinement process is functional to reduce a number of vertices generated by a transformation process executed via a controller generating the user interface and to further enhance an image included in the user interface. Improvements may include, by way of non-limiting example, one or more of: smooth an edge, define a start, or end point, associate a pattern of pixels with a predefined shape corresponding with a known component or otherwise modify a shape formed by a pattern of pixels.

In addition, some embodiments that utilize the recognition step transform features such as windows, doorways, vias and the like to other features and may remove them and/or replace them as elements-such as line segments, vectors, or polygons referenceable to other neighboring features. In a simplification step, one or more steps the AI performs (which may in some embodiments be referred to as an algorithm or a succession of algorithms) may make a determination that wall line segments, and other line segments represent a single element and then proceeds to merge them into a single element (line, vector, or polygon). In some embodiments, straight lines may be specified as a default for simplified elements, but it may also be possible to simplify collections of elements into other types of primitive or complex elements including polylines, polygons, arcs, circles, ellipses, splines, and non-uniform rational basis spline (NURBS) where a single feature object with definitional parameters may supplant a collection of lines and vertices.

The interaction of two elements at a vertex may define one or more new elements. For example, an intersection of two lines at a vertex may be assessed by the AI as an angle that is formed by this combination. As many construction plan drawings are rectilinear in nature, it may be that the simplification step inside a boundary can be considered a reduction in lines and vertices and replacing them with elements and/or polygons.

In another aspect, in some embodiments, one or both of a user and a controller may indicate a component type for a boundary. Component types may include, for example, one or more of line segments, polygons, multiple line segments, multiple polygons, and combinations of line segments and polygons.

At step 106A, in some embodiments, components presented in an interactive user interface may be analyzed by a user and refinements may be made to one or more components (e.g., size, shape and/or position of the component). In some embodiments, user modifications may also be input back to the AI engine train the AI engine. User modifications provided back to the AI Engine may be referenced to make subsequent AI processes more accurate and/or enable additional types of AI processes.

At step 108, a controller (such as, by way of non-limiting example, a cloud server) operative as an AI engine may create AI-predicted dynamic boundaries that are arranged to form a representation of submitted design plan that does not include the boundaries that bound it.

In various embodiments, a boundary or a set of boundaries may be used to define a unit, such as a residential unit, a commercial office unit, a common area unit, a water closet, a rest room, a bathroom, a public toilet, a manufacturing area, a recreational area, a dining area, or other area delineated according to a permitted use.

Some embodiments include an interface that enables user modifications of boundaries and areas defined by the modified boundaries. For example, a boundary may be selected and “dragged” to a new location. The user interface may enable a user to select a line end, a polygon portion, an apex, or other convenient portion and move the selected portion to a new position and thereby redefine the line and/or polygon. An area that includes a boundary as a border will be redefined based upon the modification to the boundary. As such, an area of a room or unit may be redefined by a user via the user interface. Changing an area of a room and/or unit may in turn be used as a basis for modifying an occupant load, defining an egress path, classifying a space, or other purposes.

For example, a change in a boundary may make an area larger. The larger area may be a basis for an increase in occupancy load. The larger area may also result in a longer path from the furthest point in the defined area to a point of egress (e.g., if a user chooses to use a worst case in determining an egress route).

At step 109, one or both of the user and an automated process on a controller may specify a code for which a compliance determination based upon the AI generated boundaries. In some embodiments, a selection of a set of codes to apply to the floor plan may be automated, for example, based upon a geographic or geopolitical area in which the building resides or will be constructed. In other embodiments, a user may specify a set of codes, such as, for example, a drop-down menu may indicate available codes, and a user may select one or more sets of codes to apply to the floor plan. Accordingly, by way of non-limiting example, a user may select that a set of floorplans be analyzed with the AI engine to assess compliance with Americans with Disabilities Act (ADA) compliance and National Fire protection Association code, or other code adopted by an authority having jurisdiction. This customizable compliance check provides that the system can adapt to the specific regulatory requirements of any project, providing accurate and relevant analysis for a wide range of building codes.

At step 110, a set of parameters for a selected set of code is applied to some or all of the dynamic components (e.g., a water closet) generated via the AI engine. This step provides that the compliance analysis is thorough, covering all relevant aspects of the design plan and providing a comprehensive assessment of whether the design or a portion of the design meets the required standards.

At step 111, the user interface or other output may be caused to display an indication of whether a design plan is in compliance with the selected set(s) of codes. In some preferred embodiments, a list of conditions required in order for a building to be in compliance, and an indication of why one or more of the conditions is met may be illustrated within a user interface or other output. For example, if the ADA is the basis for a set of codes to ascertain compliance with, a set of floorplans may be input into an AI engine and the AI engine will determine a value, and/or a range of values, which may be compared to the code requirements and a determination may be generated indicating whether the design plans describe a building that is in compliance with a selected set of codes. The ADA may require that a building described in the design plan has accessible routes that are at least thirty-six (36) inches wide. The AI engine may analyze a design plan and generate boundaries that may be manipulated by a user and then generate values for variables required to assess whether a condition the code sets forth is present in the design plan, such as the 36-inch-wide routes. This detailed compliance assessment allows the users to quickly identify and address any areas of non-compliance, providing a clear path to achieving full code compliance.

In generating a value, such as variable, the AI engine and/or the user may need to that one or more boundaries define a specific type of area, such as a bedroom, a hallway, or a stairwell. Each specific type of area may have specified variables associated with it. By way of non-limiting example, the user interface may employ a simple yes/no indicator for compliance with a requirement of a selected code. In other embodiments, the user interface may visually indicate portion of the design plan that was referenced in determining a state of compliance or on-compliance, e.g., a doorway that is thirty-six inches or more and therefore in compliance or a hallway that is only twenty-four inches wide and therefore not in compliance. The visual feedback helps users in quickly understanding and identifying the compliance status of each area (including water closet) of the design, providing a clear and intuitive interface for managing compliance.

Some specific embodiments may include a first portion of a user interface with delineated conditions for code compliance, such as, for example, a listing of sections of a code, an ability for a user to select a specific section of the code, and a link that brings up an interface with visual indicators illustrating a state of compliance (or non-compliance as the case may be) with the user selected section of code.

In some embodiments, the system may be configured to allow a user to interactively select a specific portion of the design plan within the user interface. This selection can be made by highlighting or drawing a boundary around the desired area (e.g., using a computer mouse), such as a specific room, water closet area, or any other defined space within the design plan. Upon selection, the AI engine receives the input and focuses its analysis on the selected portion of the design plan.

The AI engine then proceeds to analyze the selected portion by identifying relevant fixtures, architectural elements, and spatial arrangements within that area. It ascertains key design parameters such as the dimensions of the space, the placement and orientation of fixtures, and the clearance around the fixtures. Based on these parameters, the AI engine retrieves and applies the relevant building codes, regulations, or standards that are applicable to the selected portion.

For example, if the user selects a bathroom area within the design plan, the AI engine may apply codes related to accessibility, such as those outlined in the Americans with Disabilities Act (ADA) or other local building codes. The AI engine evaluates whether the selected area complies with these codes, taking into account factors such as the required clearances around the water closet, the height and placement of grab bars, the distance between the sink and the toilet, and the accessibility of egress paths.

If any aspect of the selected portion is found to be non-compliant, the AI engine can provide the user with automated suggestions for bringing the design into compliance. These suggestions may include repositioning fixtures, adjusting the size of the space, or altering the layout so that all code requirements are met.

At step 112, in another aspect, the present invention may use the AI to generate suggested modifications to a design plan in order to transition the design plan from a state of non-compliance to a state of compliance. In addition, the user interface may indicate other actions, in addition to a modification to the design plan, (e.g., reduce an occupant load) in order to conform to code. The AI-generated suggestions provide users with practical solutions for achieving compliance, streamlining the process of bringing a design plan into alignment with the required standards.

At step 113, a conclusion of whether a design plan is in compliance may be displayed as a user interface in an integrated fashion in relation to a replication of the two-dimensional reference (such as the design plan, architectural floor plan or technical drawing). The user interface may also be shown in a form that includes user modifiable elements, such as, but not limited to: polylines, polygons, arcs, circles, ellipses, splines, line segments, icons, points and other drawing features or combinations of lines and other elements.

Referring now to FIG. 1B, a high-level diagram illustrates components included in a system 120 that uses AI to generate an interactive user interface 125 and programmable apparatus (controller) 123 operative to execute method steps useful in determining compliance with a design plan or other architectural description. The system 120 is designed to streamline the compliance assessment process by leveraging AI to automate complex analyses, providing users with actionable insights in real-time.

According to some embodiments of the present invention, a two-dimensional reference 121, such as a design plan, floorplan, blueprint, or other document includes a pictorial representation 122 of at least a portion of a building. The pictorial representation 122 may include, for example, a portable document format (PDF) document, jpeg, png, or other essential non-dynamic file format, or a hardcopy document. The pictorial representation 122 includes an image descriptive of architectural aspects of the building, such as, by way of non-limiting example, one or more of: walls, doors, doorways, hallways, rooms, residential units, office units, bathrooms, water closets, stairs, stairwells, windows, fixtures, real estate accouterments, and the like. The AI engine is capable of analyzing these diverse architectural elements to assess compliance with relevant codes and standards.

The two-dimensional reference 121 may be electronically provided to a controller 123 running an AI engine. The controller 123 may include, for example, one or more of: a cloud server, an onsite server, a network server, or other computing device, capable of running executable software and thereby activating the AI engine. In some embodiments, the controller 123 may be part of a distributed computing system, allowing for parallel processing and faster analysis of large or complex design files. Presentation of the two-dimensional reference may include, for example, scanning a hardcopy version of the two-dimensional document into electronic format and transmitting the electronic format to the controller 123 running the AI engine. The system's flexibility in accepting both digital and digitized inputs facilitates integration into existing workflows with minimal disruption.

The controller is operative to generate a user interface 125 on a user computing device 126. The user computing device may include a smart device, workstation, tablet, laptop or other user equipment with a processor, storage. and display. The user interface 125 is designed to be intuitive and responsive, allowing users to interact with the design plan seamlessly and make adjustments as needed.

The user interface 125 includes a reproduction of the pictorial representation 122 and an overlay 124 with one or more user manipulatable components, such as, by way of non-limiting example: boundaries, line segments, polygons, images, icons, points, and the like. The line segments may have calculated lengths that may be mathematically manipulated and/or summarized. For example, a user can adjust the boundary of a room, or line of a water closet feature, and the system can automatically recalculate the area or dimensions and update any related compliance checks. Aspects such as polygons, line segments, shapes, icons, and points may be counted, added, subtracted, extrapolated, and other functions performed on them. These manipulations allow for dynamic and iterative design processes, enabling users to explore multiple compliance scenarios efficiently.

In addition, renditions of the user interface 125 may be created and saved, and/or communicated to other users, or controllers, compared to subsequent interface renditions, archived and/or submitted to additional AI analysis.

In some embodiments, a first user interface 125 rendition may be modified by a user to create a second user interface 125 and submitted to AI analysis to ascertain compliance with a selected code. This feature may support collaborative workflows, allowing multiple stakeholders to review and modify design plans, while maintaining a clear history of changes and compliance checks. Some embodiments may also calculate costs, expenses, man hours or other variables associated with changes to a design plan in order to bring the design plan into compliance. For example, if a design adjustment requires additional materials or labor, the system can provide a detailed cost estimate, helping project managers make informed decisions. Change order renditions provided as options to bring a design plan into compliance with a selected code may also be provided with a unique identifier, time and/or date stamped to create a continuum of work, as related to original projects and compliance-initiated changes. Each of the items in the continuum of work may be stored and subsequently used for ascertaining the eventual compliance of a building with each selected code.

Referring now to FIG. 1C, an exemplary two-dimensional representation of at least a portion 130 of a design plan for a building includes multiple dwelling units and one or more water closet areas. The design plan or the portion 130, is similar to the two-dimensional reference 121 that may be fed into the controller 123 in a system utilizing artificial intelligence (AI) for compliance analysis. The AI engine within the controller 123 processes the design plan to identify various architectural and spatial components, and assess compliance with relevant building codes, particularly those concerning water closets including access paths from various dwelling spaces to the water closets and from the water closets to egress points.

The design plan portion 130 comprises a variety of dwelling spaces 135, 136, 137, and 138. The dwelling spaces 135-138 may represent different functional areas within a building, such as residential units, office areas, dining areas, kitchens, or drawing areas, depending on the design and purpose of the building. For example, dwelling space 135 may be a residential unit with a combination of a bedroom and kitchenette. In contrast, the space 136 may be an office area, comprising a workspace, meeting room, and restroom. The versatility of the design allows for different interpretations of these spaces based on the specific requirements of the building in question.

The AI engine within the controller 123 begins its analysis by receiving the design plan or the portion 130 of the design plan and representing various components as dynamic elements within a user-interactive interface. These dynamic components may include structural elements such as walls, doors, and fixtures, or geometric representations like lines, polygons, and vectors that delineate specific areas and paths within the design plan. The controller 123 identifies water closet areas, within the design plan portion 130, by leveraging its AI engine to recognize key fixtures and components typically found in such areas, including but not limited to water closets 133A-133B, lavatories, grab bars, toilet paper dispensers, flush controls, urinals, and hand dryers. The AI engine may analyze the design plan to locate these elements based on a predefined criteria, such as their spatial arrangement, dimensions, and proximity to other relevant features like walls, doorways, and partitions. The identification of water closet areas may also involve detecting the location and boundaries of these areas, so that all relevant fixtures and spatial constraints within or around the water closet areas are accurately ascertained by the controller 123 for compliance analysis. The identification of water closets 133A-133B and other surrounding fixtures, may be used in compliance analysis related to the water closets.

The AI engine or the controller 123 may also identify access paths 131 from various dwelling spaces 135-138 to the water closets 133A-133B as well as from the water closets 133A-133B to an egress point 132. The AI engine may also calculate lengths of these paths and analyze their compliance with relevant codes, such as for determining that the routes are unobstructed and meet the minimum required width for accessibility. The AI engine may also determine (e.g., based on a scale 217 as discussed below in FIGS. 2A-2B) the total distances from each water closet to the nearest egress point 132 which in this case includes a stairwell 132A, and to the dwelling spaces 135-138.

For example, the AI engine determines parameters such as the total distance 131A between the water closet 133A and the egress point 132, the total distance 131B between the water closet 133B and the egress point 132, and the total distance 131C between dwelling space 135 and water closet 133A. These distances may be compared against a set of conditions relating to water closet compliance, which may include factors such as maximum allowable travel distance, path width, and the presence of any obstacles.

For example, if the design plan indicates that the distance 131A from water closet 133A to the egress point 132 exceeds the maximum allowed by the relevant code, the AI engine may flag this as non-compliant and provide suggestions for modifications, such as relocating the water closet 133A or adding additional egress points. The distance between the water closets 133A-133B and the egress point 132 should not exceed a maximum allowable distance, as these routes may be critical for emergency evacuation. The water closets within the prescribed distances are required to facilitate safe and swift evacuation, minimizing risks during emergencies by providing accessible and direct paths to exit points. Similarly, if the path 131 from dwelling space 137 to the water closets 133A-133B or the egress point 132 is too narrow or includes obstructions that violate accessibility standards, the AI may identify these issues and recommend corrective actions.

Furthermore, in some embodiments, if the distance 131C between the dwelling space 135 and the nearest water closet 133A exceeds a defined allowable distance (threshold) as set by the relevant building codes or accessibility standards, the controller 123 or the AI engine will flag this as non-compliant. Upon identifying this non-compliance, the controller 123 may also automatically generate suggestions for rectification, such as relocating the water closet 133A to a more central location, adding an additional water closet closer to the dwelling space 135, or reconfiguring the layout of the space to reduce the distance.

The AI engine's analysis is not limited to simple distance measurements. It may also consider the spatial arrangement and functionality of the design plan. For example, it may assess whether the water closets 133A-133B are adequately separated from other functional spaces like kitchens or dining areas to meet health and safety regulations. The AI engine may also evaluate whether the design allows for privacy and convenience, so that the water closets 133A-133B are easily accessible without disrupting the flow of the building's layout.

In some embodiments, the AI engine may incorporate additional factors into its analysis, such as the materials used in the construction of the water closets or the presence of features like grab bars, which are essential for accessibility. The AI engine may also simulate different emergency scenarios to evaluate how quickly occupants can evacuate the building using the identified paths 131.

As part of the interactive user interface 125, the AI engine generates a visual representation of the compliance analysis. This may include color-coded overlays on the design plan 130 to indicate areas of compliance (e.g., green for compliant paths or areas, and red for non-compliant paths or areas). The interface 125 may also allow users to interact with the design plan portion 130 dynamically, adjusting parameters like the placement of water closets or egress points and instantly seeing how these changes affect compliance.

For example, if the AI engine identifies that the distance 131B from water closet 133B to the egress point 132 is non-compliant due to an obstruction, or exceeding a threshold limit for allowable distance, the user may use the interface 125 to reposition the water closet 133B or alter the path 131 to bypass the obstruction or reduce the distance 131B. The AI engine may then recalculate the distances and update the compliance status in real time.

Moreover, the AI engine may also generate detailed reports on the compliance analysis which include not only the measurements and comparisons but also recommendations for achieving compliance, potential costs of implementing these recommendations, and timelines for completing the necessary modifications. For example, if the design plan portion 130 requires additional egress points to meet code requirements, the AI engine may estimate the construction costs and provide a phased plan for integrating these changes into the overall project timeline.

Additionally, the AI engine can store historical data on previous compliance checks and design iterations, allowing users to track the evolution of the building design over time. The historical data may be invaluable for project managers and architects, providing a clear record of how and why specific design decisions were made.

Referring now to FIG. 1D, this illustration presents various exemplary views of water closet areas 147A-148A and 147-149, which may be extracted by the controller 123 from two-dimensional design plans for compliance determination in some embodiments of the present invention. FIG. 1D details various spatial dimensions and configurations necessary for determining compliance with relevant building codes, particularly focusing on accessibility standards.

The water closet area 147A depicts a layout where a minimum clearance space of 60 inches by 56 inches is provided around the water closet 140, as delineated by the dashed boundary lines 142 and 145. These dimensions may be required to determine sufficient maneuvering space, particularly for individuals using wheelchairs. The centerline 141A of the water closet 141 may be determined by the AI engine, which is used for evaluating the symmetry and alignment of fixtures within the water closet area 148A. For example, the AI engine can assess whether fixtures are evenly spaced relative to the centerline 141A to determine ease of use and compliance with accessibility standards.

The invention generally relates to AI analysis to determine whether a building, as described in a design plan or other two-dimensional image, meets or exceeds the requirements set forth by a relevant code, particularly concerning water closet areas. For example, the AI engine can determine whether an area surrounding a water closet provides sufficient clearance as specified by an authority having jurisdiction. The AI engine automatically detects and evaluates these conditions by analyzing the spatial arrangement and dimensions provided in or ascertained from the design plan, for accurate compliance determination.

To determine that an occupant, such as a person using a wheelchair, has adequate space to transfer from their wheelchair to the water closets 140-141, accessibility codes specified by an authority having jurisdiction may mandate certain clearances, such as those indicated by 142-145 around the water closets 140-141. The AI engine can simulate the movement of a wheelchair within this specified clearance, providing dynamic feedback on whether the space is functionally adequate for the user, beyond mere dimensional compliance.

For example, ADA Standards, applicable primarily to common areas such as restaurant restrooms, and ANSI standards, typically applied to dwelling units in some jurisdictions, require a 60-inch-wide clearance (142) and a 56-inch-long clearance (145) around a water closet 140. The AI engine automatically verifies these dimensions within the design plan and flags any deviations from these standards. Additionally, it can cross-reference these measurements with other relevant codes, such as local or international standards, to provide a comprehensive compliance assessment.

Another important aspect is determining that no other fixtures are placed within the required clearance space around the water closet. For example, the AI engine may analyze a design plan to determine whether a lavatory 146 or other fixtures are improperly placed within the permitted clearance. The AI system can identify these fixtures and assess whether their placement violates the required clearance, providing immediate feedback and suggestions for repositioning if necessary.

The ANSI standards permit a lavatory overlap where the clearance is increased to 60 inches by 66 inches when an edge of the lavatory is placed 18 inches or more from the centerline 141A of the water closet 141. The AI engine can detect this specific condition and may automatically adjust its compliance assessment based on the presence and positioning of a lavatory within the clearance zone. The system may also generate visual indicators within the user interface to clearly show the required overlap area, helping users to visualize and understand the implications of their design choices.

In jurisdictions where codes such as those from the Federal Housing Administration (FHA) apply, which may permit a lavatory overlap with less stringent dimensions, the AI engine can automatically adjust its analysis parameters. This allows the correct standards to be applied based on the specific regulatory context, providing users with the flexibility needed to navigate the complexities of varying regional and national codes.

In some embodiments, particularly in regions like Texas and Florida where only the FHA standards may need to be referenced for dwelling units, which are generally less strict than ANSI requirements, the AI system can automatically switch between these standards based on the project's location. This capability streamlines the compliance process, reducing the risk of applying incorrect standards and hence allowing the design to meet all relevant requirements.

Additionally, in some embodiments, a user such as an architect, designer, or support person can specify in an interactive user interface which units are “Type A” or otherwise indicate which units should adhere to ANSI criteria or more stringent standards, such as ADA: 60 inches wide by 56 inches long; ANSI: 60 inches wide by 56 inches long or 60 inches wide by 66 inches long with lavatory; and FHA: 60 inches wide by 56 inches long, or 48 inches wide by 66 inches with lavatory 33 inches from the side wall, or 48 inches by 56 inches with lavatory 33 inches from the side wall. The AI system can accommodate these user inputs, dynamically adjusting its compliance checks based on the selected criteria and providing a summary of applicable standards, highlighting any specific areas of non-compliance that need to be addressed.

Moreover, in some embodiments, the design plan may be analyzed to identify a wall-hung lavatory and ascertain its location concerning a water closet within water closet areas 147-148, while other embodiments may ascertain a water closet within water closet area 149 without a nearby lavatory. The AI engine is capable of automatically distinguishing between different types of lavatories and their placements, providing detailed analysis to determine that all relevant fixtures are correctly identified and assessed for compliance. In instances where a lavatory is not detected, the system can alert the user to potential oversights or non-compliance, allowing for corrective actions before finalizing the design.

Referring now to FIG. 1E, the illustration presents various exemplary views of water closets 150, 152, and urinals 154-155, which may be extracted by the controller 123 from two-dimensional design plans for compliance determination in some embodiments of the present invention.

The first section of FIG. 1E focuses on two distinct types of water closets designed for accessibility: a Wheelchair Accessible Water Closet 150 and an Ambulatory Accessible Water Closet 152. For the Wheelchair Accessible Water Closet 150, the compliant distance from the wall to the centerline 151 of the water closet is required (as per some building codes) to be between 16-18 inches, as shown by the dimension line. The AI engine, upon analyzing the design plan, may assess whether this distance is accurately reflected in a layout and may flag any discrepancies that fall outside the 16-18-inch range. Such compliance checks may be useful in determining that the water closet area meets the Americans with Disabilities Act (ADA) standards, which mandate specific spatial requirements to accommodate the needs of wheelchair users.

Similarly, the Ambulatory Accessible Water Closet 152 may require a different range for compliance, with the distance from the wall to the centerline needing to be between 17-19 inches, as indicated by distance 153. This type of water closet is designed for individuals who are ambulatory but may require additional support, such as those using walking aids. The AI engine's analysis may compare the design plan's dimensions against these requirements, so that the necessary clearances are provided for safe and convenient use. If the distance is found to be non-compliant, the system may suggest adjustments, such as repositioning the water closet or altering the wall configuration to meet the required standards.

Moving to the second half of FIG. 1E, the illustration includes two types of urinals: a Wall Hung Type 154 and a Stall Type 155. For the Wall Hung Type urinal 154, the compliance requirement focuses on the height from the floor level, which should be about 17 inches, as denoted by the dimension line. The height of urinals should be within compliant ranges so that the urinals are accessible to individuals with disabilities, particularly those in wheelchairs, who may need a lower fixture height to use the urinal comfortably. The AI engine may evaluate whether this height is met within the design plan and flag any instances where the urinal is installed too high or too low, offering recommendations for adjustments where necessary.

Both urinals, 154 and 155, also have a specified width from the wall that should be about 13 and a half inches, as indicated by the respective dimension lines. The AI engine may also assess the spacing between the urinals and the adjacent walls or partitions, to determine that the design complies with relevant building codes and accessibility standards. If the spacing is insufficient, the AI system may suggest repositioning the urinals or adjusting the partition layout to provide the necessary clearance.

In addition to these specific measurements, the AI engine may also analyze other aspects of the water closets and urinals, such as the overall layout of the restroom, the placement of support bars or grab bars, and the provision of adequate turning space for wheelchair users. For example, if the water closet is positioned too close to a sidewall or another fixture, the AI engine may flag this as a potential non-compliance issue and suggest relocating the water closet or adjusting the design to provide the required clearances.

According to some embodiments, an AI engine may be trained to recognize a pattern of pixels, or an image, or a series of lines and polygons as a water closet. The AI engine may also ascertain physical parameters set forth in a design plan that pertain to conditions for which parameters have been set forth by an authority having jurisdiction.

Still further, in some embodiments, an AI engine, and/or a user may specify a margin of variance permissible during analysis of a design plan. A margin of variance may include, for example, a percentage of compliance of relative locations of pixels included in a pattern, or variance of polygons and lines included in a pattern.

Referring now to FIG. 1F, it illustrates an exemplary inside view of a water closet area 160 extracted by the controller 123 from a two-dimensional design plan for compliance determination. The water closet area 160 includes several essential fixtures, such as a water closet 161, a grab bar 162, a shower 163, a water tap 164, a hand-wash basin 165, and a floor drain 166. These elements may be used (by the controller or AI engine) in determining whether the water closet area complies with relevant accessibility and safety codes, especially in environments where users may have disabilities or other physical limitations.

The AI engine, part of the controller 123, may identify and analyze these fixtures. It can automatically recognize various elements within the water closet area 160 by comparing the design plan to a database of known fixtures. The water closet area 160 itself can be determined by the AI engine based on recognizing the fixtures that are generally used within a water closet. For example, the AI engine can automatically identify a water closet 161 by its characteristic shape, size, and position relative to other features like the grab bar 162 or the hand-wash basin 165. Similarly, the AI engine can distinguish between different types of fixtures, such as a shower 163 and a floor drain 166, based on their geometric patterns and associated components like faucets, handles, or drainage grates.

The water closet area 160 comprises several non-compliant features, which the AI engine can identify during its compliance analysis according to a relevant code for water closets. These non-compliant features may relate to various aspects, including architectural layout, fixture placement, sizes, and heights. For example, the shower 163 may be located directly above the water closet 161. This placement is highly unconventional and non-compliant with most building codes. Typically, a shower is expected to be located in a separate area from the toilet to avoid water from the shower spilling directly onto the toilet, which can create unsanitary conditions and pose a slip hazard. The AI engine may flag this as a non-compliant feature and may suggest relocating the shower 163 to a separate section of the bathroom or water closet area 160, away from the water closet 161.

Another example of non-compliance includes a grab bar 162, which is positioned behind a user 167 who is seated on the water closet 161. Grab bars are highly useful for users with mobility impairments, as they provide support and stability when transferring on or off the toilet. However, in this scenario, the placement of the grab bar 162 behind the user 167 is not practical or functional. It is challenging for the user 167 to reach the bar in this position, defeating its purpose. The AI engine may suggest repositioning the grab bar 162 to the side of the water closet 161, within easy reach of the user 167. The AI engine may also suggest installing a greater number of grab bars. For example, a grab bar can be mounted on the wall adjacent to the toilet at a height specified by accessibility standards (e.g., 33 to 36 inches above the floor), so that it is both reachable and supportive.

The hand-wash basin 165 may also present a compliance issue. The design shows that the basin 165 does not have a water tap attached directly to it; instead, the water tap 164 is positioned at a random location on a wall. This configuration is impractical and non-compliant with standard compliance codes, which typically require that water taps be directly connected to the basin 165 to provide easy and hygienic access to water for washing hands. The AI engine may identify this inconsistency and recommend repositioning the water tap 164 to be directly above or integrated with the hand-wash basin 165.

Furthermore, the floor drain 166 is also improperly placed. The drain's current position may not effectively manage water runoff, especially given the unusual placement of the shower 163 directly above the water closet 161. Proper placement of a floor drain is required to prevent water accumulation, which can lead to slipping hazards and water damage over time. The AI engine may likely suggest relocating the floor drain 166 to a position that aligns with the main sources of water flow, such as at a corner in the water closet area 160. Additionally, the AI may also determine if the drain is sloped correctly towards the drain to facilitate efficient water removal, thereby enhancing the overall safety and functionality of the water closet area 160.

The AI engine's ability to evaluate the design parameters, such as height, width, position, and placement of various fixtures, allows it to identify non-compliant features effectively. For example, the AI can compare the actual height of the grab bar 162 against the required standards and flag any discrepancies. It can also analyze the distance between the water closet 161 and other fixtures to determine if there is enough clearance for safe and comfortable use. In situations where non-compliance is detected, the AI engine does not merely flag the issues but can also generate automated suggestions for bringing the design into compliance. For example, it may recommend moving the grab bar 162 to a compliant location, adjusting the height of the hand-wash basin 165, or repositioning the shower 163 to avoid overlap with the water closet 161. The automated suggestion can be provided in augmented visual form, e.g., the AI engine may show AI generated grab bars positioned at compliant locations and heights around the water closet 161 (e.g., as shown in FIG. 1I).

In some embodiments, the AI engine can simulate different scenarios within the water closet area 160 to assess the effectiveness of various compliance suggestions. For example, it may model the movement of a user 167 within the space to determine the most ergonomic placement of the grab bar 162 or simulate water flow from the shower 163 to identify the optimal location for the floor drain 166. One such example of simulation is discussed below in FIG. 1I. By leveraging these simulations, the AI engine can offer highly tailored and practical solutions that not only meet compliance requirements but also enhance the overall user experience.

Referring now to FIG. 1G, it illustrates another exemplary inside view of a water closet area or bathroom 170 extracted by the controller 123 from a two-dimensional design plan or from a portion of the design plan for compliance determination. The water closet area 170 includes several exemplary and non-limiting features and fixtures: a water closet 171, a grab bar 172, a hand dryer 173, and a cupboard 174. These elements may be used in assessing the overall compliance of the bathroom space with relevant accessibility and safety codes.

The AI engine or the controller 123 is tasked with identifying both compliant and non-compliant features within the water closet area 170. The AI engine accomplishes this by comparing the extracted design features against a database of compliance standards, which may include regulations such as the Americans with Disabilities Act (ADA), the International Building Code (IBC), and other jurisdiction-specific building codes. By analyzing the dimensions, placements, and relationships between these fixtures, the AI engine can determine whether the design plan meets the required standards or if modifications are needed to achieve compliance.

The water closet area 170 contains several non-compliant features, which the AI engine can identify during its compliance analysis. For example, the grab bar 172 is intended to provide support to the user 177 while using the water closet 171. However, the placement of the grab bar may not offer adequate support. Typically, grab bars should be positioned at a height that allows the user to easily grasp them while sitting or standing, usually between 33 to 36 inches above the floor. In this illustration, the grab bar 172 is positioned too far from the water closet 171, making it difficult for the user 177 to reach it without straining. The design of the grab bar 172 may also be non-compliant, not providing adequate hand support, or may comprise a smooth surface which can lead to hand slippage. The AI engine may likely flag this as a non-compliant feature and suggest repositioning the grab bar closer to the water closet 171, within easy reach of the user. The AI engine may also suggest different designs and shapes for the grab bars. Additionally, the AI may recommend that the grab bar be placed horizontally on the side wall, within 12 inches from the back wall, as this is a common placement guideline that provides maximum support.

Another significant issue in this design is the placement of the hand dryer 173. Hand dryers are typically used immediately after washing hands, so they should be positioned near a hand wash basin for convenience. However, in this scenario, the hand dryer 173 is located near the water closet 171 and above the cupboard 174, which is both impractical and non-compliant. The AI engine may recognize that this placement does not follow the logical sequence of bathroom use, where a user would wash their hands and then need to dry them without having to move across the room. The AI may suggest relocating the hand dryer 173 to a more appropriate location, preferably adjacent to a hand wash basin (which, although not shown in this figure, would be considered in the full design plan).

The cupboard 174 also presents a compliance challenge. In its current position, the cupboard 174 is placed within a distance 175 from the water closet 171. This distance 175 may be less than the allowable distance for a fixture to avoid obstruction and provide sufficient front clearance for the user 177. For example, ADA guidelines typically require at least 30 inches by 48 inches of clear floor space in front of the water closet to accommodate wheelchair users and provide easy transfer. The placement of the cupboard 174 within this space can obstruct the user's movement and make the bathroom less accessible. The AI engine may likely flag this issue and recommend either relocating the cupboard outside of the clear floor space or modifying its design so that it does not impede the user's ability to maneuver around the bathroom safely.

In addition to identifying these non-compliant features, the AI engine is also capable of suggesting improvements that go beyond mere compliance. For example, while the grab bar 172 can be repositioned to meet the minimum requirements, the AI may also suggest upgrading to a more aesthetically pleasing design or using a material that is both durable and visually appealing, such as stainless steel with a brushed finish. Similarly, the AI may recommend that the hand dryer 173 be replaced with a model that is quieter or more energy-efficient, balancing compliance with user comfort and operational efficiency.

The AI engine may also analyze other potential non-compliant features within the water closet area 170 that are not explicitly depicted in FIG. 1G. For example, it may evaluate the lighting within the bathroom to determine that it meets minimum luminance requirements, which are useful for users with visual impairments. Inadequate lighting can create safety hazards, so the AI may suggest installing additional light fixtures or upgrading existing ones to provide more even illumination throughout the space.

Moreover, the AI engine may assess the overall layout of the bathroom to determine that all fixtures are placed logically and conveniently. For example, the proximity of the water closet 171 to the bathroom entrance may be evaluated to determine that the user 177 can easily access the toilet without unnecessary obstacles. The AI may also suggest adding a second grab bar on the opposite wall to provide additional support for users who may need it when entering or exiting the bathroom.

In scenarios where the water closet area 170 includes compliant features, the AI engine may still offer suggestions for improvement. For example, if the water closet 171 meets the height and clearance requirements, the AI may recommend using a wall-mounted toilet instead of a floor-mounted one to free up additional floor space, making the bathroom feel more open and less cramped. Additionally, the AI may propose upgrading the cupboard 174 to include soft-close hinges or integrated lighting, enhancing both the functionality and aesthetics of the bathroom.

Referring now to FIG. 1H, it illustrates another exemplary inside view of a water closet area or bathroom 180 extracted by the controller 123 from a two-dimensional design plan or from a portion of the design plan for compliance determination. The water closet area 180 includes several exemplary fixtures and components, such as a water closet 181, a hand wash basin 182, a ventilation fixture 183, a soap dispenser 184, a mirror 185, a drainage pipe 186, a toilet paper holder 187A, and a bidet or water jet 187B. These fixtures (including their designs and placements) may be analyzed by the AI engine within the controller 123 to assess whether they are compliant with relevant building codes and accessibility standards.

The water closet area 180 may contain multiple non-compliant features, which the AI engine can detect during its compliance analysis based on the guidelines set forth by applicable code. These non-compliant features are identified based on design parameters such as, but not limited to: distances between fixtures, fixture designs, their placement, alignment, and overall functionality within the space.

One of the exemplary non-compliant features in this layout is the proximity of the hand wash basin 182 to the water closet 181. According to standard guidelines, there should be a minimum distance between the hand wash basin and the toilet to provide ease of movement and to maintain hygiene. For example, the ADA suggests that there should be at least 15 inches (38 cm) of clearance from the centerline of the toilet to any adjacent fixture. However, in this scenario, the actual distance 188 between the centerline 189 of the water closet 181 and the hand wash basin 182 falls short of this requirement. The AI engine, upon detecting this non-compliance, may suggest moving the hand wash basin further away from the toilet to meet the required clearance, thereby providing that the bathroom is accessible and comfortable for all users, especially those using mobility aids.

Another non-compliant feature involves the mirror 185 and the hand wash basin 182. Ideally, the mirror should be aligned with the basin to allow users to see themselves while washing their hands. This alignment is useful not only for functionality but also for determining that the bathroom meets relevant standards. In the current design, the mirror 185 is not aligned with the hand wash basin 182 which can lead to inconvenience and frustration for users. The AI engine may identify this misalignment and recommend repositioning the basin 182 directly below the mirror 185, so that it is at an appropriate height and angle for all users, including those in wheelchairs.

The placement of the soap dispenser 184 also presents a compliance issue. In a functional bathroom design, the soap dispenser should be located near the hand wash basin to facilitate easy access while washing hands. However, in this layout, the dispenser is placed at an awkward distance from the basin 182, making it inconvenient for users. The AI engine may flag this as a non-compliant feature and suggest relocating the soap dispenser 184 closer to the hand wash basin 182 (after providing appropriate placement for the basin 182 itself), ideally within an arm's reach of someone standing at the basin 182.

Similarly, the toilet paper holder 187A and the bidet 187B are incorrectly positioned. These fixtures should be placed close to the water closet 181 so that they are within easy reach of a user seated on the water closet 181. In the current design, the placement of these fixtures is too far from the water closet 181, which can make it difficult for users to access them without straining or moving uncomfortably. The AI engine may likely recommend repositioning these fixtures closer to the water closet 181, e.g., within a distance of 7 to 9 inches (18 to 23 cm) from the front of the toilet, which is typically considered optimal for user convenience and compliance with accessibility standards.

The ventilation fixture 183 is another area of concern. Proper ventilation is required in a bathroom to provide adequate airflow and to prevent the buildup of moisture, which can lead to mold and mildew. The current ventilation opening 183 is insufficient in size for the bathroom's needs, and also there is no exhaust fan, which is essential for maintaining air quality in enclosed spaces. The AI engine may likely flag this as a non-compliant feature and suggest either increasing the size of the ventilation fixture 183 or installing an exhaust fan to provide proper ventilation.

Additionally, the drainage pipe 186 beneath the water closet 181 is positioned in a manner that may not comply with plumbing codes. Proper drainage is essential to prevent leaks so that wastewater is efficiently directed away from the bathroom. The AI engine may assess whether the drainage pipe's position and angle meet the required standards, and if not, suggest adjustments so that the pipe 186 is correctly aligned and securely installed. The drainage pipe 186 should not be exposed or visible in the water closet area 180.

In some embodiments, the AI engine may also assess other features not explicitly shown in FIG. 1H. For example, it may evaluate the height of the hand wash basin 182 to determine if it is accessible to all users or not, including those in wheelchairs. The ADA specifies that the basin's rim should be no higher than 34 inches (86 cm) from the floor, with a knee clearance of at least 27 inches (69 cm) underneath. If the basin in FIG. 1H does not meet these requirements, the AI engine may flag this as non-compliant and suggest lowering the basin 182 to the appropriate height.

The AI engine may also evaluate the overall layout of the bathroom to determine if there is adequate maneuvering space for users or not, particularly those with mobility aids. For example, it can calculate the clear floor space around the water closet 181 to determine that it meets the minimum required dimensions for a wheelchair to turn or approach the toilet. If the space is too cramped, the AI engine may recommend reconfiguring the bathroom layout to provide more clearance, possibly by moving or removing certain fixtures.

Referring now to FIG. 1I, it illustrates an exemplary simulation method used by the AI engine for compliance analysis in some embodiments of the present invention. FIG. 1I shows an exemplary water closet area 190 identified by the AI engine from a design plan or a portion of a floor plan based on recognizing features or fixtures generally found in or around a bathroom. The AI engine not only identifies these features but also determines the location and boundaries of the water closet area 190 within the design plan as part of its comprehensive analysis.

The water closet area 190 includes several fixtures typically found in accessible bathroom designs, such as a toilet 191, grab bars 192A and 192B, a soap dispenser 193, and a backrest 194. These fixtures are generally used for the safety and accessibility of the bathroom for users, especially those with disabilities. For example, grab bars 192A and 192B are installed to provide support for users when transferring onto or off the toilet 191, helping to prevent falls and enabling independent use of the bathroom. The backrest 194 may provide additional support for users who may need to rest while seated on the toilet 191, which may particularly be important for individuals with lower back pain or limited core strength.

In addition to these fixtures, the water closet area 190 may also include other common elements such as a hand wash basin, towel dispensers, a mirror, or even emergency pull cords in facilities designed for users with severe mobility impairments. The AI engine is capable of identifying and analyzing each of these components to determine if they meet the relevant accessibility standards or not.

To determine code compliance, particularly in relation to ease of accessibility, the AI engine may employ advanced simulation techniques. One such technique involves simulating the movement of various shapes and types of wheelchairs within the water closet area 190. This simulation allows the AI engine to assess whether the layout of the bathroom provides adequate space for a wheelchair user to maneuver comfortably. In FIG. 1I, the AI engine is depicted simulating a wheelchair 196 with a virtual person 195 sitting in it. The virtual person 195 represents a user with disabilities, and the simulation is used to determine if there is sufficient front clearance for the wheelchair 196 to rotate within the space 197 in front of the toilet 191.

The rotation simulation is represented by an arc 198, which illustrates the path the wheelchair 196 may take when turning within the space 197. This type of simulation helps the AI engine to determine if the water closet area 190 complies with standards such as those set by a relevant authority. The ADA, for example, requires at least 60 inches (1525 mm) of clear space in front of the toilet for a forward approach, which allows the user to maneuver their wheelchair into position.

The AI engine does not limit itself to simulating only one type of wheelchair; it can simulate multiple wheelchair sizes and configurations, including manual wheelchairs, power wheelchairs, and mobility scooters. Each of these devices has different space requirements and turning radii, so the AI engine may consider these variations when determining compliance. For example, power wheelchairs typically have larger footprints and require more space to turn than manual wheelchairs. By simulating different types of wheelchairs, the AI engine can provide a comprehensive analysis of whether the water closet area 190 is accessible to all potential users.

Furthermore, the AI engine may also simulate different scenarios to test other aspects of the water closet's compliance. For example, it may simulate the movement of a user transferring from the wheelchair to the toilet to determine that the grab bars 192A and 192B are positioned within the required reach range and at the correct height. The ADA specifies that grab bars should be mounted at a height of 33 to 36 inches (840 to 915 mm) from the floor and extend at least 12 inches (305 mm) beyond the front of the toilet to provide adequate support. The AI engine may evaluate whether the existing installation meets these standards and suggest modifications if necessary.

Another type of simulation may involve testing the reachability of the soap dispenser 193 and other controls (e.g., light switches, flush buttons, racks, item holders etc.) from a seated position in the wheelchair. This may also determine if all fixtures are within easy reach, which is essential for users with limited upper body strength or mobility. The AI engine may check if the dispenser is mounted between 15 and 48 inches (380 to 1220 mm) from the floor, as recommended by accessibility guidelines.

In addition to accessibility, the AI engine can simulate emergency scenarios to evaluate the safety features of the water closet area 190. For example, it may simulate an evacuation process, assessing the layout allows a wheelchair user to quickly exit the bathroom in case of an emergency. This may involve checking the path of egress from the water closet to the nearest exit, assessing that there are no obstructions or narrow passages that can hinder quick movement (as discussed in FIG. 1C above).

The AI engine may also assess the placement of the backrest 194 to determine if it provides adequate support without interfering with the user's ability to use the toilet 191 or transfer from the wheelchair 196. If the backrest 194 is too high, too low, or incorrectly angled, it may pose a risk to the user, and the AI engine can flag this as a non-compliant feature.

Moreover, the AI engine can also simulate the use of other assistive devices within the space, such as transfer boards or hoists, to determine if the bathroom can accommodate these tools without compromising accessibility. For example, the AI may check if there is enough space around the toilet 191 to use a transfer board or if the grab bars 192A-192B are sturdy enough to support a hoist system.

In cases where the AI engine detects non-compliant features, it may generate automated suggestions to bring the design into compliance. For example, if the simulation reveals that the front clearance (in space 197) is insufficient for wheelchair rotation (198), the AI may suggest repositioning the toilet 191 or adjusting the layout of other fixtures to create more space. Similarly, if the grab bars 192A and 192B are found to be improperly placed, the AI may recommend new mounting locations that better support user needs.

Referring now to FIG. 2A, a given two-dimensional reference 200 may have a number of elements that an observer and/or an AI engine may classify as features 201-209 such as, for example, one or more of: exterior walls 201; interior walls 202; doorways 204; windows 203; plumbing components, such as sinks 205, toilets 206, showers 207, water closets or other water or gas related items; kitchen counters 209 and the like. The two-dimensional references 200 may also include narrative or text 208 of various kinds throughout the two-dimensional references. These features collectively represent the architectural layout and utility elements used by the AI engine for functional analysis and design optimization.

In some embodiments, the AI engine may also recognize additional structural elements, such as load-bearing walls, HVAC systems, electrical conduits, and fire safety installations, which may be used for comprehensive compliance assessments and construction planning. The AI engine can differentiate between these various features based on their geometric properties, spatial relationships, and annotations within the design plan. For example, the AI engine may distinguish between a kitchen counter and a bathroom vanity by recognizing the specific fixtures associated with each, such as a sink versus a stove.

Identification and characterization of various features 201-209 and/or text may be included in the input two-dimensional reference 200. Generation of values for variables included in generating a bid may be facilitated by splitting features into groups called ‘disparate features’ 201-209 and boundary definitions and generation of a numerical value associated with the features, wherein numerical values may include one or more of: a quantity of a particular type of feature; size parameters associated with features, such as the square area of a wall or floor; complexity of features (e.g. a number of angles or curves included in a perimeter of an area; a type of hardware that may be used to construct a portion of a building, a quantity of a type of hardware that may be used to construct a portion of the building; or other variable value. For example, the AI engine may calculate the total linear footage of interior walls required for a specific room (including water closet) or the amount of tiling needed for a bathroom floor based on the identified boundaries, and features. In some embodiments, the AI engine may also provide cost estimations associated with these features, such as the cost of materials and labor required to install a specific type of window or the total expense for plumbing installations within a designated area.

In some embodiments, a recognition step may function to replace or ignore a feature. For example, for a task goal of the result shown in FIG. 2B, features such as windows 203, and doorways, 204, may be recognized and replaced with other features consistent with exterior walls 201 or interior walls 202 (as shown in FIG. 2A). This replacement may be useful when focusing on structural integrity or load distribution analysis, where openings like windows and doors are less relevant. Other features may be removed, such as the text 208, the plumbing features and other internal appliances and furniture which may be shown on drawings used as input to the processing. The removal of these elements may particularly be useful when generating simplified models for structural analysis or when focusing solely on spatial configurations, such as when defining escape routes or calculating usable floor area.

Again, such feature recognition may be useful to accomplish other goals, but for a goal of boundary 211 definition that delineates a floorplan 210 as illustrated in FIG. 2B a pictorial representation may be purposefully devoid of such features, as illustrated. This approach simplifies the model, making it easier to identify and adjust key spatial boundaries without the distraction of non-essential elements. In some cases, the AI engine may automatically generate multiple versions of the floorplan, each tailored for a specific analysis, such as one version focused on structural elements and another on interior design features. In other embodiments, the AI engine may automatically generate multiple versions of the floorplan, separating water closet areas for detailed compliance analysis.

Referring now to FIG. 2B, a boundary 211 is illustrated around a grouping of defined spaces 213-216. Spaces are areas within a boundary (which may include, but are not limited to rooms, hallways, water closets, stairwells etc.).

FIG. 2B illustrates an AI predicted boundary 211 based upon an analysis of the floorplan 210 illustrated in FIG. 2A. A transition from FIG. 2A to FIG. 2B illustrates how an AI engine successfully distinguishes between wall features and other features such as a shower 207, kitchen counter 209, toilet 206, bathroom sink 205, etc. shown in FIG. 2A. The AI engine's ability to accurately differentiate between these features provides that boundaries are drawn precisely, reflecting the actual layout of the building and facilitating accurate compliance assessments and design modifications.

In another aspect, in some embodiments, a boundary may include a polygon 211B. A polygon may be any shape that is consistent with a design submitted for AI analysis. For example, a rectangular polygon 211B may be based upon a wall segment 211A and have a width X 218 and a length Y 219. The use of polygons allows the AI engine to represent complex shapes and areas within the design plan, enabling more detailed and versatile analysis. Boundaries that include polygons are useful, for example, in creating a three-dimensional representation of a design plan.

According to the present invention, a boundary may be represented on a user interface as one or both of: one or more line segments, and one or more polygons. For example, a bathroom sink or a water closet can be represented as a polygon with specific dimensions, while a smaller feature like a light switch may be represented as a single point. In addition, a feature may be represented as a single point, a polygon, an icon, or a set of polygons. In some embodiments, a point may be placed in a centroid position for the feature, and the centroid points may be counted, summarized, subtracted, averaged, or otherwise included in mathematical processes. These centroid points can be useful for various calculations, such as determining the center of gravity for a room's furnishings or optimizing the placement of utilities for accessibility.

In some embodiments, an analytical use for a boundary may influence how a boundary is represented. For example, determination of a length of a wall section, or size of a feature may be supported via a boundary that includes a line segment. A count of feature type may be supported with a boundary that includes a single point or predefined polygon or set of polygons. This method can be used to quickly quantify items like windows or doors within a specific area, aiding in inventory and cost estimation. Extrapolation of a two-dimensional reference into a three-dimensional representation may be supported with a boundary that includes polygons. The three-dimensional models are useful for visualizing how different components of the building interact in space, assisting architects and engineers in refining their designs.

A scale 217 may be used to indicate a size of features included in a technical drawing included in the two-dimensional reference. As indicated above, executable software may be operative with a controller to count pixels on an image and apply a scale to a bitmapped image. Alternatively, a user may input a drawing scale for a particular image, drawing or other two-dimensional reference. Typical units referenced in a scale include inches: feet, centimeters: meters, or any other appropriate unit.

In some embodiments, a scale 217 may be determined by manually measuring a room, a component, or other empirical basis for assessing a relative size. Examples therefore include a scale included as a printed parameter on two-dimensional reference or obtained from dimensioned features in the drawing. For example, if it is known that a particular wall is thirty feet in length, a scale may be based upon a length of the wall in a particular rendition of the two-dimensional reference and proportioned according to that length.

Referring now to FIG. 2C, a user interface 220 is illustrated with multiple regions 221-224. The multiple regions 221-224 may be presented via different hatch representations or other distinguishing patterns. In some embodiments, these regions may also be represented in various colors, textures, or transparency levels to enhance visual differentiation, especially in complex designs. During training of AI engines, and in some embodiments, when a submitted design drawing includes highly customized or unique features, a user may wish to adjust an automated identification of boundaries and automated filling of space within the boundaries. This adjustment may particularly be important in scenarios where the design includes unconventional layouts, non-standard room shapes, or bespoke architectural elements that the AI engine may not initially recognize accurately.

During training of processes executed by a controller, such as those included in an AI engine made operative by the controller, and in some embodiments, when a submitted design drawing includes highly customized or unique features, an automated identification of boundaries and automated filling of space within the boundaries may be included in the interactive user interface may not be according to a particular need of a user. Therefore, in some embodiments of the present invention, an interactive user interface may be generated that presents a user with a display of one or more boundaries and pattern or color filled areas arranged as a reproduction of a two-dimensional reference input into the AI engine. This allows the user to visualize how the AI engine interprets the design and to make necessary corrections or adjustments. For example, in a design with irregularly shaped rooms, the AI engine may incorrectly assign boundaries, which the user can then manually correct.

In some embodiments, the controller may generate a user interface 220 that includes indications of assigned vertices and boundaries, and one or more filled areas or regions with user changeable editing features to allow the user to modify the vertices and boundaries. These editing features may include drag-and-drop functionality, point-and-click adjustments, and input fields for precise numerical adjustments. For example, the user interface may enable a user to transition an element, such as a vertex to a different location, change an arc of a curve, move a boundary, or change an aspect of polylines, polygons, arcs, circles, ellipses, splines, NURBS, or predefined subsets of the interface. The user may also have the option to lock certain boundaries or vertices to prevent further changes, so that critical design elements remain consistent throughout the editing process. The user can thereby “correct” an assignment error made by the AI engine, or simply rearrange aspects included in the interface for a particular purpose or liking.

In some embodiments, modifications and/or corrections of this type can be documented and included in training datasets of the AI model, also in processes described in later portions of the specification. By incorporating user feedback into the training process, the AI engine can gradually improve its accuracy and adaptability, learning to recognize and correctly interpret a wider range of design elements and configurations.

Discrete regions may be regions associated with an estimation function. A region that is contained within a defined wall feature may be treated in different ways such as ignoring all areas within a boundary, to counting all area in a boundary (even though regions do not include boundaries). In some cases, the AI engine may be programmed to automatically exclude certain regions from calculations (or from compliance analysis), such as areas designated as voids or spaces intended for non-occupational use. If the AI engine counts the area, it may also make an automated decision on how to allocate the region to an adjacent region or regions that the region defines. For example, if a region represents a common area between two rooms, the AI may allocate the area proportionally to each room based on predefined rules or user input, thus influencing cost estimations, material requirements, and compliance checks.

Referring to FIG. 2D, an exemplary user interface 230 illustrates a user interface floorplan model 231 with boundaries 236-237 between adjacent regions 233-234 with interior boundaries 236-237 that may be included in an appropriate region of a dynamic component. The AI may incorporate a hierarchy where some types of regions may be dominant over others, as described in more detail in later sections. For example, in a residential design, living areas may be prioritized over utility spaces like water closets, influencing how space is allocated in the final design. Regions with similar dominance rank may share space, or regions with higher dominance rank may be automatically assigned to a boundary. In general, a dominance ranking schema will result in an area being allocated to the space with the higher dominance rank. For example, in a hospital design, operating rooms may have a higher dominance rank over storage rooms, so that the most critical areas are given priority in space allocation. In some embodiments, a dominance rank will allocate an area that may be used in determining an occupancy load. Moreover, in those embodiments that analyze a dynamic file (such as, for example, a Revit® compatible file) a dominance rank may be included, or added to, one or more dynamic features and be modified as the dynamic feature is modified. This dynamic ranking allows for the real-time adjustment of priorities based on user input or changes in the design parameters.

In some embodiments, an area 235A between interior boundaries 236-237 and an exterior boundary 235 may be fully assigned to an adjacent region 232-234. An area 235A between interior boundaries 236-237 may be divided between adjacent regions 232-234 to the interior boundaries 236-237. In some embodiments, an area 235A between boundaries 236-237 may be allocated equally, or it may be allocated based upon a dominance scheme where one type of area is parametrically assessed as dominant based upon parameters such as its area, its perimeter, its exterior perimeter, its interior perimeter, and the like. This allows for flexible and adaptive space planning, especially in multi-functional areas where space needs may overlap. Parameters may also be based upon items that are automatically counted using AI analysis of pixel patterns that identifies a pattern as an item, such as, by way of non-limiting example, one or more of: doors or other paths of egress; plumbing fixtures; fixed obstacles; stairs; inclines; and declines.

In some examples, a boundary 235-237 and associated area 235A may be allocated to a region 232-234 according to an allocation schema, such as, for example, an area dominance hierarchy, to prioritize a kitchen over a bathroom, or a larger space over a smaller space. This prioritization may be based on the intended use of the space or on specific requirements such as those found in commercial kitchens, which need more room for equipment and movement. In some embodiments, user selectable parameters (e.g., a bathroom having parameters such as two showers and two sinks may be more dominant over a kitchen having parameters of a single sink with no dishwasher). These parameters may be used to determine boundary and/or area dominance. A resulting computed floorplan model may include a designation of an area associated with a region. This allows for a more tailored and functional layout that meets the specific needs of the user or project. In various embodiments, different calculated features are included in a user interface floorplan model 231 such as features representing aspects of a wall, such as, for example, center lines, the extent of the walls, zones where doors open and the like, and these features may be displayed in selected circumstances.

Some embodiments may also include AI analysis of a dynamic file, such as a Revit or Revit compatible file and/or a raster file with patterns of dots, the AI may generate a likelihood that a region or area represented by one or both of a polygon or pattern of dots, includes a common path or dead end or an area definable for determining an occupancy load, egress capacity, travel distance and/or other factor that may influence a decision on compliance with a local code. This analysis is particularly valuable in complex building designs, such as large office buildings or hospitals, where compliance with safety codes and efficient egress planning are critical.

Once boundaries have been defined a variety of calculations may be made by the system. A controller may be operative to perform method steps resulting in calculation of a variable representative of a floorplan area, which in some embodiments may be performed by integrating areas between different line features that define the regions. For example, this may involve calculating the total floor area of a commercial space to determine leasing rates or occupancy limits.

Alternatively, or in addition to method steps operative to calculate a value for a variable representative of an area, a controller may be operative to generate a value for element lengths, which values may also be calculated. For example, if ceiling heights are measured, presented on drawings, or otherwise determined, then volume for the room and surface area calculations for the walls may be made. These volume and surface area calculations may be useful for tasks such as determining HVAC capacity, estimating paint requirements, or assessing acoustic properties. There may be numerous dimensional calculations that may be made based on the different types of model output and the user inputted calibration factors and other parameters entered by the user.

In some embodiments, a controller may be provided with two dimensional references that include a series of architectural drawings with disparate drawings representing different elevations within a structure. A three-dimensional model may be effectively built based upon a sequenced stacking of the disparate drawings representing different levels of elevations. In other examples, the series of drawings may include cross sectional representation as well as elevation representation. A cross-section drawing, for example, may be used to infer a common three-dimensional nature that can be attributed to the features, boundaries and areas that are extracted by the processes discussed herein. Elevation drawings may also present a structure in a three-dimensional perspective. Feature recognition processes may also be used to create three-dimensional model aspects. These 3D models can then be used for various purposes, including virtual walkthroughs, structural analysis, and construction planning, providing a comprehensive toolset for architects and engineers.

Referring now to FIG. 2E, an exemplary portion 240 of a design plan is depicted, comprising a public toilet facility with a plurality of water closets 241-244 in some embodiments of the present invention. Public toilets, particularly those in industrial or office buildings, are essential for accommodating large numbers of people. These facilities must adhere to stringent guidelines and requirements as specified by relevant building and accessibility codes, such as the Americans with Disabilities Act (ADA) in the United States, as well as local building regulations that provide safety, hygiene, and accessibility for all users.

In public toilet facilities like the one illustrated in FIG. 2E, it is required to determine that the design allows for sufficient space between water closets to accommodate user comfort and comply with regulatory standards. The design portion 240 also includes multiple dwelling spaces, labeled as Space 1 through Space 4. These spaces may represent various areas within the building, such as office rooms, meeting areas, or other functional spaces that are accessible from the shared toilet facilities.

The AI engine employed in the compliance analysis of this design may assess various aspects of the toilet layout to determine if it meets the necessary standards. One of the design parameters the AI engine may analyze is the space between the water closets, specifically the distance between the centerlines of each toilet fixture. According to many building codes, there are minimum distance requirements that must be maintained between the centerlines of adjacent water closets to provide privacy and accessibility. These requirements are especially important in public or shared facilities where multiple people may need to use the facilities simultaneously.

The AI engine may determine that the water closets 241 and 242 have sufficient space 245 between their centerlines, as per the relevant codes. This spacing provides that users have enough room to use the facilities comfortably without feeling cramped or encroached upon by adjacent stalls. Similarly, the space 246 between the centerlines of water closets 243 and 244 is also determined by the AI engine to be compliant with the necessary standards. This indicates that the design provides adequate separation between these fixtures, contributing to user comfort and compliance with regulatory requirements.

However, the AI engine may identify a potential issue with the spacing 247 between water closets 242 and 243. The distance between the centerlines of these two fixtures may not meet the minimum requirements set forth by the relevant codes. In many cases, insufficient spacing between water closets can lead to a range of problems, including a lack of privacy, reduced accessibility for users with disabilities, and potential safety hazards. For example, if the space between these toilets is too narrow, it can make it difficult for users to enter and exit the stalls, especially those who use mobility aids like walkers or wheelchairs.

In response to this issue, the AI engine may provide several suggestions to bring the design into compliance. One common recommendation can be to increase the distance between the water closets 242 and 243 to meet the required minimum spacing. This may involve redesigning the layout of the toilet area, potentially moving one or both of the water closets to create more space. The AI engine may offer specific guidance on how much the fixtures need to be moved and in which direction to achieve compliance.

Additionally, the AI engine may suggest the reconfiguration of adjacent spaces, such as Space 1 through Space 4, to accommodate the necessary adjustments in the toilet area. For example, if Space 2 or Space 3 has some flexibility in its layout, the AI engine may recommend reducing the size of one or both of these spaces slightly to allow for more room in the toilet area. Alternatively, the AI may suggest shifting the entire row of water closets slightly to the left or right, depending on the available space and the overall layout of the building.

Another potential solution provided by the AI engine may involve altering the partitions or walls between the water closets. If the physical space cannot be expanded due to structural limitations, the AI may recommend using thinner partitions that still meet privacy and safety standards but allow for more space between the fixtures. In some cases, the AI engine may suggest the use of specialized fixtures or compact toilet designs that require less space, thereby allowing the existing layout to remain largely unchanged while still achieving compliance. In some embodiments, the AI engine may suggest removing one or more water closets if there are more than required number of water closets. The AI engine may also determine that the number of water closets are sufficient based on various factors such a load capacity of the building.

Referring now to FIG. 2F, an exemplary portion 250 of a design plan is illustrated, which includes a water closet area 257 meant for compliance analysis in some embodiments of the present invention. The water closet area 257 comprises several fixtures commonly found in bathroom layouts, including a water closet 251, a urinal 252, a hand wash basin 253, and a bathtub 254. Each of these fixtures is positioned within the water closet area 257 in a manner that will be closely scrutinized by the AI engine to determine whether the design meets the necessary standards for safety, accessibility, and functionality as set forth by relevant building codes.

The AI engine may analyze that a door 255, being able to rotate 259 in one or possibly both directions, depending on the design specifications. The width 258 of the door 255 is a significant factor (design parameter) in determining whether the entryway is compliant with accessibility standards, such as those specified by the ADA. The AI engine may assess whether the door's width 258 is sufficient to allow easy access for all users, including those with disabilities who may be using mobility aids like wheelchairs or walkers. If the door 255 does not meet the required width, the AI engine may likely flag this as a non-compliance issue and suggest increasing the door width to meet the minimum standards, typically around 32 inches for clear width to provide wheelchair accessibility.

In addition to the width 258 of the door 255, the AI engine may also analyze the door's rotation 259 and how it interacts with other fixtures within the water closet area 257. Specifically, the AI engine may assess whether the door 255, when rotated inward, collides with the water closet 251 (or any other fixture). This collision risk is a significant concern because it can prevent the door from fully opening, thus restricting access to the bathroom and posing a potential hazard to users. The AI engine may simulate the door's movement within a virtual environment of the design plan to determine the exact points of contact between the door 255 and the water closet 251 or other fixtures. If a collision is detected, the AI may suggest several potential solutions, such as reorienting the door to swing outward instead of inward, or relocating the water closet 251 to a different part of the bathroom where it may not interfere with the door's movement. Another suggestion may involve using a sliding door mechanism, which may eliminate the risk of collision altogether by removing the need for door rotation.

The positioning of the hand wash basin 253 is another exemplary aspect that the AI engine may evaluate for compliance. In the illustrated design, the hand wash basin 253 is situated in a corner of the bathroom, accessible only through a narrow path 256. The AI engine may assess whether this placement allows for adequate and comfortable use of the basin 253. Specifically, the AI engine may consider whether users can easily approach and use the basin 253 without experiencing discomfort or restriction, especially those with mobility issues. The narrow path 256 leading to the basin 253 may be too restrictive, making it difficult for some users to access the basin 253, particularly if they are using a wheelchair or walker. The AI may flag this placement as non-compliant with accessibility standards and suggest relocating the basin 253 to a more central or accessible location within the bathroom. For example, the basin 253 can be repositioned closer to the door 255 where it may be more easily reachable upon entry, or it may be placed along a wall where the path 256 is wider, providing better access for all users.

The AI engine may also analyze the overall layout of the water closet area 257 to identify potential issues with the arrangement of the fixtures. For example, it may determine whether the proximity of the urinal 252 to other fixtures, such as the water closet 251 and the bathtub 254, allows for adequate spacing and privacy. The AI engine may also evaluate whether the layout meets hygiene standards, such as determining if the urinal is too close to areas where users may store personal items or clean themselves. If the AI engine finds any layout issues, it may suggest rearranging the fixtures to optimize the use of space and improve the bathroom's functionality. For example, it may recommend moving the urinal 252 to a more discrete location, away from the primary area of use, or suggest installing partitions to increase privacy and hygiene.

Additionally, the AI engine may assess the bathtub 254 for compliance with safety and accessibility standards. This may involve evaluating the bathtub's dimensions, the height of the tub's edge, and the ease with which users can enter and exit the tub. If the bathtub 254 is found to be too high or too narrow, the AI may suggest alternatives, such as installing a lower tub or adding grab bars around the tub to assist users in maintaining balance while entering or exiting.

In some embodiments, the AI engine may also identify other potential compliance issues within the water closet area 257 that are not immediately apparent in the initial design. For example, it may analyze the lighting within the bathroom to determine that it meets the required standards for visibility and safety. Poorly lit areas may pose a risk, particularly near the bathtub 254 or water closet 251, where slips and falls are more likely to occur. If the lighting is found to be inadequate, the AI may suggest adding more light fixtures or increasing the wattage of existing lights to improve visibility.

Moreover, the AI engine may also assess the ventilation within the bathroom, as proper airflow is required for maintaining hygiene and preventing the buildup of moisture, which can lead to mold and mildew. If the bathroom lacks adequate ventilation, the AI may recommend installing an exhaust fan or increasing the size of the existing ventilation openings.

Referring now to FIGS. 2G-2L, these figures illustrate various exemplary designs of water closets 260-261 and hand wash basins 262-265 that can be used in a water closet area, and which may be analyzed by the AI engine for compliance analyses with relevant building codes and standards. The design and placement of these fixtures are analyzed to determine that the water closet area is accessible, safe, and functional for all users, including those with disabilities.

Starting with the water closets, FIG. 2G illustrates a water closet 260 that has a height 260A. The AI engine may determine that the height 260A does not comply with relevant codes, particularly those related to accessibility standards such as the Americans with Disabilities Act (ADA) or other local codes that specify the appropriate height for a toilet seat to accommodate users with mobility impairments. For example, if the height 260A is too low, it may be difficult for users, especially those in wheelchairs or those with limited lower body strength, to transfer onto the toilet. The AI engine may suggest raising the height of the toilet seat to bring it within the compliant range, typically between 17 to 19 inches from the floor, depending on the specific code.

In contrast, FIG. 2H shows a water closet 261 with a height 261A. The AI engine may also analyze this height and determine that it exceeds the maximum allowable height as per the relevant standards. If the height 261A is too high, it may pose a challenge for users to sit down or stand up, particularly for those with limited mobility, or both children. In such cases, the AI engine may recommend lowering the toilet seat height so that it falls within the acceptable range, thereby making it more accessible to all users.

Moving on to the hand wash basins, FIGS. 2I-2L depict various shapes and sizes of basins that may be analyzed by the AI engine for compliance. FIG. 2I shows a basin 262 with an edged, angular design. FIG. 2J illustrates a round basin 263, while FIG. 2K and FIG. 2L display square and octagonal basins 264 and 265, respectively. The AI engine may analyze the shapes, sizes, and mounting heights of these basins to determine if they meet the requirements for accessibility and usability.

For example, certain codes may specify that hand wash basins should not have sharp edges to prevent injury, particularly in facilities used by children or individuals with disabilities. The AI engine may flag the basin 262 for its sharp-edged design and suggest a rounded alternative, such as the basin 263, which is less likely to cause injury upon contact. Additionally, the AI engine may evaluate whether the basins provide adequate knee clearance for wheelchair users, typically requiring a clearance of at least 27 inches from the bottom of the basin to the floor.

The AI engine may also check if the basins 262-265 are large enough to accommodate the needs of users but not so large that they encroach on the required clear floor space in front of the basin. The AI may recommend resizing the basin if it is too large or too small to meet the standards for usability, providing that it offers sufficient space for handwashing without limiting the maneuverability within the water closet area.

In some embodiments, the AI engine may analyze the distance of a fixture, such as the basin 262 shown in FIG. 2I, from an adjacent wall to determine compliance with relevant building codes and accessibility standards. The proper positioning of fixtures like hand wash basins relative to walls is considered for both functionality and accessibility.

For example, the AI engine may assess whether the basin 262 is too close to the wall, which may restrict user access and limit the maneuverability of individuals. If the basin 262 is positioned too near to the wall, it may also impede the ability of users to comfortably reach the basin 262, potentially causing inconvenience or even safety hazards.

To analyze compliance, the AI engine may measure the actual distance from the edge of the basin 262 to the adjacent wall and compare this distance against prescribed standards. For example, certain guidelines may require that a hand wash basin be installed with a minimum distance from the wall to provide sufficient clearance for users' hands and arms, or to allow for the installation of additional accessibility features such as grab bars.

If the AI engine detects that the distance from the basin 262 to the wall is less than the required minimum, it may flag this as a non-compliant feature. The AI engine may then generate automated suggestions for repositioning the basin. For example, it may recommend moving the basin further away from the wall to achieve the necessary clearance, thereby improving accessibility. The suggestion may also include specific measurements for how far the basin should be moved to comply with the relevant codes.

In addition, the AI engine may also consider the distance in terms of other fixtures and space allocations within the water closet area. For example, if the basin is too far from the wall, it may encroach upon the clear floor space required for wheelchair maneuverability or reduce the space available for other essential fixtures like the toilet or a shower. The AI may provide a balanced recommendation that optimizes the layout for both compliance and user convenience.

Moreover, the AI engine may provide suggestions related to the installation height of various fixtures including basins. For example, if any of the basins 262-265 are installed too high or too low, the AI may recommend adjustments to bring them to the standard height, which is typically about 34 inches from the floor to the top of the basin.

Referring now to FIG. 2M, it illustrates an exemplary view of a water closet 270 that may experience a reverse backflow 272 in future from a drainage pipe 271, as predicted by the AI engine during compliance analysis in some embodiments of the present invention. Reverse backflow is a condition where wastewater flows back into the water closet from the drainage system, typically due to a failure in the plumbing design, blockage in the drainage system, or improper venting. This condition poses significant health risks, including the potential for contamination of the water supply and the spread of harmful bacteria and pathogens. Additionally, reverse backflow can lead to unpleasant odors, structural damage due to water exposure, and general unsanitary conditions.

The AI engine, during its compliance analysis, can predict the possibility of reverse backflow by analyzing the design parameters of the water closet installation, such as the slope and configuration of the drainage pipes, the presence and adequacy of venting systems, and the overall design of the plumbing network. In this particular scenario, the AI engine may determine that the slope of the drainage pipe 271 is insufficient to allow for proper wastewater flow, which may cause the reverse backflow 272 in future. Alternatively, the AI may detect that the drainage pipe 271 is too narrow or not properly vented, leading to a buildup of pressure that forces the wastewater back into the water closet.

To bring this situation into compliance, the AI engine may provide several automated suggestions. One potential recommendation can be to increase the slope of the drainage pipe 271 so that gravity assists in the proper flow of wastewater away from the water closet 270. The AI may suggest a specific angle or slope gradient that aligns with local plumbing codes and standards. Another suggestion may involve reconfiguring the plumbing system to include additional or improved venting, which would help equalize the pressure in the drainage system and prevent the occurrence of backflow. The AI may specify the ideal locations and dimensions for the vents, taking into account the overall layout of the plumbing system and the building's structure.

Additionally, the AI may recommend installing backflow prevention devices such as check valves or air admittance valves (AAVs) within the drainage system. These devices are designed to allow wastewater to flow in one direction only, thus preventing backflow into the water closet. The AI may provide specifications for the type of backflow preventer that may be most effective in this scenario, based on the flow rate, pipe size, and other relevant factors.

In cases where structural modifications are necessary, such as rerouting pipes or adding additional support for the correct slope, the AI may suggest alternative design approaches that minimize disruption and cost. For example, instead of extensive demolition to adjust the pipe slope, the AI may recommend installing a booster pump to assist with wastewater movement, especially in scenarios where gravity alone is insufficient due to the building's layout.

Referring now to FIG. 2N, it illustrates an exemplary view of a water closet 280 with two improperly installed and unnecessary water tanks, 281 and 282, as well as an uneven floor type 283, all identified as design flaws by the AI engine during compliance analysis in some embodiments of the present invention. The presence of two water tanks, 281 and 282, in this design is unnecessary and may introduce multiple complications, both in terms of functionality and code compliance.

In a typical water closet design, a single water tank is sufficient to manage the flushing system. The inclusion of two water tanks may be an indication of either a redundant design choice or a misunderstanding of the plumbing requirements. Such redundancy not only increases the cost of materials and installation but also complicates the maintenance and potential repair work. Each additional component in a system introduces more points of failure, which may lead to increased wear and tear or operational inefficiencies over time.

The AI engine, recognizing this redundancy, may flag the presence of the second water tank (or fixture) as non-compliant or unnecessary according to relevant building and plumbing codes. It may suggest the removal of one of the tanks, advising that a single, properly installed water tank may be sufficient to provide the correct operation of the water closet 280. The AI may also recommend revising the plumbing layout to accommodate a single tank, simplifying the overall design and reducing potential points of failure.

The figure also highlights an uneven floor type 283, which may present another significant design flaw. An uneven floor can lead to instability in the installation of the water closet 280, causing it to rock or move during use. The AI engine may recommend leveling the floor before any installation work begins, so that the water closet 280 is properly seated and stable. In addition to these corrections, the AI engine may suggest further optimizations to the design. For example, it may recommend the use of more efficient or space-saving fixtures, improving both the functionality and the overall user experience within the bathroom.

In some embodiments, the AI engine may consider a comprehensive range of design parameters for compliance analyses, for determining if all fixtures within a water closet area or bathroom meet relevant codes and standards. These design parameters may include (not limited to) the height of fixtures such as water closets, basins, showers, and grab bars, which must comply with specific accessibility guidelines to provide ease of use for all individuals. The shape and size of these fixtures may also be considered; for example, the AI may analyze whether the dimensions of a hand wash basin or the seating area of a toilet are adequate for safe and comfortable use. Additionally, the distance from the wall may be another design parameter, particularly for determining if fixtures like basins and toilets are too close to or too far from adjacent walls.

The AI may also evaluate relative distances between fixtures, such as the distance between a toilet and a grab bar, or between a basin and a shower, to determine if the layout provides sufficient clearance for users to move freely and safely. Clear floor space around each fixture, particularly in front of water closets and basins, is another important consideration, as it impacts the maneuverability of wheelchairs or other mobility aids. The placement and alignment of fixtures relative to one another, such as aligning a mirror above a basin, providing the proper reach distance to a soap dispenser, and the positioning of a toilet paper holder at an accessible height and distance from the toilet, are additional design parameters that the AI may analyze. Furthermore, the AI may assess structural parameters, including the load-bearing capacity of walls where grab bars are installed, or the slope of the floor for adequate drainage. Lastly, other factors, such as the ease of use and reachability of controls (e.g., flush levers, faucet handles, shower controls), and aesthetic considerations, like the overall harmony of the bathroom design, may also be part of the AI's analysis to determine not only if the design plan is compliant but also functional, safe, and pleasing to use.

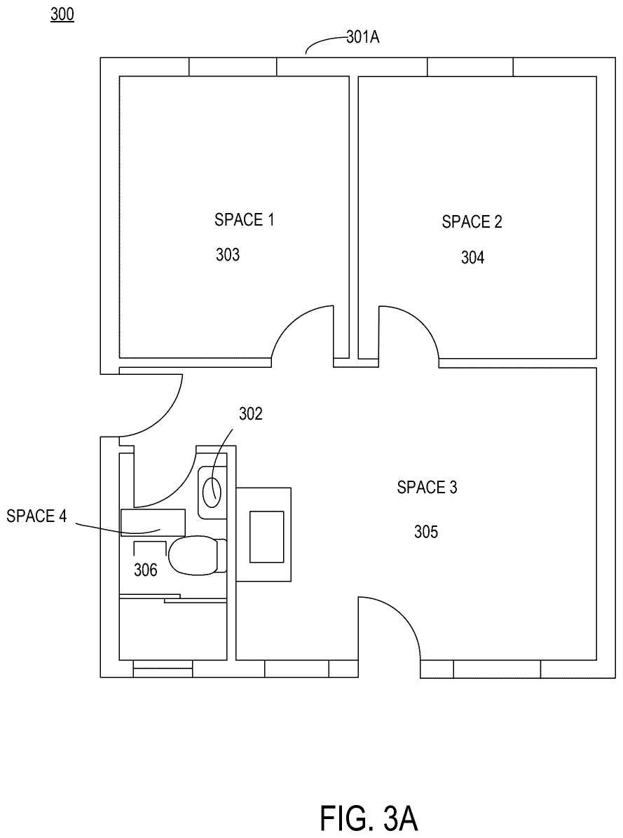

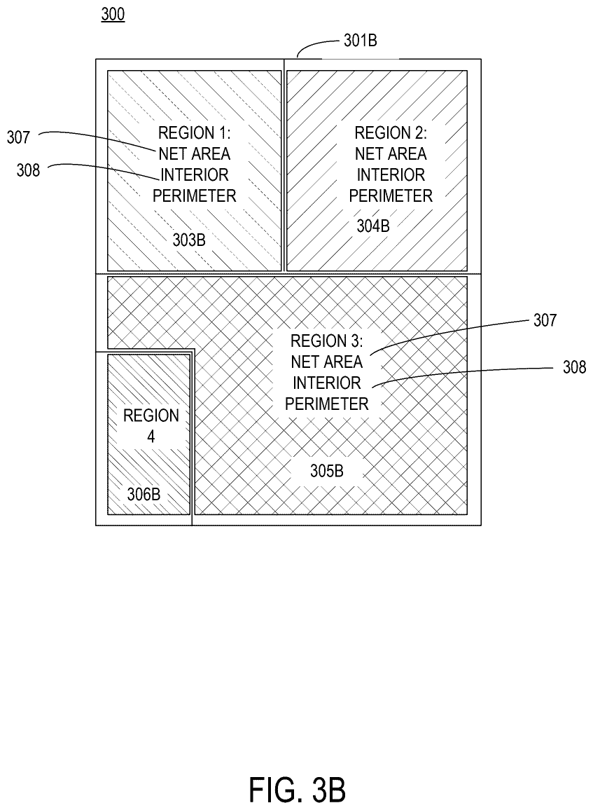

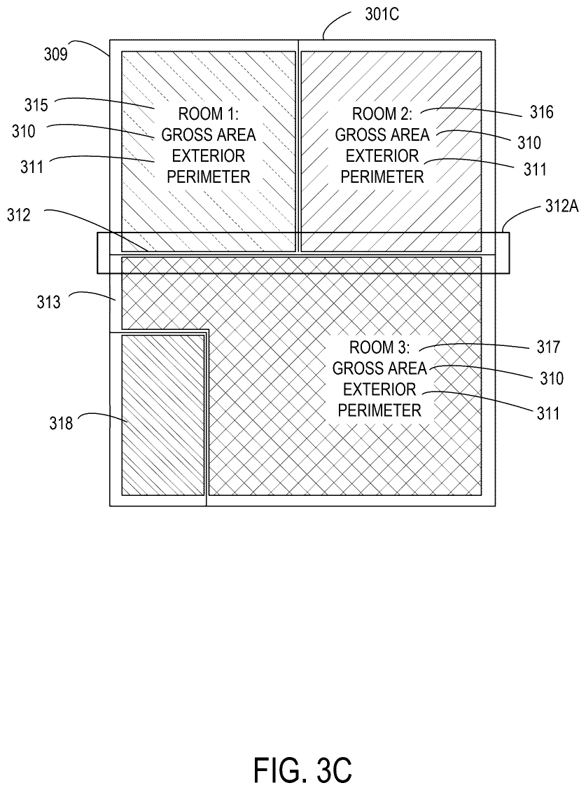

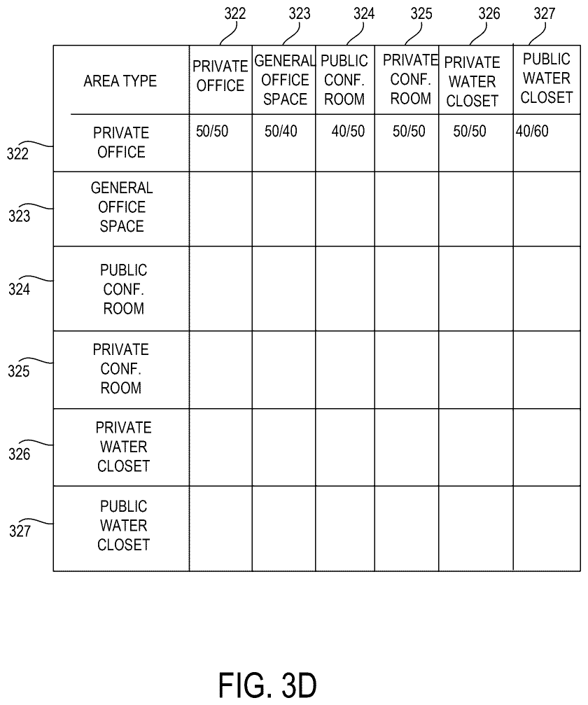

Referring now to FIGS. 3A-3C, a user interface 300 may generate multiple different user views, each view has different aspects related to the two-dimensional reference drawing input. For example, referring now to FIG. 3A, a user interface 300 with a replication view 301A may include replication of an original floor plan represented by a two-dimensional reference, without any controller added features, vectors, lines, or polygons integrated or overlaid into the floorplan. The replication view 301A includes various spaces 303-306 that are undefined in the replication view 301A but may be defined during the processes described herein. For example, some or all of a space 303-306 may correlate to a region in a region view 301B.

The replication view 301A, may also include one or more fixtures 302. A rasterized version (or pixel version) of the fixtures 302 may be identified via an AI engine. If a pattern is present that is not identified as a fixture 302, a user may train the AI engine to recognize the pattern as a fixture of a particular type. The controller may generate a tally of multiple fixtures 302 identified in the two-dimensional reference. The tally of multiple fixtures 302 may include some or all of the fixtures identified in the two-dimensional reference and be used to generate an estimate for completion of a project illustrated by, or otherwise represented by the two-dimensional reference.

Referring now to FIG. 3B, in the user interface 300 a user may specify to a controller that a one of multiple views available to presented via the interface. For example, a user may designate via an interactive portion of a screen displaying the user interface 300 that a region view 301B be presented. The region view 301B may identify one or more regions and/or spaces 303B-306B identified via processing by a controller, such as for example, via an AI engine running on the controller. The region view 301B may include information about one or more regions 303-306 delineated in the region view 301B of the user interface 300. For example, the controller may automatically generate and/or display information descriptive of one or more of: user displays, printouts or summary reports showing a net interior area 307 (e.g., a calculation of square footage available to an occupant of a region), an interior perimeter 308, a type of use a region 303B-306B will be deployed for, or a particular material to be used in the region 303B-306B. For example, Region 4 306B may be designated for use as a bathroom; and flooring and wall board associated with Region 4 may be designated as needing to be waterproof material.

Referring now to FIG. 3C a gross area region view 301C and 309 is illustrated. As illustrated in FIG. 3B, a user interface may include interactive devices for display of additional parameters, such as, for example, one or more of: a net interior area 307 may generate a designation of a value that is in contrast to a gross area 310 and exterior perimeter 311. The selection of gross area 310 may be more useful to a proprietor charging for a leased space, but may be less useful to an occupant than a net interior area 307 and interior perimeter 308. One or more of the net interior areas 307, interior perimeter 308 gross area 310 and exterior perimeter 311 may be calculated based upon analysis by an AI engine of a two-dimensional reference.

In addition, a height for a region may also be made available to the controller and/or an AI engine, then the controller may generate a net interior volume and vertical wall surface areas (interior and/or exterior).

In some embodiments, an output, such as a user interface of a computing device, smart device, tablet and the like, or a printout or other hardcopy, may illustrate one or both of: a gross area 310 and/or an exterior perimeter 311. Either output may include automatically populated information, such as the gross area of one or more rooms (based upon the above boundary computations) or exterior perimeters of one or more rooms.

In some embodiments, the present invention calculates an area bounded within a series of polygon elements (such as, for example, using mathematical principals or via pixel counting processes), and/or line segments.

In some embodiments, in an area of a bounded by lines intersecting at vertices, the vertices may be ordered such that they proceed in a single direction such as clockwise around the bounded area. The area may then be determined by cycling through the list of vertices and calculating an area between two points as the area of a rectangle between the lower coordinate point and an associated axis and the area of the triangle between the two points. When a path around the vertices reverses direction, the area calculations may be performed in the same manner, but the resulting area is subtracted from the total until the original vertex is reached. Other numerical methods may be employed to calculate areas, perimeters, volumes, and the like.

These views may be used in generating estimation analysis documents. Estimation analysis documents may rely on fixtures, region area, or other details. By assisting in generating net area, estimation documents may be generated more accurately and quickly than is possible through human-engendered estimation parameters.

With reference now again to FIGS. 3B and 3C, regions 303B-306B defined by an AI engine may include one or more Rooms in FIG. 3B subsequently have regions assigned as “Rooms” in FIG. 3C. The rooms may comprise various types of spaces, including but not limited to living rooms, bedrooms, bathrooms (e.g., water closet areas), kitchens, dining areas, offices, and storage rooms. Each room may serve a specific function within the building and may be designed with particular features and fixtures to accommodate that function. For example, a bathroom may include water closets, sinks, showers, and bathtubs, while a kitchen may comprise counters, sinks, ovens, and cabinetry. In the context of compliance analysis, each room's layout, dimensions, and the placement of fixtures are used for determining if the space meets relevant building codes and standards. The AI engine may analyze these aspects, considering the room type, intended use, and the specific requirements dictated by regulations such as accessibility standards, safety codes, and occupancy limits.

Referring now to FIG. 3D, a table is illustrated containing hierarchical relationships between area types 322-327 that may be defined in and/or by an AI engine and/or via the user interface. The area types 322-327 may be associated with dominance relationship values in relation to adjacent areas. For example, a border region 312-313 (as illustrated in FIG. 3C) will have an area associated with it. According to the present invention, an area 315-318 associated with the border region 312-313 may have an area type 322-327 associated with the area 315-318. An area 312A included in the border region 312-313 may be allocated according to a ratio based upon a dominance ranking of one feature as compared to another feature, which may be represented as a hierarchical relationship between the features, such as, for example, adjacent areas (e.g., area 315 and area 317 or area 317 and area 318), the hierarchical relationship may be used to generate a dominance ranking of one area of another area, or to ascertain factors useful in determining whether a building is in compliance with an applicable code. For example, a dominance ranking may allocate space used to calculate one or more of: an occupancy load; a width and/or area of an egress path; a width and/or area of a common path; a length of a dead end; egress capacity; and travel distance from a furthest point.

Some embodiments of the present invention allocate one or more areas according to a user input (wherein the user input may be programmed to override and automated hierarchical relationship or be subservient to the automated hierarchical relationship). For example, as indicated in the table, a private office located adjacent to a private office may have an area in a border region split between the two adjacent areas in a 50/50 ration, but a private office adjacent to a general office space may be allocated 60 percent of an area included in a border region, and so on.

Dominance associated with various areas may be systemic throughout a project, according to customer preference, indicated on a two-dimensional reference by two-dimensional reference basis or another defined basis.

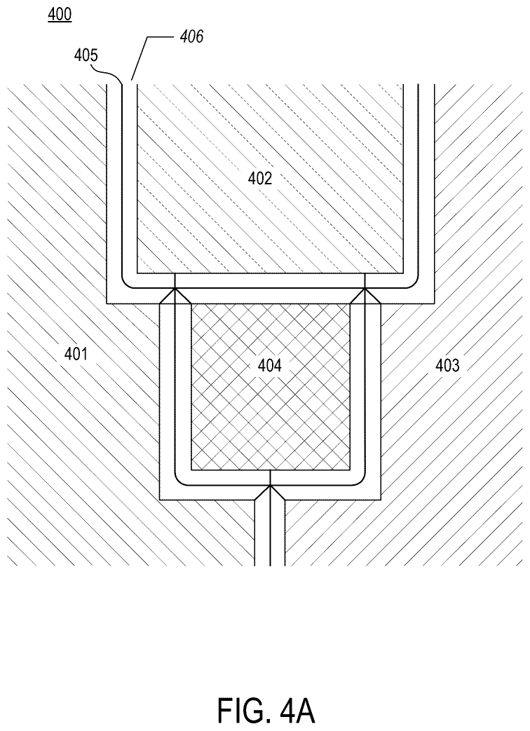

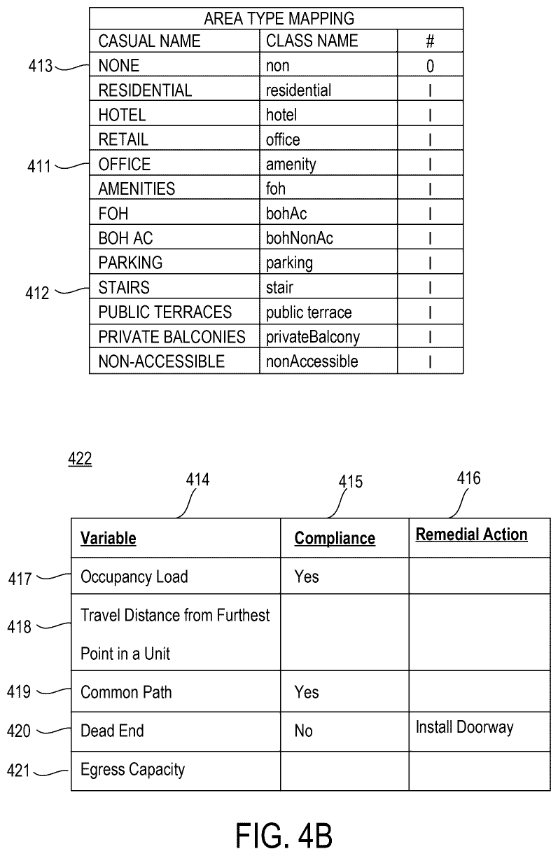

Referring now to FIG. 4A, an exemplary user interface 400 may include boundaries (which, as discussed above, may include one or more of: line segments, polygons, and icons) and regions overlaid on aspects included in a two-dimensional reference is illustrated. A defined space within a boundary (sometimes referred to as a region or area) may include an entire area within perimeters of a structure.

For example, a controller running an AI engine may determine locations of boundaries, edges, and inflections of neighboring and/or adjacent areas 401-404. There may be portions of boundary regions 405 and 406 that are initially not associated with an adjacent area 401-404. The controller may be operative via executing software in the AI engine to determine the nature of respective adjacent areas 401-404 on either side of a boundary and apply a dominance-based ranking upon an area type, or an allocation of respective areas 401-404. Different classes or types of spaces or areas may be scored to be equal to, dominant (e.g., above) others or subservient (e.g., below) others.

Referring now to FIG. 4B, an exemplary table A indicates classes of space types and their associated ranks. In some embodiments, a controller may be operative via execution of software to determine relative ranks associated with a region on one or either side of a boundary. For example, area 402 may represent office space and area 404 may represent a stair well. An associated rank lookup value for office space may be found at rank 411, and the associated rank lookup value for stairwells may be found at rank 413. Since the rank 413 of stairwells may be higher, or dominant, over the rank 411 of office space then the boundary space may be associated with the dominant stairs 412 or stairwell space. In some embodiments, a dominant rank may be allocated to an entirety of boundary space at an interface region. In other examples, more complicated allocations may be made where the dominant rank may get a larger share of boundary space than another rank allocated by some functional relationship. In still other examples (Table B), controller may execute logical code to be operative to assign pre-established work costs to elements identified within boundaries.

In some embodiments, a boundary region may transition from one set of interface neighbors to a different set. For example, again in FIG. 4A, a boundary 405 between office region 402 and stairwell 404 may transition to a boundary region between office region 402 and unallocated space 403. The unallocated space may have a rank associated with the unallocated space 403 that is dominant. Accordingly, the nature of allocated boundary space 405 may change at such transitions where one space may receive allocation of boundary space in one pairing and not in a neighboring region. The allocation of the boundary space 405 may support numerous downstream functionalities and provide an input to various application programs. Summary reports may be generated and/or included in an interface based upon a result after incorporation of assignment of boundary areas.

In another aspect, in FIG. 4B, a table 422 illustrates fields 414-416 that may have variable 417-421 values designated by an AI engine or other process run by a controller based upon the two-dimensional reference, such as a floor plan, design plan or architectural blueprint. The variables 417-421 include aspects that may affect compliance with conditions that must be met in order to be compliant with a code, such as, for example, compliance and remedial actions. For example, as illustrated, variables 417-421 may include occupancy load 417, travel distance form a furthest point 418, Common path 419, dead end 420, and egress capacity 421.

### Area Takeoff Classification

The determination of boundary definitions for a given inputted design plan, which may be a single drawing or set of drawings or other image, has many important uses and aspects as has been described. However, it can also be important for a supporting process executed by a controller, such as an AI algorithm to take boundary definitions and area definitions and generate classifications of a space. As mentioned, this can be important to support processes executed by a controller that assigns boundary areas based on dominance of these classifications.

Classification of areas can also be important for further aggregations of space. In a non-limiting example, accurate automatic classification of room spaces may allow for a combination of all interior spaces to be made and presented to a user. Overlays and boundary displays can accordingly be displayed for such aggregations. There may be numerous functionalities and purposes to automatic classification of regions from an input drawing.

An AI engine or other process executed by a controller may be refined, trained, or otherwise instructed to utilize a number of recognized characteristics to accomplish area classification. For example, an AI engine may base predictions for a type “/”category” of a region with a starting point of the determination that a region exists from the previous predictions by the segmentation engine.

In some embodiments, a type may be inferred from text located on an input drawing or other two-dimensional reference. An AI engine may utilize a combination of factors to classify a region, but it may be clear that the context of recognized text may provide direct evidence upon which to infer a decision. For example, a recognized textual comment in a region may directly identify the space as a bedroom, which may allow the AI engine to make a set of hierarchical assignments to space and neighboring spaces, such as adjoining bathrooms, closets, and the like.

Classification may also be influenced by, and use, a geometric shape of a predicted region. Common shapes of certain spaces may allow a training set to train a relevant AI engine to classify a space with added accuracy. Furthermore, certain space classes may typically fall into ranges of areas which also may aid in the identification of a region's class. Accordingly, it may be important to influence the makeup of training sets for classification that contain common examples of various classes as well as common variations on that theme.

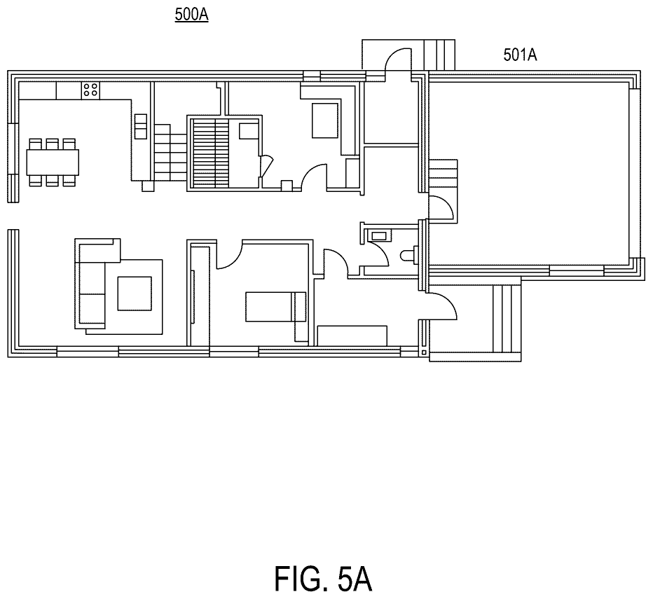

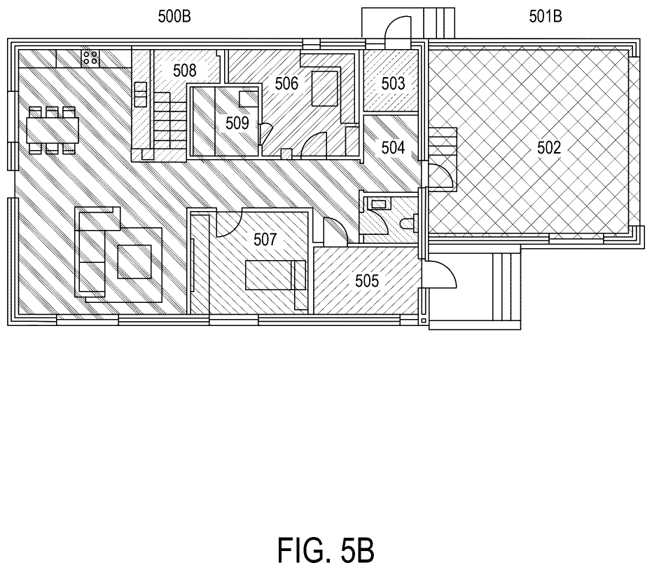

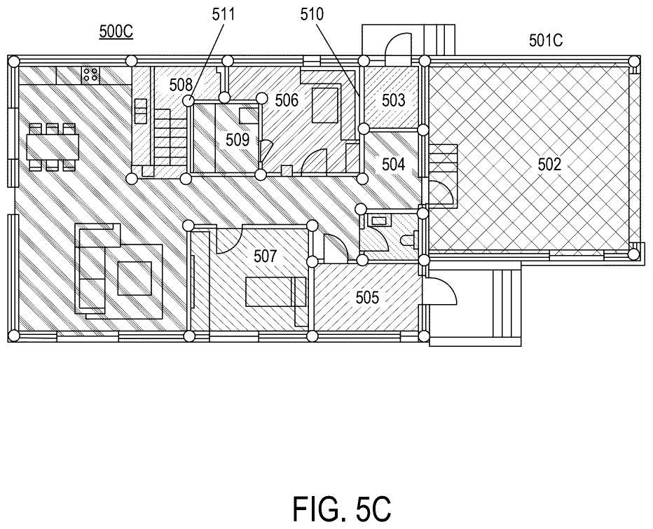

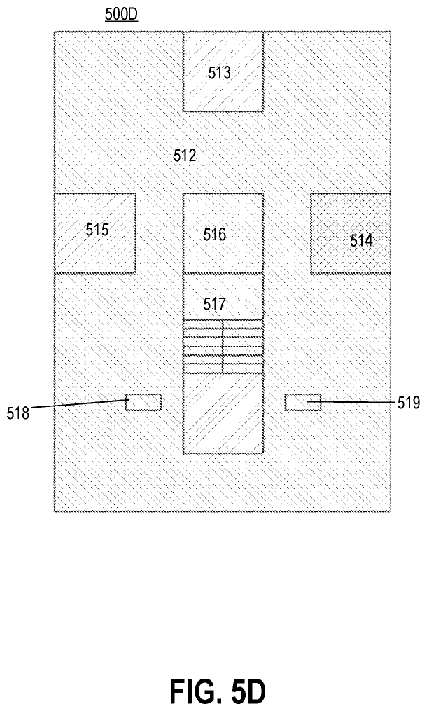

Referring now to FIGS. 5A-5D, a progressive series of outputs that may be included in various user interfaces are illustrated and provide examples of a recognition process that may be implemented in some embodiments of the present invention. Referring now to FIG. 5A, a relatively complex drawing of a floorplan may be input as a design plan 501A into a controller running an AI engine. The two-dimensional reference 501 may be included in an initial user interface 500A.

An AI engine based automated recognition process executes method steps via a controller, such as a cloud server, and identifies multiple disparate regions 502-509. Designation of the regions 502-509 may be integrated according to a shape and scale of the two-dimensional reference and presented as a region view 501B user interface 500B, with symbolic hatches or colors etc., as shown in FIG. 5B.

The region view 501B may include the multiple regions 502-509 identified by the AI engine arranged based upon to a size and shape and relative position derived from the two-dimensional reference 501.

Referring now to FIG. 5C, a line segment view 501C may include identified boundary line segments 510 and vertices 511 may also be presented as an overlay of the regions 502-509 illustrated as delineated symbolic hatches or colors etc., as illustrated in FIG. 5C. Said line segments 510 may also be represented as symbols such as but not limited to dots. Such an interactive user interface 500C may allow a user to review and correct assignments in some cases. A component of the AI engine may further be trained to recognize aggregations of regions 502-509 spaces, or areas, such as in a non-limiting sense the aggregation of internal regions 502-509, spaces or areas.

Referring now to FIG. 5D, an illustration of exemplary aggregation of regions 512-519 is provided where a user interface 500D includes patterned portions 512-519 and the patterned portions 512-519 may be representative of regions, spaces, or areas, such as, for example, aggregated interior living spaces.

In some embodiments, integrated and/or overlaid aggregations of some or all of: regions; spaces; patterned portions; line segments; polygons; symbols; icons or other portions of the user interfaces may be assembled and presented in a user output and our user interface, or as input into another automated process.

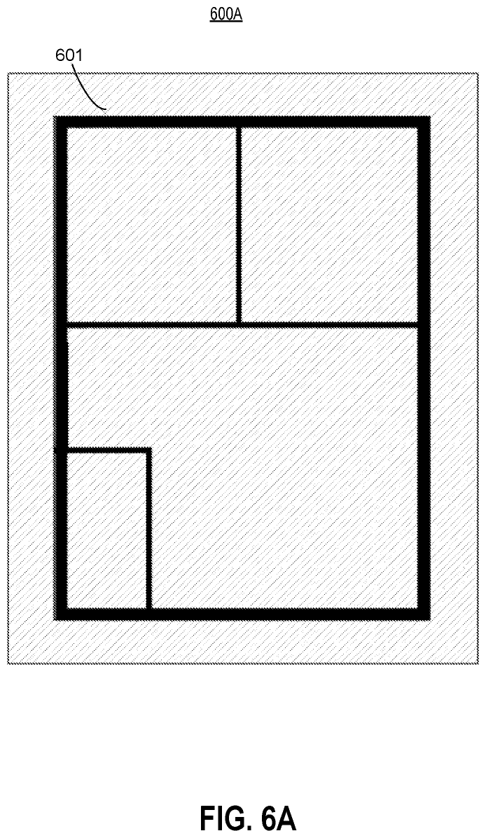

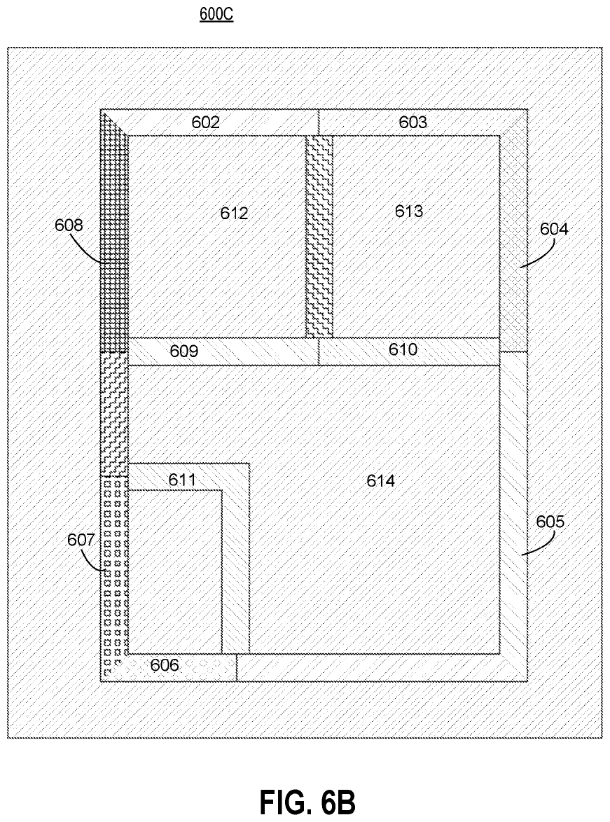

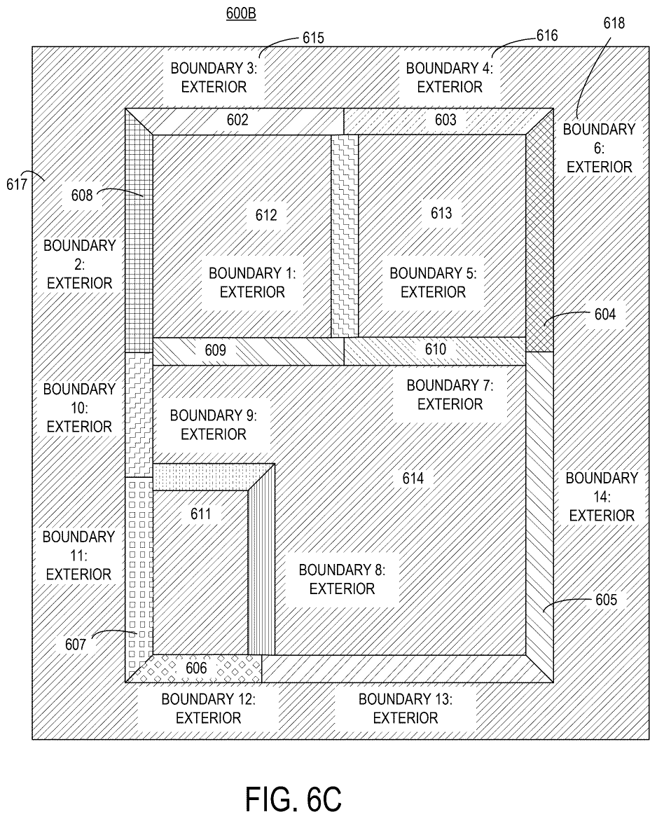

Referring now to FIGS. 6A-6C, in some embodiments, automated and/or user-initiated processes may include refinement of regions, spaces, or areas may involve one or both of a user and a controller identifying individual wall segments 211A from previously defined boundaries.

For example, in some embodiments, a controller running an AI engine may execute processes that are operative to divide a previously predicted boundary into individual wall segments. In FIG. 6A, a user interface 600A includes a representation of a design plan with an original boundary 601 defined from an inputted design.

In FIG. 6B, an AI engine may be operative to take one or more original boundaries 601 and isolate one or more individual line segments 602-611 as shown by different hatching symbols in an illustrated user interface 600B. The identification of individual line segments 602-611 of a boundary 601 enables one or both of a controller and a user to assign and/or retrieve information about the individual line segment 602-611 such as, for example, one or more of: the length of the segment 602-611, a type of wall segment 211A, materials used in the wall segment 211A, parameters of the segment 602-611, height of the segment 602-611, width of the segment 602-611, allocation of the segment 602-611 to a region 612-614 or another, and almost any digital content relevant to the segment.

Referring now to FIG. 6C, in some embodiments, a controller executing an AI engine or other method steps, may be operative, in some embodiments, to classify individual line segments 602-611 of a boundary 601 and present a user interface 600C indicating the classified individual line segments 602-611. The AI engine may be trained, and subsequently operative, to classify individual line segments 602-611 included in a boundary 601 in different classes. As a non-limiting example, an AI engine may classify walls as interior walls, exterior walls and/or demising walls that separate internal spaces.

As illustrated in FIG. 6C, in some embodiments, an individual line segment 602-611 may be classified by the AI engine and an indication of the classification 615-618, such as alphanumeric or symbolic content, may be associated with the individual line segment 602-611 and presented in the user interface 600C.

In some embodiments, functionality may be allocated to classified individual line segments 602-611, such as, by way of non-limiting example, a process that generates an estimated materials list for a region or an area defined by a boundary, based on the regions or area's characteristics and its classification.

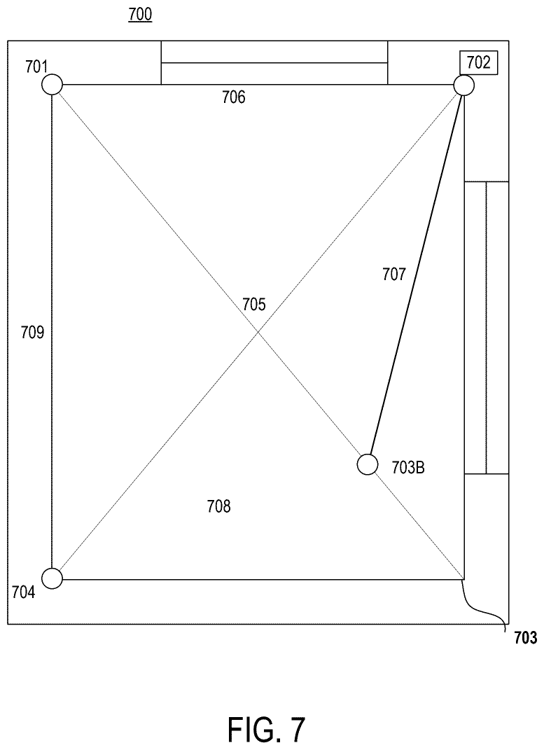

Referring now to FIG. 7 in some embodiments, a user interface 700 may include user interactive controls operative to execute process steps described herein (e.g. make a boundary determination, region classification, segmentation decision or the like) in an automated process (e.g. via an AI routine) and also be able to receive an instruction (e.g. from a user via a user interface, or a controller operative via executable software to perform a process) that modify one or more boundary segments.

For example, a user interface may include one or more vertex 701-704 (e.g., points where two or more line segments meet) that may be user interactive such that a user may position the one or more vertex 701-704 at a user selected position. User positioning may include, for example, user drag and drop of the one or more vertex 701-704 at a desired location or entering a desired position, such as via coordinates. A new position for a vertex 703B may allow an area 705 bounded by user defined boundaries 706-709 User interactive portions of a user interface 700 are not limited to vertex 701-704 and can be any other item 701-709 in the user interface 700 that may facilitate achievement of a purpose by allowing one or both of: the user, and the controller, to control dynamic sizing and/or placement of a feature or other item 701-709.

Still further, in some embodiments, user interaction involving positioning of a vertex 701-704 or modification of an item 705-709 may be used to train an AI engine to improve performance.

### Model Training Procedures

An important aspect of the operation of the systems as have been described is the training of the AI engines that perform the functions as have been defined. A training dataset may involve a set of input drawings associated with a corresponding set of verified outputs. In some embodiments, a historical database of drawings may be analyzed by personnel with expertise in the field. user, including in some embodiments experts in a particular field of endeavor may manipulate dynamic features of a design plan or other aspects of a user interface to be used to train an AI engine, such as by creating or adding to an AI referenced database.

In some other examples, a trained version of an AI engine may produce user interfaces and/or other outputs based on the trained version of the AI engine. Teams of experts may review the results of the AI processing and make corrections as required. Corrected drawings may be provided to the AI engine for renewed training.

### Estimation Automation

Aspects that are determined by a controller running an AI engine to be represented in a design plan may be used to generate an estimate of what will be required to complete a project. For example, according to various embodiments of the present invention, an AI engine may receive as input a two-dimensional reference and generate one or more of: boundaries, areas, fixtures, architectural components, perimeters, linear lengths, distances, volumes, and the like may be determined by a controller running an AI engine to be required to be required to complete a project.

For example, a derived area or region comprising a room and/or a boundary, perimeter or other beginning and end indicator may allow for a building estimate that may integrate choices of materials with associated raw materials costs and with labor estimates all scaled with the derived parameters. The boundary determination function may be integrated with other standard construction estimation software and feed its calculated parameters through APIs. In other examples, the boundary determination function may be supplemented with the equivalent functions of construction estimation to directly provide parametric input to an estimation function. For example, the parameters derived by the boundary determinations may result in estimation of needed quantities like cement, lumber, steel, wall board, floor treatments, carpeting and the like. Associated labor estimates may also be calculated.

As described herein, a controller executing an AI engine may be functional to perform pattern recognition and recognize features or other aspects that are present within an input two-dimensional reference or other graphic design. In a segmentation phase used to determine boundaries of regions or other space features, aspects that are recognized as some artifact other than a boundary may be replaced or deleted from the image. An AI engine and/or user modified resulting boundary determination can be used in additional pattern recognition processing to facilitate accurate recognition of the non-wall features present in the graphic.

For example, in some embodiments, a set of architectural drawings may include many elements depicted such as, by way of non-limiting example, one or more of: windows, exterior doors, interior doors, hallways, elevators, stairs, electrical outlets, wiring paths, floor treatments, lighting, appliances, and the like. In some two-dimensional references, furniture, desks, beds, and the like may be depicted in designated spaces. AI pattern recognition capabilities can also be trained to recognize each of these features and many other such features commonly included in design drawings. In some embodiments, a list of all the recognized image features may be created and also used in the cost estimation protocols as have been described.

In some embodiments of the present invention, a recognized feature may be accompanied on a drawing with textual description which may also be recognized by the AI image recognition capabilities. The textual description may be assessed in the context of the recognized physical features in its proximity and used to supplement the feature identification. Identified feature elements may be compared to a database of feature elements, and matched elements may be married to the location on the architectural plan. In some embodiments, text associated with dimensioning features may be used to refine the identity of a feature. For example, a feature may be identified as an exterior window, but an association of a dimension feature may allow for a specific window type to be recognized. Also, a text input or other narrative may be recognized to provide more specific identification of a window type.

Identified features may be associated with a specific item within a features database. The item within the features database may have associated records that precisely define a vector graphics representation of the element. Therefore, an input graphic design may be reconstituted within the system to locate wall and other boundary elements and then to superimpose a database element graphic associated with the recognized feature. In some embodiments, various feature types and text may be associated into separate layers of a processed architectural design. Thus, a user interface or other output display or on reports, different layers may be illustrated at different times along with associated display of estimation results.

In some embodiments, a drawing may be geolocated by user entry of data associated with the location of a project associated with the input architectural plans. The calculations of raw material, labor and the like may then be adjusted for prevailing conditions in the selected geographic location. Similarly, the geolocation of the drawing may drive additional functionality. The databases associated with the systems may associate a geolocation with a set of codes, standards and the like and review the discovered design elements for compliance. In some embodiments, a list of variances or discovered potential issues may be presented to a user on a display or in a report form. In some embodiments, a function may be offered to remove user entered data and other personally identifiable information associated in the database with a processing of a graphic image.

In some embodiments, a feature determination that is presented to a user in a user interface may be assessed as erroneous in some way by the user. The user interface may include functionality to allow the user to correct the error. The resulting error determination may be included in a training database for the AI engine to help improve its accuracy and functionality.

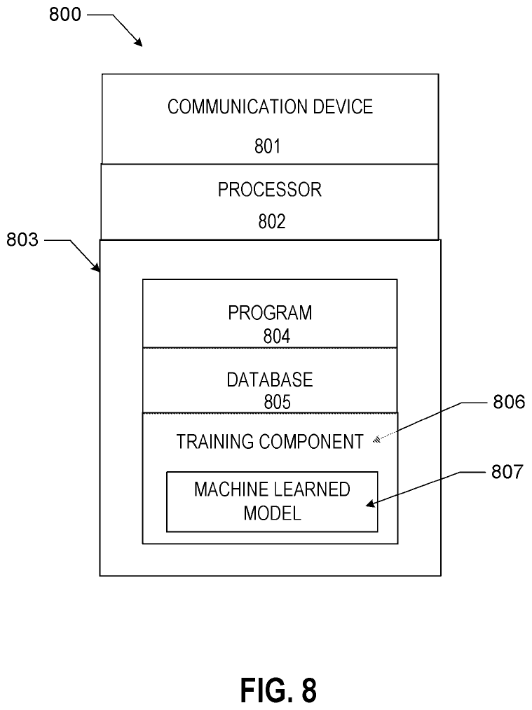

Referring now to FIG. 8, an automated controller is illustrated that may be used to implement various aspects of the present disclosure, in various embodiments, and for various aspects of the present disclosure, controller 800 may be included in one or more of: a wireless tablet or handheld device, a server, a rack mounted processor unit. The controller may be included in one or more of the apparatuses described above, such as a Server, and a Network Access Device. The controller 800 includes a processor unit 802, such as one or more semiconductor-based processors, coupled to a communication device 801 configured to communicate via a communication network (not shown in FIG. 8). The communication device 801 may be used to communicate, for example, with one or more online devices, such as a personal computer, laptop, or a handheld device.

The processor 802 is also in communication with a storage device 803. The storage device 803 may comprise any appropriate information storage device, including combinations of magnetic storage devices (e.g., magnetic tape and hard disk drives), optical storage devices, and/or semiconductor memory devices such as Random Access Memory (RAM) devices and Read Only Memory (ROM) devices.

The storage device 803 can store a software program 804 with executable logic for controlling the processor 802. The processor 802 performs instructions of the software program 804 and thereby operates in accordance with the present disclosure. In some embodiments, the processor may be supplemented with a specialized processor for AI related processing. The processor 802 may also cause the communication device 801 to transmit information, including, in some instances, control commands to operate apparatus to implement the processes described above. The storage device 803 can additionally store related data in a database 805. The processor and storage devices may access an AI training component 806 and database, as needed which may also include storage of machine learned models 807.

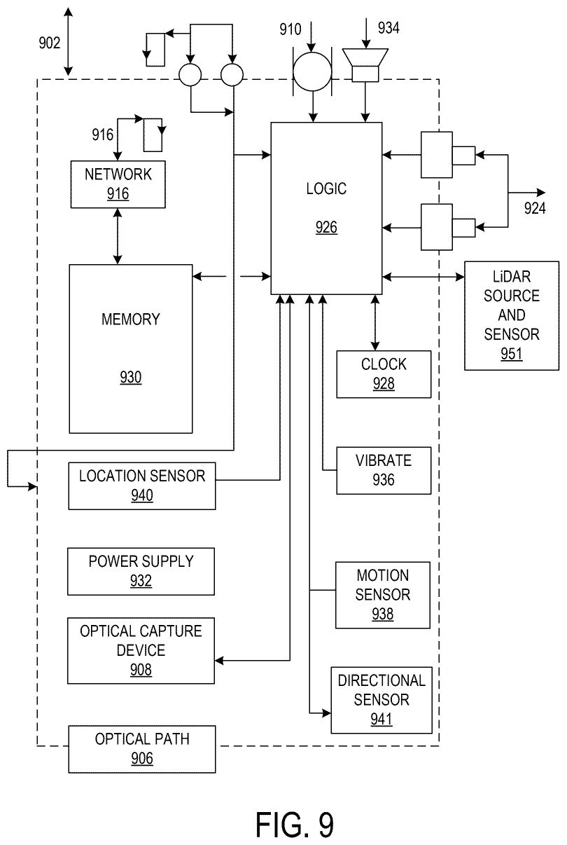

Referring now to FIG. 9, a block diagram of an exemplary mobile device 902 is illustrated. The mobile device 902 comprises an optical capture device 908 to capture an image and convert it to machine-compatible data, and an optical path 906, typically a lens, an aperture, or an image conduit to convey the image from the rendered document to the optical capture device 908. The optical capture device 908 may incorporate a Charge-Coupled Device (CCD), a Complementary Metal Oxide Semiconductor (CMOS) imaging device, or an optical Sensor 924 of another type.

A microphone 910 and associated circuitry may convert the sound of the environment, including spoken words, into machine-compatible signals. Input facilities may exist in the form of buttons, scroll wheels, or other tactile Sensors such as touchpads. In some embodiments, input facilities may include a touchscreen display.

Visual feedback to the user is possible through a visual display, touchscreen display, or indicator lights. Audible feedback 934 may come from a loudspeaker or other audio transducer. Tactile feedback may come from a vibrate module 936.

A motion Sensor 938 and associated circuitry convert the motion of the mobile device 902 into machine-compatible signals. The motion Sensor 938 may comprise an accelerometer that may be used to sense measurable physical acceleration, orientation, vibration, and other movements. In some embodiments, motion Sensor 938 may include a gyroscope or other device to sense different motions.

A location Sensor 940 and associated circuitry may be used to determine the location of the device. The location Sensor 940 may detect Global Position System (GPS) radio signals from satellites or may also use assisted GPS where the mobile device may use a cellular network to decrease the time necessary to determine location.

The mobile device 902 comprises logic 926 to interact with the various other components, possibly processing the received signals into different formats and/or interpretations. Logic 926 may be operable to read and write data and program instructions stored in associated storage or memory 930 such as RAM, ROM, flash, or other suitable memory. It may read a time signal from the clock unit 928. In some embodiments, the mobile device 902 may have an on-board power supply 932. In other embodiments, the mobile device 902 may be powered from a tethered connection to another device, such as a Universal Serial Bus (USB) connection.

The mobile device 902 also includes a network interface 916 to communicate data to a network and/or an associated computing device. Network interface 916 may provide two-way data communication. For example, network interface 916 may operate according to the internet protocol. As another example, network interface 916 may be a local area network (LAN) card allowing a data communication connection to a compatible LAN. As another example, network interface 916 may be a cellular antenna and associated circuitry which may allow the mobile device to communicate over standard wireless data communication networks. In some implementations, network interface 916 may include a Universal Serial Bus (USB) to supply power or transmit data. In some embodiments, other wireless links may also be implemented.

As an example of one use of mobile device 902, a reader may scan an input drawing with the mobile device 902. In some embodiments, the scan may include a bit-mapped image via the optical capture device 908. Logic 926 causes the bit-mapped image to be stored in memory 930 with an associated timestamp read from the clock unit 928. Logic 926 may also perform optical character recognition (OCR) or other post-scan processing on the bit-mapped image to convert it to text.

A directional sensor 941 may also be incorporated into the mobile device 902. The directional device may be a compass and be based upon a magnetic reading or based upon network settings.

A LiDAR sensing system 951 may also be incorporated into the mobile device 902. The LiDAR system may include a scannable laser light (or other collimated) light source which may operate at nonvisible wavelengths such as infrared. An associated sensor device, sensitive to the light of emission may be included in the system to record time and strength of returned signal that is reflected off of surfaces in the environment of the mobile device 902. In some embodiments, as have been described herein, a 2 dimensional drawing or representation may be used as the input data source and, vector representations in various forms may be utilized as a fundamental or alternative input data source. Moreover, in some embodiments, files which may be classified as BIM input files may be directly used as a source on which method steps may be performed. BIM and CAD file formats may include, by way of non-limiting example, one or more of: BIM, RVT, NWD, DWG, IFC and COBie. Features in the BIM or CAD datafile may already have defined boundary aspects having innate definitions such as walls and ceilings and the like. An interactive interface may be generated that receives input from a user indicating a user choice of types of innate boundary aspects a user provides instruction to the controller to perform subsequent processing on.

In some embodiments, a controller may receive user input enabling input data from either a design plan format or similar such formats or also allow the user to access BIM or CAD formats. Artificial intelligence may be used to assess boundaries in different manners depending on the type of input data that is initially inputted. Subsequently, similar processing may be performed to segment defined spaces in useable manners as have been discussed. The segmented spaces may also be processed to determine classifications of the spaces.

As has been described, a system may operate (and AI Training aspects may be focused upon) recognition of lines or vectors as a basic element within an input design plan. However, in some embodiments, other elements may be used as a fundamental element, such as, for example, a polygon and/or series of polygons. The one or more polygons may be assembled to define an area with a boundary, as compared, in some embodiments, with an assembly of line segments or vectors, which together may define a boundary which may be used to define an area. Polygons may include different vertices; however common examples may include triangular facets and quadrilateral polygons. In some embodiments, AI training may be carried out with a singular type of polygonal primitive element (e.g., rectangles), other embodiments will use a more sophisticated model. In some other examples, AI engine training may involve characterizing spaces where the algorithms are allowed to access multiple diverse types of polygons simultaneously. In some embodiments, a system may be allowed to represent boundary conditions as combinations of both polygons and line elements or vectors.

Depending upon one or more factors, such as processing time, a complexity of the feature spaces defined, and a purpose for AI analysis, simplification protocols may be performed as have been described herein. In some embodiments, object recognition, space definition or general simplification may be aided by various object recognition algorithms. In some embodiments, Hough type algorithms may be used to extract diverse types of features from a representation of a space. In other examples, Watershed algorithms may be useful to infer division boundaries between segmented spaces. Other feature recognition algorithms may be useful in determining boundary definitions from building drawings or representations.

In some embodiments, the user may be given access to movement of boundary elements and vertices of boundary elements. In examples where lines or vectors are used to represent boundaries and surrounding areas, a user may move vertices between lines or center points of lines (which may move multiple vertices). In other examples, elements of polygons such as the user may move vertices, sides, and center points. In some embodiments, the determined elements of the space representation may be bundled together in a single layer. In other examples, multiple layers may be used to distinguish distinct aspects. For example, one layer may include the AI optimized boundary elements, another layer may represent area and segmentation aspects, and still another layer may include object elements. In some embodiments, when the user moves an element such as a vertex the effects may be limited only to elements within its own layer. In some examples, a user may elect to move multiple or all layers in an equivalent manner. In still further examples, all elements may be assigned to a single layer and treated equivalently. In some embodiments, users may be given multiple menu options to select disparate elements for processing and adjustment. Features of elements such as color and shading and stylizing aspects may be user selectable. A user may be presented with a user interface that includes dynamic representations of a features or other aspects of a design plan, and associated values and changes may be input by a user. In some embodiments, an algorithm and processor may present to the user comparisons of various aspects within a single model or between different models. Accordingly, in various embodiments, a controller and a user may manipulate aspects of a user interface and AI engine.

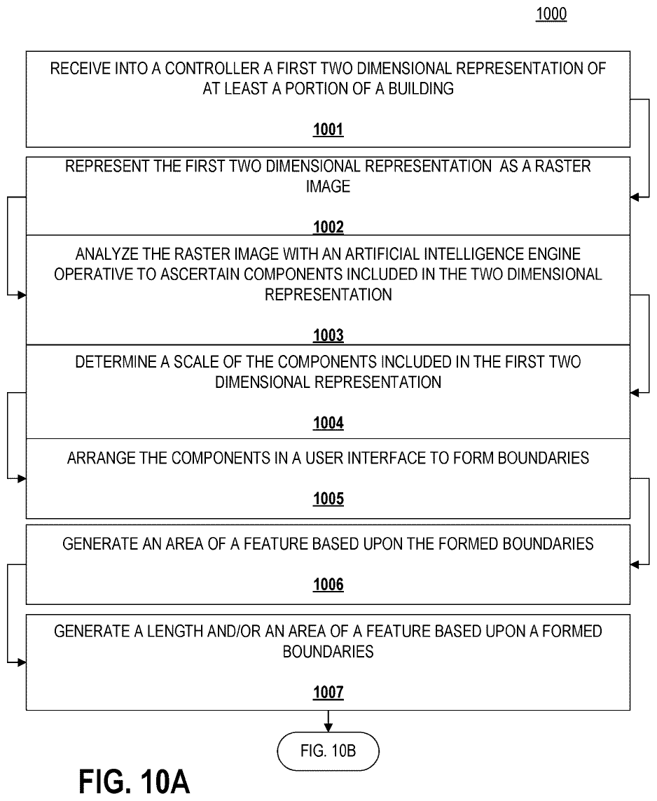

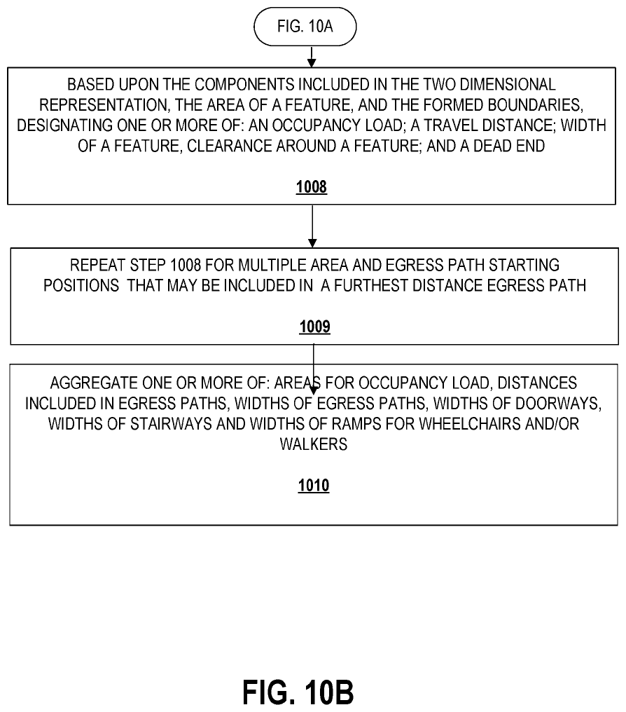

Referring now to FIGS. 10A-10B, method steps 1000 are illustrated for quantifying requirements for compliance of a selected code applied to a building based upon artificial intelligence analysis of a design plan according to some embodiments of the present invention. At step 1001, the method includes receiving into a controller a design plan of at least a portion of a building. As described above, the design plan may include an architectural drawing, floor plan, design drawing and the like.

At step 1002, the portion of a design plan may be represented as a raster image or other image type that is conducive to artificial intelligence analysis, such as, for example, a pixel-based drawing.

At step 1003, the raster image may be analyzed with an artificial intelligence engine that is operative on a controller to ascertain components included in the design plan.

At step 1004, a scale of components included in the design plan may be determined. The scale may be determined, for example, via a scale indicator or ruler included in the design plan, or inclusion in the design plan of a component of a known dimension.

At step 1005, a user interface may be generated that includes at least some of the multiple components.

At step 1006, the components may be arranged in the user interface to form boundaries for various spaces identified in the design plan, including water closet areas.

At step 1007, a length or area of a feature (e.g., room, space, bathroom, fixture item) may be generated based upon a formed boundary.

At step 1008, based upon one or more of components included in at least one or the user interface and the design plan, at least one of: the area of a feature, space or region may be generated and/or a length of a feature may be generated and one or more of: an occupancy load; a travel distance of an egress path; a dead end; a common path; clearance around a feature such as a plumbing fixture (e.g. ADA specified clearance around a toilet); a width of an egress path including doorways, stairways, elevators, and ramps.

At step 1009, one or more of the above steps may be repeated for multiple areas, units and egress paths of a building being described by the design plan.

At step 1010, values of variables specified in a relevant code may be aggregated. The aggregated quantities may include, by way of non-limiting example, one or more of: areas for occupancy, authorized use during occupancy; distances of egress paths; widths of egress paths; widths of doorways; widths of stairways; and widths of ramps suitable for use by a wheelchair and/or walker.

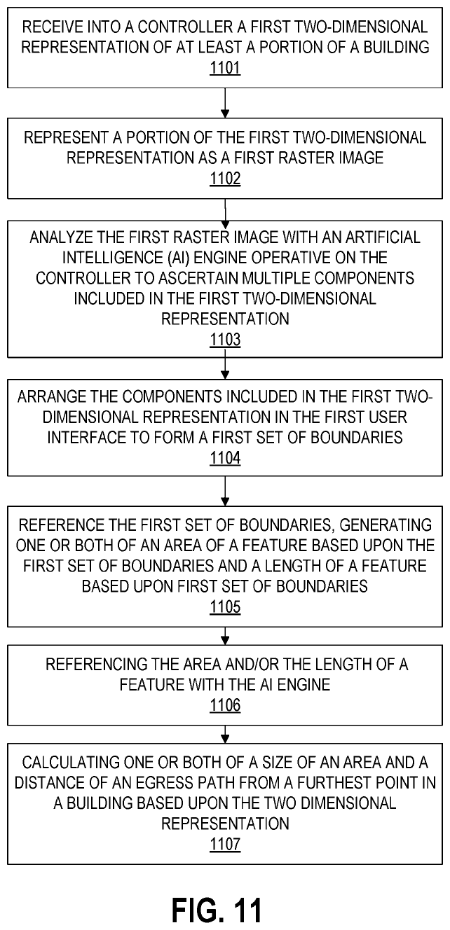

Referring now to FIG. 11, a system including one or more controllers can be configured to perform particular operations or actions by virtue of having executable software, firmware, hardware, or a combination of them that in operation cause the controllers to be operative to perform method steps. In some embodiments, the controller may perform method steps directed to quantifying requirements for construction of a building based upon artificial intelligence analysis of design plans.

At step 1101, the method of quantifying whether requirements for compliance with a relevant code are present in a building may include receiving into a controller a design plan of at least a portion of a building.

At step 1102 the method may include representing a portion of the first design plan as a first raster image; and step 1103 analyzing the first raster image with an artificial intelligence (AI) engine operative on the controller to ascertain multiple components included in the first design plan. The controller may also generate a first user interface including at least some of the multiple components included in the first design plan; and at step 1104, arrange the components included in the first design plan in a first user interface that forms a first set of boundaries.

At step 1105, the method may include generating one or both of an area of a feature based upon the first set of boundaries and a length of a feature based upon first set of boundaries.

At step 1106, the method may include using the AI engine to reference at least one of: the area of the feature and the length of a feature, and at step 1107 the controller may calculate an area or distance of an aspect of the building, such as an area of a unit and/or a distance of an egress path e.g., from a furthest point or from a water closet area.

Any or all of steps 1101-1107 may be repeated for different portions of the two-dimensional reference descriptive of the building.

A scale of one or more components may be determined and a parameter of one or both of a polygon and a line segment may be modified based upon receipt of an instruction for a user; and a boundary may be set based upon reference to a boundary allocation hierarchy.

The steps may be performed multiple times and may include two or more two dimensional references with results of the process be compared one against the other to ascertain when a change has been made to a two-dimensional reference that places a building in compliance with a selected code. In various embodiments, a change in subsequent two-dimensional references may be used to generate a change in one or more of a take-off, labor costs, project management input or other aspects that may impact construction of a building and/or associated costs.

Implementations may include one or more of the following features. The method additionally determining a scale of the components included in the design plan and/or generating a user interface including user interactive areas to change at least one of: a size and shape of at least one of the dynamic components, the dynamic components may include, by way of non-limiting example, one or more of: architectural features, polygons or arcuate shapes; regions, areas, spaces, travel paths, egress paths, dominance hierarchies, occupancy loads, doorways, stairs, or other portion of a design plan that may be modified.

In some embodiments dynamic components may include a polygon and/or arcuate shape. A method of practice of the present invention may further include the steps of: receiving an instruction via the user interactive interface to modify a parameter of the polygon and modifying the parameter of the polygon based upon the instruction received via the interactive user interface. The parameter modified may include one or both of: an area of the polygon; and a shape of the polygon.

In another aspect a dynamic component may include a line segment and/or arcuate segment, and methods of practice may include one or more of: receiving an instruction via a user interactive interface to modify a parameter of the line segment, and the method further includes the step of modifying the parameter of the line segment based upon the instruction received via the interactive user interface. The parameter of the line segment may include a length of the line segment, and the method may additionally include modifying a length of a wall based upon the modifying the length of the line segment.

The parameter modified may additionally include a direction of the line segment and the method may additionally include modifying an area of a room based upon the modifying of the length and direction of the line segment. A boundary may be set based upon reference to a boundary allocation hierarchy.

In another aspect, a price may be associated with each of the quantities of items to be included in construction of the building. In addition, a type of labor associated with at least one of the items to be included in construction of the building may be designated based upon AI analysis of the first two-dimensional reference and the second two-dimensional reference, respectively.

Methods of practice may additionally include the steps of determining whether a design plan received into the controller includes a vector image, and if one of the first and the second design plan received into the controller includes a vector image converting at least a portion of the vector image into a raster image. Implementations of the described techniques may include hardware, a method or process, or computer software on a computer-accessible medium.

Methods of practice may additionally include one or more of the steps of: generating a user interface including user interactive areas to change at least one of: a size and shape of at least one of the dynamic components. At least one of the dynamic components may include a polygon and the method further includes the steps of: receiving an instruction via the user interactive interface to modify a parameter of the polygon and modifying the parameter of the polygon based upon the instruction received via the interactive user interface. The parameter modified may include an area of the polygon and/or a shape of the polygon. Moreover, a modification of a dynamic component included in a polygon may change a calculation of an area of a unit, or other defined space. A change in area of a unit may allow for a recalculation that results in a modification of one or more of: an occupancy load; a length of a path of egress; an length and/or area of a common path; a width of a stair; a travel distance to traverse a dead end; an existence of a dead end; or other variable referenced in determination of compliance with a set of conditions, such as a code relevant to a geopolitical locality and a building.

A dynamic component may include a line segment and/or vector, and the method may further include the steps of receiving an instruction via the user interactive interface to modify a parameter of the line segment and/or vector and modifying the parameter of the line segment and/or vector based upon the instruction received via the interactive user interface. The parameter modified may include a magnitude of the line segment and/or vector and/or a direction of the vector.

The methods may additionally include one or more of the steps of setting a boundary based upon reference to a boundary allocation hierarchy; associating a price with each of the quantities of items to be included construction of the building; totaling the aggregated prices of items to be included construction of the building; designating a type of labor associated with at least one of the items to be included construction of the building; designating a quantity of the type of labor associated with the at least one of the items to be included in construction of the building; repeating the steps of designating a type of labor associated with at least one of the items to be included construction of the building and designating a quantity of the type of labor associated with the at least one of the items to be included in construction of the building for multiple items, and generating an aggregate quantity of the type of labor.

The method may additionally include the step of training the AI engine based upon a human identifying portions of a design plan to indicate that it includes a particular type of item; or to identify portions of the design plan that include a boundary. The AI engine via may also be trained by reference to a boundary allocation hierarchy.

The methods may additionally include the steps of determining whether the design plans received into the controller include a vector image, and if the design plan received into the controller does include a vector image converting at least a portion of the vector image into a raster image; and/or whether a design plan includes a vector image format. Implementations of the described techniques and method steps may include hardware (such as a controller and/or computer server), a method or process, or computer software on a computer-accessible medium.

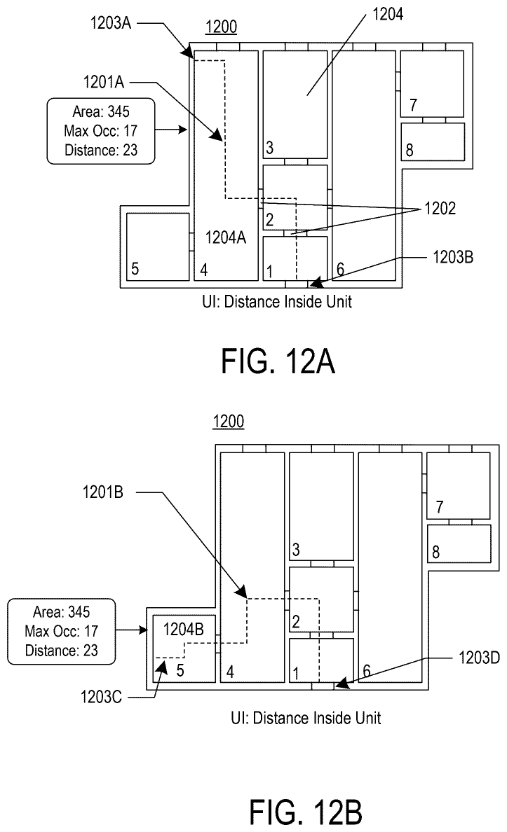

Referring now to FIG. 12A, a diagram of a design plan 1200 of a unit 1200 with an egress path 1201A originating in a first area 1204A inside the unit is illustrated. The egress path 1201A proceeds from a furthermost point of travel 1203A for an occupant, to a point of egress 1203B (in the case illustrated the point of egress includes a door to an exterior of the unit 1204). The egress path 1201A proceeds through two interior doorways 1202. In some preferred embodiments, an egress path will follow a setoff distance from all walls and generally traverse a middle portion of an area or region.

Referring now to FIG. 12B, an egress path 1201B through originating in a second area 1204B inside the unit is illustrated from a second furthest point 1203C in a second area 1204B (may comprise a water closet area) to a point of egress 1203D. In some embodiments, multiple paths of egress 1201A-1201B may be generated, each with a respective distance from an origination point to a point of egress, so that a path of egress with the longest distance may be determined.

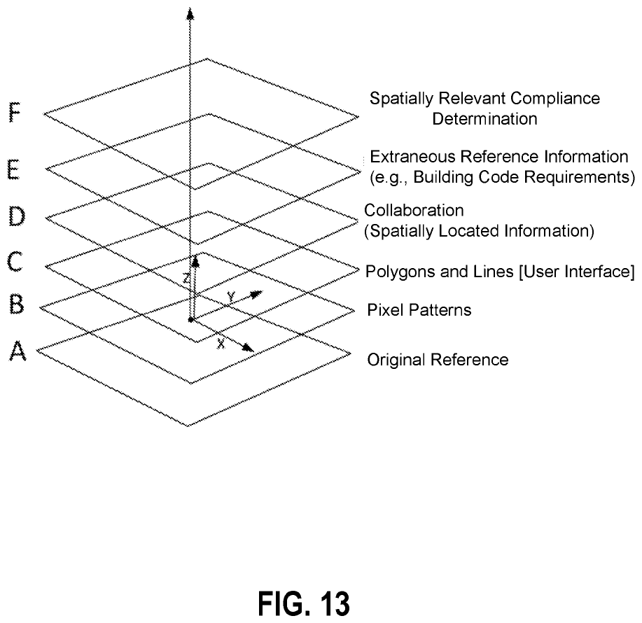

Referring now to FIG. 13, a schematic diagram illustrates a conceptual framework encapsulating a multi-layered structure of an AI-powered collaborative system designed for compliance analysis of design plans, in accordance with the present invention. The framework is divided into six distinct levels, labeled A through F, each representing a different stage or component of the system's operation, ultimately leading to a comprehensive spatially relevant compliance determination.

Starting with Level A, this foundational layer represents the intake of the original reference, such as an architectural drawing or floor plan. The original reference may be a two-dimensional representation of a floor plan used by the AI engine for all analytical processes in compliance analyses. The design plan, typically in a static format such as a PDF, CAD file, or a scanned image, is received into the system at this stage. This level can be seen as the data entry point where the system begins its journey towards transforming static design into a dynamic, interactive, and compliant spatial model. The AI engine begins its work here by recognizing the basic components of the design plan, such as walls, rooms, water closets, and associated fixtures.

Progressing to Level B, the system undertakes the transformation of the original reference into pixel patterns. The pixel data provides the foundation for the AI's analytical capabilities. Each pixel within the design plan is treated as a data point, enabling the AI to detect and distinguish between different shapes, lines, and other design elements. This level is where the raw data begins to take shape, transitioning from a mere visual representation into a structured format that can be processed by the AI. For example, the AI may identify the outline of a room or water closet, the location of a door, or the position of a window (or other fixtures) based on the patterns it recognizes within the pixel data.

At Level C, the pixel patterns identified in Level B are further organized into dynamic elements within the user interface. This layer involves the conversion of pixel data into interactive components like polygons, vectors, and lines, which delineate various design elements and boundaries within the user interface. These dynamic components allow users to engage with the design plan in an interactive manner, adjusting and manipulating elements as necessary. For example, a wall identified at Level B may now be represented as a manipulatable line, and a water closet may be outlined as a polygon that users can click on for further detail.

Level D introduces the collaboration aspect of the system, transforming the design plan into a shared workspace where multiple users can interact with the same data in real-time. At this level, the collaborative platform becomes fully operational, allowing users such as architects, engineers, and code compliance officers to concurrently view, modify, and annotate the design plan. This collaborative capability is particularly useful in large-scale projects where multiple stakeholders need to contribute their expertise simultaneously. For example, an architect may propose a design change, which the engineer can immediately evaluate for structural integrity, and a compliance officer can assess code adherence-all within the same platform. The collaborative nature of this layer provides that changes are tracked, and updates are made visible to all parties, fostering a more integrated and cohesive workflow. The real-time interaction helps prevent miscommunications and allows everyone involved in the project to work with the most current version of the design plan.

Level E expands the system's functionality by integrating various standards and compliance protocols. Level E illustrates how the AI engine may be beneficially employed for applying relevant building codes, safety regulations, and accessibility standards to the design plan. The AI at this level provides cross-referencing spatial data from the various levels with a database of compliance requirements. In some embodiments the compliance requirements may include a vast number of disparate conditions to be met in order to comply with requirements (or preferences of multiple disparate authorities having jurisdiction). For example, the AI may check whether the width of a pathway from water closets meets a minimum accessibility requirement, or if a placement of fire exits complies with local safety codes.

Finally, Level F represents the culmination of the entire process, where spatially relevant compliance determination is made. At this level, the AI engine generates a final assessment of the design plan's compliance status, based on the analysis performed in the previous levels. The output may include a comprehensive report detailing areas of compliance, non-compliance, and suggestions for improvement. For example, the AI engine may identify that a restroom does not meet ADA standards due to insufficient clearance around a water closet and provide recommendations for how to adjust the layout to achieve compliance. The final level also allows users to visualize the compliance status in a spatial context, perhaps by highlighting compliant and non-compliant areas in different colors within the user interface.

### User Interaction and Experience

In some embodiments, the present invention includes a controller operative to analyze a building described via one or more of: a floorplan, two-dimensional reference, and/or Revit® compatible file, to ascertain whether the building described possesses a set of conditions useful to determine compliance with code set. In addition, in some embodiments, a process executed by an AI engine may ascertain building attributes and analyze the building attributes may be modified in order to bring the building into compliance. A user interface may present suggested modifications to a user. Some embodiments may also include designation and/or ranking of variables that may be modified in order to bring a building into compliance. By way of non-limiting example, variables may relate to one or more of: magnitude of structural changes, cost to implement changes, time to implement changes, impact of a change(s) on a desired use of the building, and duration of a proposed change.

In another aspect, in some embodiments, suggested modifications may be ranked according to a priority ranking of features input via a user interface. For example, a user may input priority rankings that dictate that a number of a certain type of room or unit must be maintained above a threshold within the plan, such as, for example, the plan must include: ten residential units, each unit with three bedrooms and two bathrooms and kitchen a living room; or at least four units with three bedrooms each; a second priority may include room sizes of a minimum and/or maximum size; a third priority may include a washer and dryer area; a fourth priority may include a common area of a minimum size; and other prioritized attributes to be included in a building design. AI and/or user input may modify a design of the building to bring the building into compliance with an applicable code while also adhering to the priority ranking of features.

Still further, in some embodiments, the controller may assess how assignment of different classes of space to one or more designated areas may alter conformance of a design with a specified code. Furthermore, in some embodiments, particular attributes of a building may be analyzed based upon laws or regulations in effect within a geopolitical boundary encompassing the building. In some embodiments, multiple disparate user interfaces may be used to communicate calculated parameters associated with determined attributes in order to give a user an improved experience while determining code compliance of a given design plan, as well as changes in a determination of code compliance based upon a change in one or more of the building attributes.

In an example, a user interface may be designed for an optimal user experience in evaluating an existence (or non-existence) of attributes necessary in order for a design plan to be in compliance with a specified code. In some embodiments a design may be evaluated by any of the various processes as have been described herein. After a design plan is received into a controller, an interface may be presented to a user to allow for interactive assessment of attributes required for code compliance.

Some embodiments may comprise alternative methods of receiving data from various sources that can be used to generate a design or to supplement a design created in the manners as have been described previously. For example, the system may receive an architectural file with intelligent features of various kinds which will be discussed in further detail following. The present system may operate in concert with a BIM or CAD design system for example, as an add-in to these design systems and then the present system may have access to design elements, location data and the like directly. In other examples, the present system may access BIM or CAD design system data by loading data files from said systems. In still further examples, the present system may operate to capture data from display screens that are displaying designs from the said BIM or CAD design systems.

In a non-limiting example, the present system may receive a file in one of the REVIT native formats such as files of types RVT, RFA, RTE and RFT. Embodiments may also include receiving non-Revit compatible file formats, such as, one or more of: BMP, PNG, JPG, JPEG, and TIF.

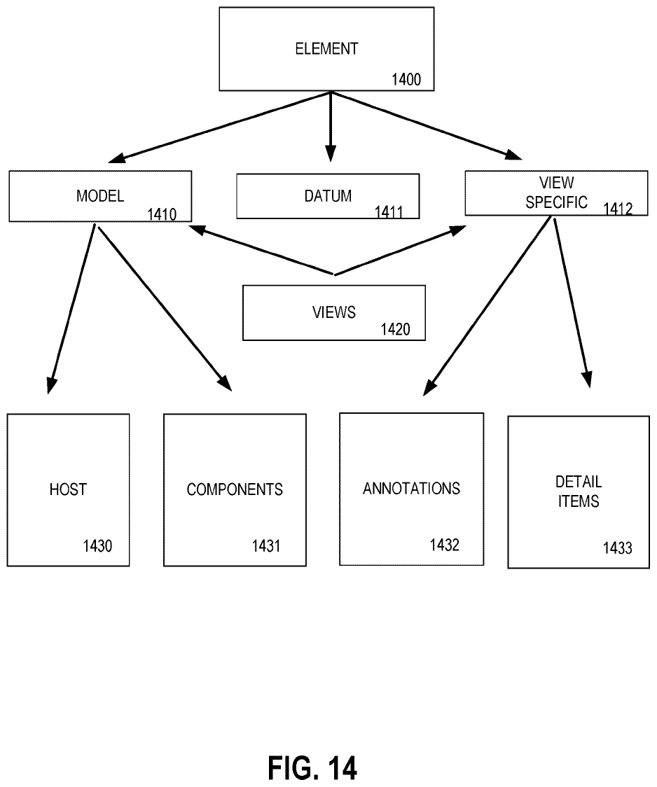

Referring now to FIG. 14, a high level review of the type of information that may be stored in such a filetype is provided, in general, for Revit file types. As shown, the datafile may include objects that may be considered elements 1400. The elements may be of different types such as model elements, datum elements and view-specific elements. Model elements 1410 may correspond to physical elements that are constructed. These may include, amongst others, such elements as floors, walls, ceilings, walls that include structural support aspects, roofs, and the like which may be considered “Hosts” 1430. Other model elements 1400 may include components 1431. Components 1431 may include features such as windows, doors and cabinets and the like. Components may also include beams, braces and structural columns amongst other such features. An artificial intelligence based analysis system may be used to load such features from a file and recognize their content and context based upon direction information in the file as well as learned aspects.

The Datum elements 1411 may include aspects that define the design context. These may include contextual support such as definition of grids, which in some cases may be used to “snap” elements or components to. The Datum elements 1411 may also include levels which may organize components and elements into similar groups. The Datum elements 1411 may include reference planes to support specifically locating and placing elements and components in a design.

The files may also include view-specific elements 1412. View specific elements may be details and annotation elements that appear only when specific views 1420 are activated. Annotation elements 1432 may include keynotes, comments, tags, dimensions, and other such annotations. Detail elements 1433 may include detail lines, filling of various aspects and other such components.

These various elements may be loaded from exemplary files and extracted for their relevant information. Other file types in addition to the Revit® types previously mentioned may include in a non-limiting sense DGN, DWF, DWG, DXF, IFC, SAT, SKP, ODBC, HTML, TXT, and gbXML file types. As mentioned, systems of the present type may be configured to extract information based on defined file structure of the input file times. In addition, learned aspects may be applied to interpret the designs and assign components or alter certain information about a component. For example, a wall definition may be recognized by the present system and have aspects of it modified, and additional model aspects defined such as an appropriate center line defined, or a set of different dividing line types assigned. The wall may have a designation assigned such as whether it is an internal or external wall. Other such learned assignments may be applied after data is loaded from an external file. As mentioned, the present system may also operate in manners where it has access to objects of the BIM or CAD design system directly as an add-in, or a parallel running system with access to memory locations running in the BIM or CAD design system. Still further examples may derive from capturing design elements in displays of various kinds. Finally, such access to external file types may be used to verify models generated in the standard manners as have been described or add information such as annotations, descriptions, and other such aspects.

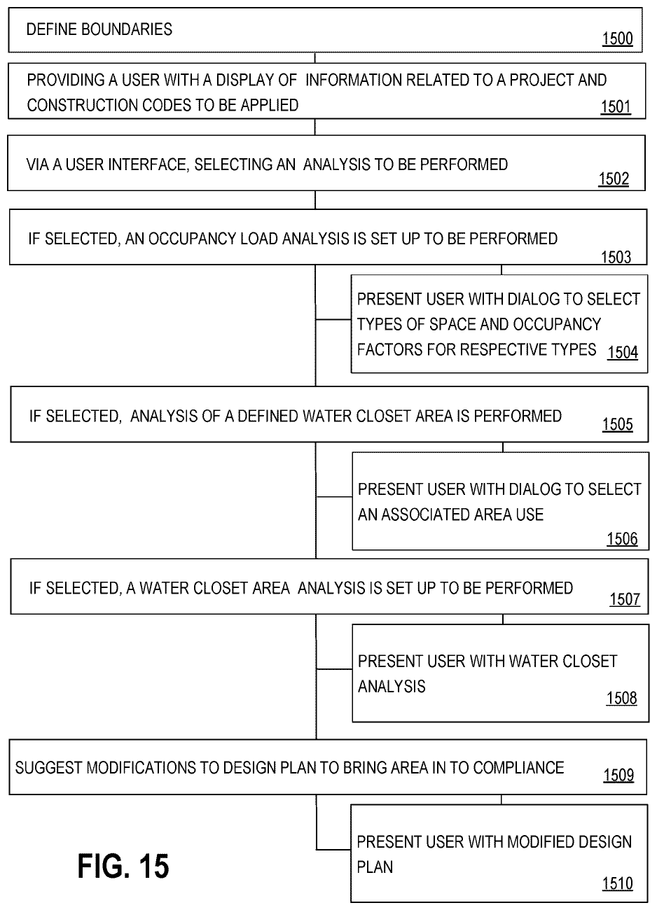

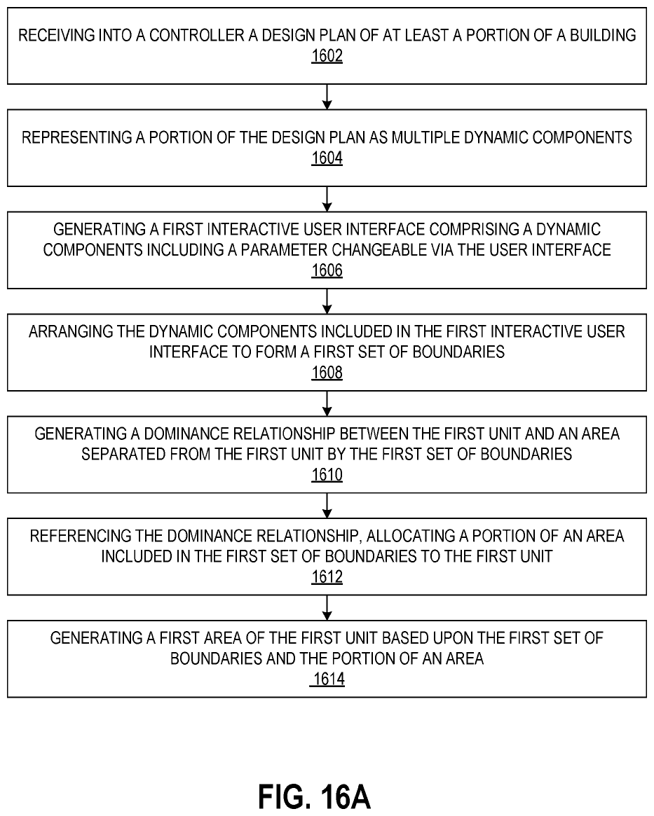

Referring now to FIG. 15 exemplary method steps that may be completed in accordance with the present invention are illustrated. The method steps may be part of a user experience.

At step 1500, boundaries may be defined. This step is foundational, as the boundaries set the stage for subsequent analyses by clearly delineating spaces, such as rooms, corridors, or specific areas like water closets, which will be subject to compliance checks.

At step 1501, the user may be provided with an interactive user interface that displays project information, including building attributes that are included in a determination of compliance with a set of conditions, such as statutory or regulatory codes. The user interface allows users to review essential details and understand the scope of compliance that needs to be met.

At step 1502, the user may select an analysis to be performed. In some embodiments, the options for the analysis may include an analysis of a building for attributes that pertain to, one or more of: water closet clearance, plumbing fixture counts, and wheelchair turning spaces described in a design plan (or other reference). In some examples, multiple analyses or all offered analyses may be chosen by the user. Since a choice of all analysis may proceed through all exemplary analysis, the example in the illustration will proceed with this choice.

At step 1503, if an occupancy load analysis is selected, the system sets up this analysis. Occupancy load is used for determining how many people can safely occupy a space, use a water closet, or safely escape especially in emergency situations.

At step 1504, in some examples, the user may decide on the types of space to be used along with an occupant load factor for the associated type of space. In some examples, the user may enter descriptions and factors manually. In other examples, a drop-down dialog may be presented to the user for them to choose the space types. In some examples, the user may enter associated space use factors. In other examples, an automatic look up of the space's associated space use factor may occur with a choice of the type of space. In some examples, an associated code to be used for appropriate regions may be displayed to the user. In some embodiments, optical character recognition may be performed on located code documents to look up the appropriate occupant load factors automatically. As well, as mentioned in some examples, the user may input the types of area for a design, while in other examples algorithms may be used to automatically classify areas by type.

At step 1505, if an analysis of a defined water closet area is selected, the system proceeds with this analysis. The AI engine will scrutinize the water closet area for compliance with accessibility standards and other relevant codes, determining if the design meets the necessary requirements.

At step 1506, the system presents the user with a dialog allowing them to input an associated water closet area use, such as whether the space is part of a residential unit, a restaurant, an office, retail space, or another type of area. This input helps the system apply the correct compliance standards based on the specific use case of the water closet area.

At step 1507, the system may perform an analysis of the common path, which involves checking the accessibility and safety of pathways leading to and from the water closet area, providing they comply with standards for emergency egress and accessibility.

At step 1508, one or more results of the analysis are presented to the user. These results may include a detailed breakdown of compliant and non-compliant aspects of the water closet design, with suggestions for improvement where necessary.

At step 1509, the system may suggest modifications to the design plan to bring non-compliant areas into compliance. These suggestions may range from adjusting the layout to increasing clearance around water closets or repositioning elements like doors, lavatories, fixtures, or walls to meet regulatory requirements.

At step 1510, the user may be presented with a modified design of a floorplan that improves compliance with one or more code requirements from an authority having jurisdiction over the building containing the water closet.

In some examples, where non-compliant aspects are detected, the AI engine, trained on numerous examples of non-compliant designs and their subsequent modifications, may suggest specific changes to remediate these issues. These suggestions may involve adding free space around a water closet, relocating design elements, or even adding new fixtures or areas to meet compliance standards.

Highlighting tools, such as those previously described, may be used to indicate both compliant and non-compliant aspects of the design. The system may display relevant portions of the code in an overlay or pop-up window, matched to the design under analysis through coloration or other visual indicators. This approach enhances the effectiveness and efficiency of inspectors and designers by providing a clear, summarized view of the design's compliance status.

Additional tools within the user interface may include features like click-and-drag options for selecting rooms, overlaying symbols and icons on the design, and zoom capabilities for detailed reviews. Users can also check the calibration of the design scale or even recalibrate it, prompting the system to reassess compliance based on the updated measurements.

In some examples, where there are non-compliant aspects, a trained artificial intelligence analysis of numerous examples of non-compliant designs and their subsequent design changes that remediated the issues may be used to suggest modifications based on an analysis of the design under review. In other examples, other algorithms may be used to provide such suggestions, such as by review of databases which track commonly required changes to make a building conform to requirements. Examples of improvements which the system may recommend to a user may include adding space free of impediments around a water closet. In other examples, design elements such as walls, lavatories, doors, etc. may be relocated to address non-compliance. Still further examples may address non-compliance aspects by adding features such as by suggesting the adding of a water closet or area of a building as a non-limiting example.

Highlighting, such as in the ways previously described, may be used to indicate one or both of points of compliance and points of non-compliance. The relevant portions of the code may be displayed such as in an overlay, or a pop-up window and may be matched in various manners to the design under analysis, such as with coloration as a non-limiting example. Alternatively, points of non-compliance may be highlighted. These aspects of the user interface experience may improve effectiveness and/or efficiency for inspectors by providing this highlighting or other summarization of points of compliance and points of non-compliance.

Other tools may also be provided through the user interface experience to support users such as, for example, allowing the user to click and drag a cursor over a space designated as a room. Various symbols and icons may be overlayed on the design to indicate various artifacts, corners, stairs, measurements such as door width, access to measurements or design data of various kinds and the like. The user may be able to zoom to portions of the drawing for more detailed review and/or the display of more detailed measurements and design data. Furthermore, the user may be able to zoom to features such as in a non-limiting example, a doorway to allow a check of calibration of the scale of the design or even a recalibration of the scale, where such a recalibration may drive a reassessment of compliance by the system.

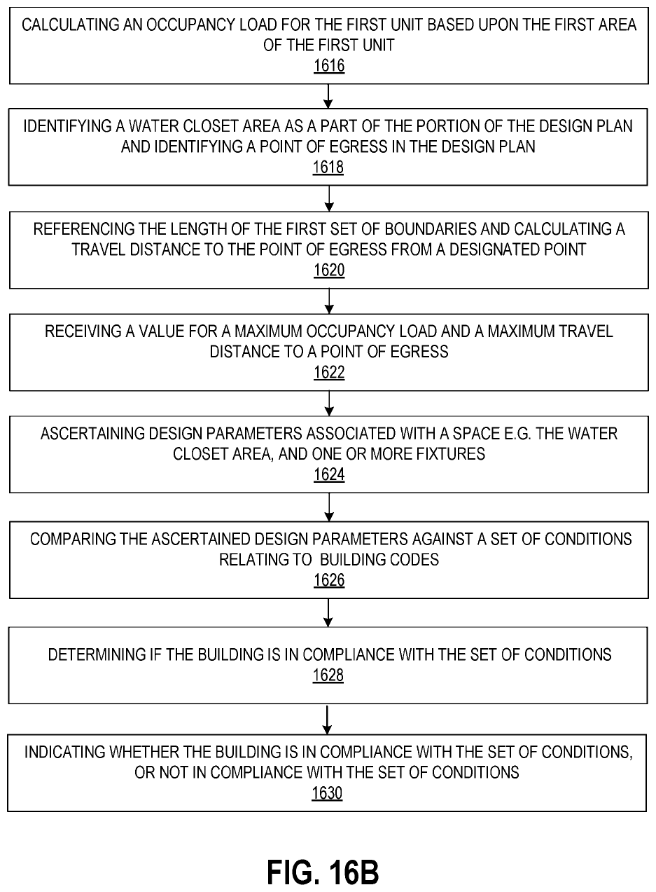

FIGS. 16A and 16B illustrate flowcharts that describe methods, according to some embodiments of the present disclosure. The methods involve a series of steps for analyzing and determining water closet compliance with relevant building codes, utilizing a combination of artificial intelligence (AI) and user interaction. This comprehensive process can be applied to design plans of various building types, determining that all necessary regulatory standards are met. According to the present invention, a method of practice may include the steps of:

At step 1602, the method begins with receiving into a controller a design plan of at least a portion of a building. This step involves importing the architectural floor plans or design documents into the AI-driven system, where they serve as the foundational input for subsequent analysis. The design plan may include detailed layouts of water closets, surrounding spaces, and other relevant features.

At step 1604, the method continues with representing a portion of the design plan as multiple dynamic components. These dynamic components can include elements such as lines, polygons, vectors, walls, doors, fixtures, and other critical architectural features within the design plan. Each of these components is treated as an independent, manipulable entity within the system.

Step 1606 involves generating a first interactive user interface comprising dynamic components including a parameter changeable via the user interactive interface. Here, the user interface is populated with the dynamic components from the design plan, enabling users to interact with and modify these components directly. For example, users can adjust the placement of a water closet, alter the dimensions of a clearance space, or change the orientation of fixtures, all within the interactive environment.

At step 1608, the method includes arranging the dynamic components included in the first interactive user interface to form a first set of boundaries. This step may define the spatial limits of different areas within the design plan, such as the boundaries around a water closet. These boundaries may include measurements for compliance, such as determining that the clearance space around a water closet meets the required dimensions set by building codes.

In step 1610, the method proceeds by generating a dominance relationship between the first unit and an area separated from the first unit by the first set of boundaries. For example, a dominance relationship may determine that a water closet area takes precedence over an adjacent hallway, influencing how space is allocated between these two areas.

At step 1612, the method includes referencing the dominance relationship, allocating a portion of an area included in the first set of boundaries to the first unit. This step may involve assigning additional space to a water closet area to meet minimum clearance requirements or reallocating space from an adjacent area to comply with accessibility standards.

Step 1614 involves generating a first area of the first unit based upon the first set of boundaries and the portion of an area included in the first set of boundaries that may be allocated to the first unit. For example, the system may calculate the total square footage of a water closet area, determining if it meets minimum size requirements as specified by relevant codes.

At step 1616, the method begins with calculating an occupancy load for the first unit based upon the first area of the first unit. This step involves determining the maximum number of occupants that a space, such as a water closet area, can safely accommodate based on its size and layout.

At step 1618, the method includes identifying a water closet area as a part of the portion of the design plan and identifying a point of egress in the design plan. This step is essential for assessing the accessibility and safety of the water closet area, particularly in emergency situations where rapid egress is necessary.

Step 1620 involves referencing the length of the first set of boundaries and calculating a travel distance to the point of egress from a designated point. The system calculates the distance users must travel from a further point or from the water closet area to an exit, determining that it falls within the maximum allowable distance specified by building codes.

At step 1622, the method proceeds with receiving a value for a maximum occupancy load and a maximum travel distance to a point of egress. This step integrates regulatory limits, allowing the system to compare the calculated values against these benchmarks to evaluate compliance.

Step 1624 involves ascertaining design parameters associated with a space e.g., the water closet area, and one or more fixtures. These design parameters may include dimensions, placement, and orientation of fixtures like toilets, urinals, sinks, and other elements within the water closet area.

At step 1626, the method includes comparing the ascertained design parameters against a set of conditions relating to the building code. The system evaluates whether the design parameters meet the specific requirements outlined in relevant building codes, focusing on aspects like fixture spacing, accessibility, and safety standards.

In step 1628, the method involves determining if the building is in compliance with the set of conditions. This determination is based on the comparison in the previous step, where the system assesses if all regulatory requirements have been satisfied. In some, embodiments, the compliance determination may involve simulating a virtual user or a virtual wheelchair within a space e.g., a water closet.

Finally, at step 1630, the method includes indicating whether the building is in compliance with the set of conditions, or not in compliance with the set of conditions. The system provides a clear indication to the user, highlighting areas of compliance and non-compliance within the water closet area. If non-compliance is detected, the system may also suggest modifications to bring the design into compliance.

In some embodiments, the method may additionally include determining a scale of the components included in the design plan and/or referencing the dynamic components and determining a width of one or more of: a size of an area adjacent to a water closet and a distance from a center line of a water closet to a lavatory.

In some embodiments, the method may also include training the AI engine via a human identifying portions of the design plan as a particular type of component and associating a pattern of pixels with the portions of the design plan.

Another aspect may include generating suggested modifications to a design plan in order to meet compliance with a set of conditions. Modifications may include, by way of non-limiting example, including a doorway, changing a length of a wall, widening the path of egress, eliminating a dead end, such as, for example, via inclusion of an additional wall.

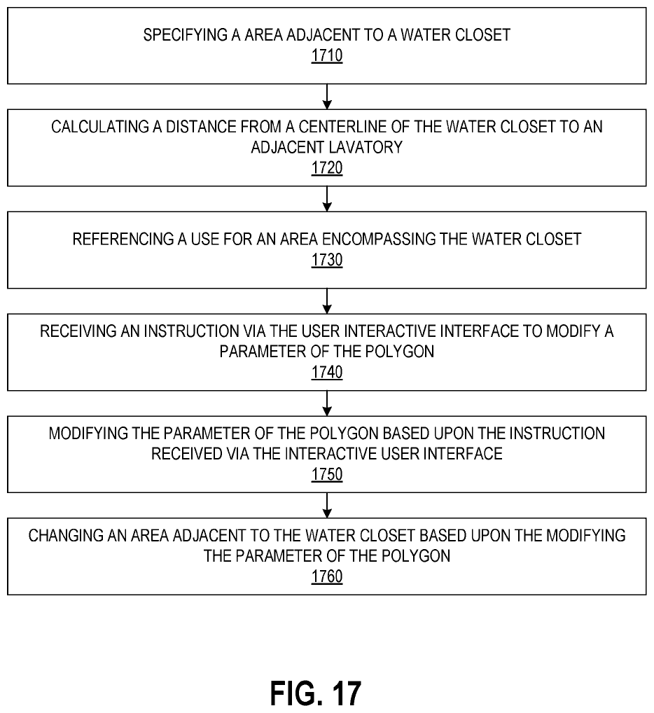

FIG. 17 illustrates a flowchart that describes additional method steps according to some embodiments of the present disclosure. At step 1710, the method may include specifying an area adjacent to a water closet. At step 1720, the method may include a distance from a center line of the water closet to a nearby lavatory. At step 1730, the method may include referencing a use for an area encompassing the water closet.

In some embodiments, some steps of the processes described herein may be repeated for multiple units included in a design plan. For example, the steps of: arranging the dynamic components included in the first interactive user interface to form a first set of boundaries, the first set of boundaries comprising a respective length and area, and said first set of boundaries defining at least a portion of a first unit; generating a dominance relationship between the first unit and an area separated from the first unit by the first set of boundaries; referencing the dominance relationship, allocating a portion of an area included in the first set of boundaries to the first unit; generating a first area of the first unit based upon the first set of boundaries and the portion of an area included in the first set of boundaries that is allocated to the first unit; calculating an occupancy load for the first unit based upon the first area of the first unit; identifying a point of egress in the design plan; and with the controller, referencing the length of the first set of boundaries and calculating a travel distance to the point of egress from a designated point included in the first unit; may be repeated multiple times for multiple respective units.

In some embodiments, a geopolitical locality with jurisdiction over a situs of the building may be determined and a set of conditions specified by a building code adopted by the locality with jurisdiction over a situs of the building may be used in the methods described.

At step 1740, the method may include receiving an instruction via the user interactive interface to modify a parameter of the polygon. At step 1750, the method may include modifying the parameter of the polygon based upon the instruction received via the interactive user interface.

At step 1760, the method may include changing an area adjacent to the water closet based upon the modifying the parameter of the polygon.

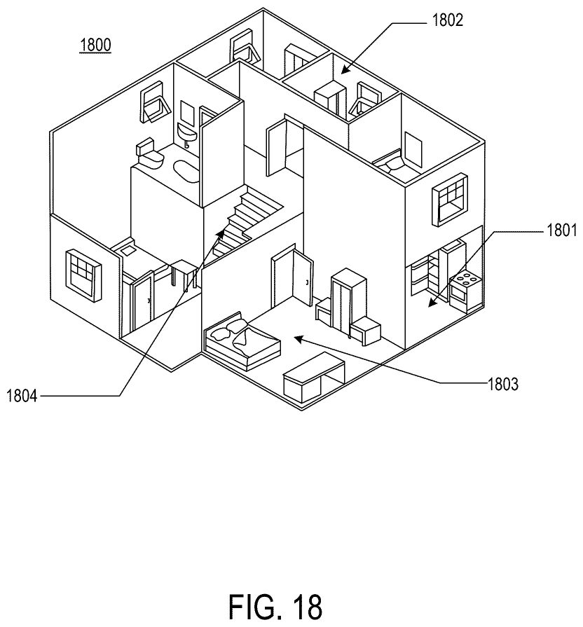

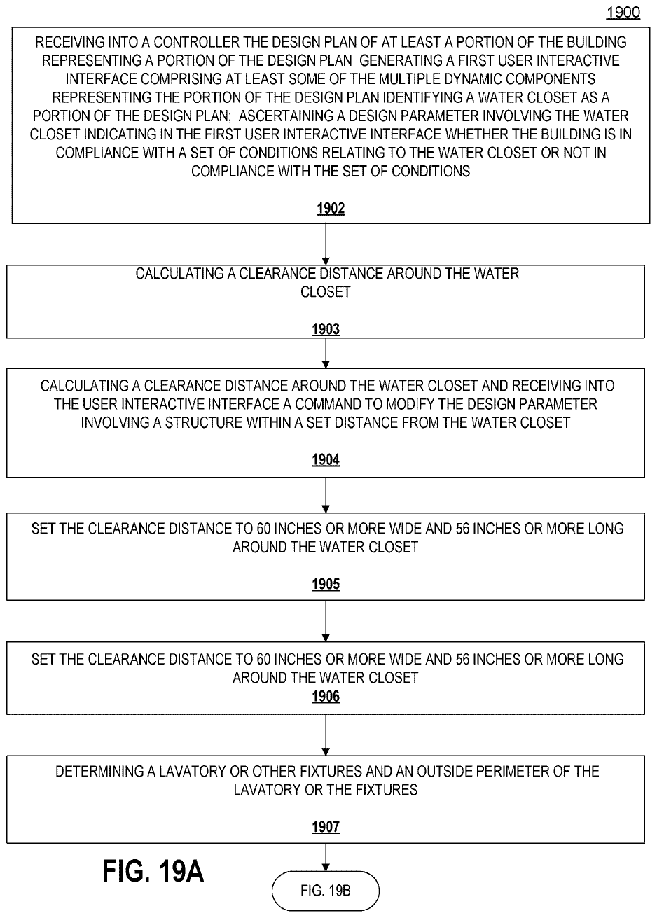

Referring now to FIG. 18, an exemplary multi-story building 1800, such as a single family residence, is illustrated in a perspective view. The multi-story building 1800 may include: contained rooms (or other areas) such as a kitchen 1801 and a bedroom 1802; a multi-story open area 1803; and a stairway 1804. Other architectural features and design aspects may also be included in a two-dimensional or three-dimensional representation of the multi-story building 1800. Codes governing proper allocation of water closets may be chosen based upon a use of the various rooms 1801-1804.

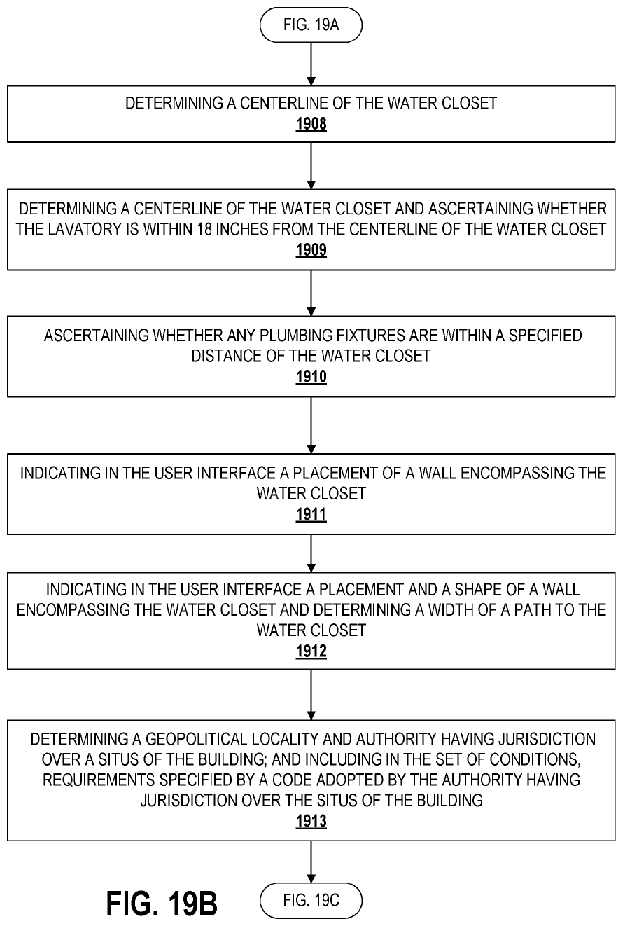

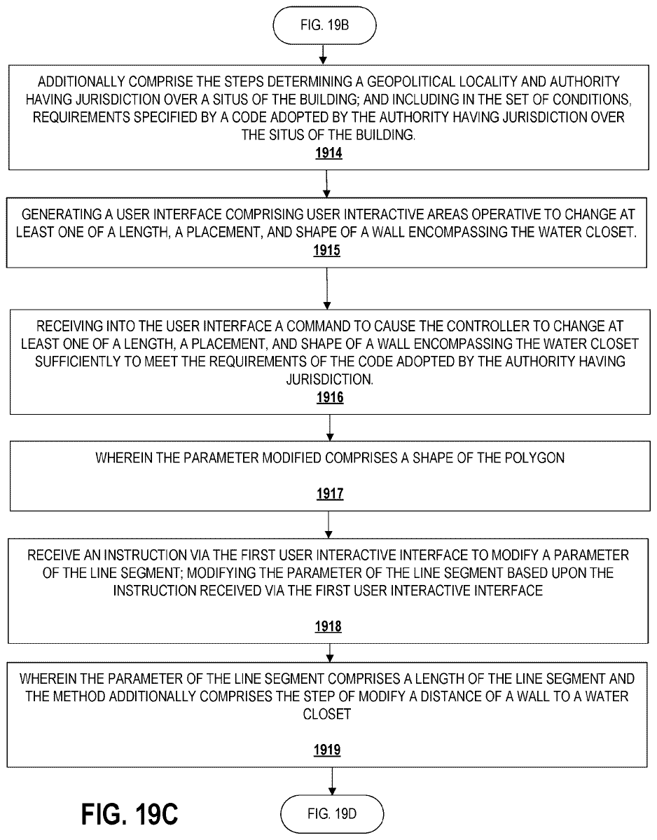

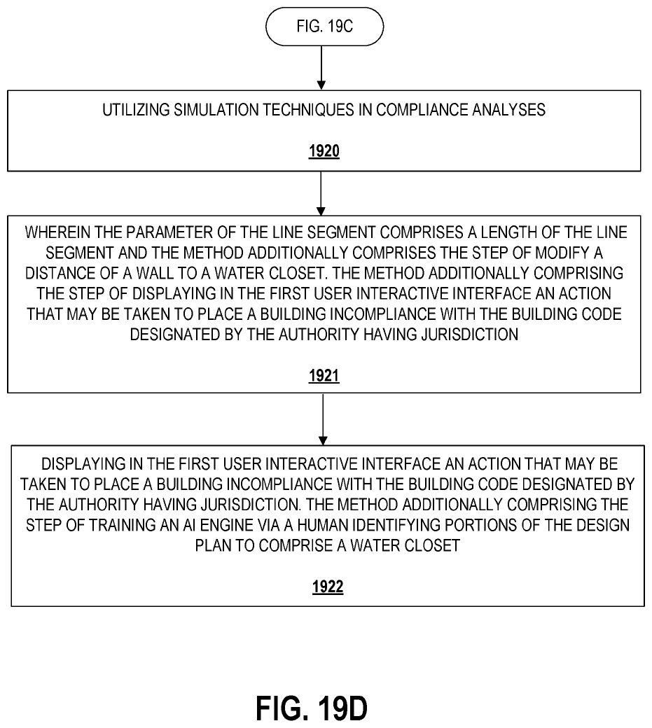

Referring now to FIGS. 19A-19D, a flowchart 1900 illustrates exemplary processes that may be performed in some embodiments of the present invention for analyzing water closet compliance with relevant building codes. These processes leverage AI-powered tools integrated into a controller system to facilitate and streamline the compliance determination process through a user-interactive interface.

At step 1902, the process begins with receiving into a controller the design plan of at least a portion of the building. This step involves uploading or importing the architectural design plan, which may include floor plans, sections, elevations, or other drawings that represent the layout and features of a building. The design plan is then converted into dynamic components by the controller, enabling it to recognize different elements within the plan, such as walls, fixtures, and spaces. The controller then generates a first user-interactive interface, which displays these dynamic components. This interface is key for users to interact with the design, allowing them to make changes, assess compliance, and view real-time feedback on whether the building meets a set of conditions related to water closet compliance.

At step 1903, the method focuses on calculating a clearance distance around the water closet. This step is required in determining whether the space around the water closet is sufficient to meet the standards set by building codes, particularly those related to accessibility. The clearance distance is calculated based on the spatial arrangement of walls, fixtures, and other elements within the water closet area. The controller uses this data to evaluate whether the space allows for the necessary maneuvering, especially for individuals who may use mobility aids such as wheelchairs.

At step 1904, the method enhances interactivity by calculating a clearance distance around the water closet and receiving into the user interactive interface a command to modify the design parameter involving a structure within a set distance from the water closet. This step allows the user to actively engage with the design, making modifications to bring the design plan to compliance. For example, if the clearance distance is found to be insufficient, the user can command the system to adjust the placement of walls, fixtures, or other elements within the specified distance, thereby improving the design's compliance with relevant codes.

Steps 1905 and 1906 both emphasize the importance of setting the clearance distance to 60 inches or more wide and 56 inches or more long around the water closet. These dimensions are useful requirements for determining accessibility, particularly under guidelines like the Americans with Disabilities Act (ADA). By setting these dimensions, the system helps to bring the water closet area to compliance with the necessary standards, providing adequate space for users to maneuver comfortably and safely.

At step 1907, the method involves determining whether a lavatory or other fixtures are within the specified clearance distance and examining the outside perimeter of these fixtures. This step is vital because the placement of fixtures like lavatories, sinks, and other elements can impact the overall accessibility and functionality of the water closet area. The system checks whether these fixtures encroach upon the required clearance space, which can hinder movement or accessibility. If any fixtures are found to be within the prohibited zone, the system can suggest modifications, such as relocating the fixture or adjusting the layout, to bring the design into compliance.

At step 1908, the process involves determining a centerline of the water closet. This step is fundamental for assessing the symmetrical placement of the water closet within the designated space. The centerline serves as a reference point from which other measurements and spatial arrangements are calculated, such as the distance to adjacent fixtures or walls. Accurately identifying this centerline is important for determining that the water closet is positioned correctly according to design specifications and relevant codes.

At step 1909, the method further refines the analysis by determining a centerline of the water closet and ascertaining whether the lavatory is within 18 inches from the centerline of the water closet. This step focuses on verifying the spatial relationship between the water closet and the lavatory, so that the lavatory is placed within the allowable proximity. The 18-inch distance is typically a standard requirement to facilitate ease of use and accessibility. The system checks this distance to determine if the design meets the required guidelines, allowing for adjustments if necessary.

Step 1910 involves ascertaining whether any plumbing fixtures are within a specified distance of the water closet. This step is essential for evaluating the placement of plumbing fixtures such as sinks, bidets, or showers relative to the water closet. The system checks whether these fixtures are within the permissible distance as defined by the relevant building codes. This analysis helps to prevent overcrowding and provide sufficient space for users to move around comfortably.

At step 1911, the method includes indicating in the user interface a placement of a wall encompassing the water closet. This step provides users with a visual representation of where walls are located around the water closet within the design plan. The placement of walls is a critical aspect of the overall layout, influencing the available space and accessibility. The system indicates these walls in the user interface, allowing users to see how the water closet is enclosed and whether the placement of the walls meets compliance standards.

Step 1912 builds on the previous step by indicating in the user interface a placement and a shape of a wall encompassing the water closet and determining a width of a path to the water closet. This step not only shows the placement of walls but also their shape and how they define the path leading to the water closet. The system assesses whether the width of this path is sufficient for accessibility, particularly for users with mobility aids such as wheelchairs. If the path is too narrow, the system can recommend adjustments to widen it, thus enhancing accessibility.

At step 1913, the method involves determining a geopolitical locality and authority having jurisdiction over a situs of the building; and including in the set of conditions, requirements specified by a code adopted by the authority having jurisdiction over the situs of the building. This step provides that the compliance analysis is aligned with the specific building codes and regulations that apply to the geographical location of the building. Different regions may have different requirements, and the system adjusts its analysis accordingly, taking into account the codes enforced by the relevant authority. This step is critical for making sure that the design complies with local regulations and standards.

These steps collectively guide the process of evaluating and adjusting the design of water closet areas to meet specific regulatory requirements, with a focus on spatial relationships, accessibility, and compliance with local building codes. The interactive interface allows for real-time adjustments and feedback, making it a valuable tool for architects and designers.

At step 1914, the method includes determining a geopolitical locality and authority having jurisdiction over a situs of the building; and including in the set of conditions, requirements specified by a code adopted by the authority having jurisdiction over the situs of the building. This step is essential for tailoring the compliance analysis to the specific regulations enforced by the relevant local authorities. By identifying the geopolitical locality, the system can reference the correct building codes that apply to the building's location, so that the analysis is accurate and appropriate for the region.

At step 1915, the process involves generating a user interface comprising user interactive areas operative to change at least one of a length, a placement, and shape of a wall encompassing the water closet. This step allows users to interact with the design plan directly, enabling them to modify key parameters of the water closet's surrounding walls. The interactive interface offers a dynamic way to adjust the design in real-time, allowing users to see the impact of changes on compliance with the relevant building codes.

Step 1916 describes receiving into the user interface a command to cause the controller to change at least one of a length, a placement, and shape of a wall encompassing the water closet sufficiently to meet the requirements of the code adopted by the authority having jurisdiction. This step highlights the user's ability to input commands that will modify the design plan according to the necessary compliance requirements. The system processes these commands and adjusts the design to align with the applicable codes, so that the layout is both functional and compliant.

At step 1917, the method further refines this process by wherein the parameter modified comprises a shape of the polygon. This step focuses on the specific parameter that is being altered-namely, the shape of the polygon, which represents the walls enclosing the water closet. By modifying the shape, the system can address issues such as inadequate space or non-compliant dimensions, thereby optimizing the design to meet the required standards.

Step 1918 involves receiving an instruction via the first user interactive interface to modify a parameter of the line segment; modifying the parameter of the line segment based upon the instruction received via the first user interactive interface. This step allows users to adjust the parameters of line segments within the design, such as their length or orientation, directly through the interface. The system responds to these instructions by modifying the design in real-time, which helps users to make precise adjustments that affect the overall compliance of the water closet area.

At step 1919, the method includes wherein the parameter of the line segment comprises a length of the line segment and the method additionally comprises the step of modifying a distance of a wall to a water closet. This step is critical for fine-tuning the spatial relationships within the water closet area. By adjusting the length of line segments, the system can modify the distance between walls and the water closet, so that the space adheres to the necessary clearance requirements specified by the relevant codes.

At step 1920, the method involves utilizing simulation techniques (e.g., using a virtual person or wheelchair) in compliance analyses. This step focuses on the application of advanced simulation methods to evaluate and assess compliance with building codes. The use of simulation allows for a detailed analysis of various scenarios within the design plan, helping to identify potential issues before they arise in real-world construction. These simulations can include aspects such as spatial clearances, accessibility for individuals with disabilities, and the impact of modifications on overall compliance.

At step 1921, the process describes wherein the parameter of the line segment comprises a length of the line segment and the method additionally comprises the step of modifying a distance of a wall to a water closet. This step focuses on refining the spatial configuration within the water closet area by adjusting the length of line segments that represent walls. By modifying these lengths, the system can determine and adjust the distance between the walls and the water closet, so that the design meets the required clearance and compliance standards. The method also includes displaying in the first user interactive interface an action that may be taken to place a building in compliance with the building code designated by the authority having jurisdiction. This action provides users with clear guidance on how to bring the design into compliance, making the process more efficient and user-friendly.

Finally, at step 1922, the method further elaborates on displaying in the first user interactive interface an action that may be taken to place a building in compliance with the building code designated by the authority having jurisdiction. This step emphasizes the role of the user interface in providing actionable insights and recommendations for code compliance. Additionally, the method involves training an AI engine via a human identifying portions of the design plan to comprise a water closet. This step highlights the collaborative aspect of the system, where human input is used to train the AI engine, thereby improving its accuracy and effectiveness in identifying and analyzing water closet areas within design plans.

### Glossary

“Artificial Intelligence” as used herein means machine-based decision making and machine learning including but not limited to: supervised and unsupervised recognition of patterns, classification, and numerical regression. Supervised learning of patterns includes a human indicating that a pattern (such as a pattern of dots formed via the rasterization of a two-dimensional image) is representative of a line, polygon, shape, angle or other geometric form, or an architectural aspect, unsupervised learning can include a machine finding a pattern submitted for analysis. One or both may use mathematical optimization, formal logic, artificial neural networks, and methods based on one or more of: statistics, probability, linear regression, linear algebra, and/or matrix multiplication.

“AI Engine” as used herein an AI Engine (sometimes referred to as an AI model) refers to methods and apparatus for applying artificial intelligence and/or machine learning to a task performed by a controller. In some embodiments, a controller may be operative via executable software to act as an AI engine capable of recognizing aspects and/or tally aspects of a design plan that are relevant to generating an estimate for performing projects included in construction of a building or other activities related to construction of a building.

“Computer Aided Design,” sometimes referred to as “CAD,” as used herein shall mean the use of automation for the creation, modification, analysis, or optimization of a design plan or design plan file.

“Vector File” as used herein a vector file is a computer graphic that uses mathematical formulas to render its image. In some embodiments, a sharpness of a vector file will be agnostic to size within a range of sizes viewable on smart device and personal computer display screens.

Typically, a vector image includes segments with two points. The two points create a path. Paths can be straight or curved. Paths may be connected at connection points. Connected paths form more complex shapes. More points may be used to form longer paths or closed shapes. Each path, curve, or shape has its own formula, so they can be sized up or down and the formulas will maintain the crispness and sharp qualities of each path.

A vector file may include connected paths that may be viewed as graphics. The paths that make up the graphics may include geometric shapes or portions of geometric shapes, such as: circles, ellipsis, Bezier curves, squares, rectangles, polygons, and lines. More sophisticated designs may be created by joining and intersecting shapes and/or paths. Each shape may be treated as an individual object within the larger image. Vector graphics are scalable, such that they may be increased or decreased without significantly distorting the image.

The methods and apparatus of the present invention are presented herein generally, by way of example, to actions, processes, and deliverables important to industries such as the construction industry, by generating improved determination of compliance with specified codes, based on inputted design plans, floor plans or other construction related diagrams, however, design plans may include almost any artifact that may be converted to a pixel pattern.

Some specific embodiments of the present invention include input of a design plan (e.g., a blueprint, design plan floorplan or other two-dimensional artifact) so that it may be analyzed using artificial intelligence and used to generate a determination of compliance with specified conditions included in one or multiple building codes in a short time period. However, unless expressly indicated in an associated claim, the present invention is not limited to analysis of design plans for any particular industry. The examples provided herein are illustrative in nature and show that the present invention may use controllers and/or neural networks and artificial-intelligence (AI) techniques to identify aspects of a building described by a design plan and specify quantities for variables used to generate a bid or other proposal for completion of a project (or some subset of a project) represented by the design plan. For example, aspects of a building that are identified may include one or more of: walls or other boundaries; doorways; doors; plumbing; plumbing fixtures; hardware; fasteners; wall board; flooring; a level of complexity and other variables ascertainable via analysis of the design plan. AI analysis provides values for variables used in estimations involved in a project bidding process or related activity.

The present invention provides for systems of one or more computers that can be configured to perform particular operations or actions by virtue of having software, firmware, hardware, or a combination of them installed on the system that in operation causes or cause the system to perform the actions. One or more computer programs can be configured to perform artificial intelligence operations or actions by virtue of including instructions that, when executed by data processing apparatus, cause the apparatus to perform the actions.

### Conclusion

A number of embodiments of the present disclosure have been described. While this specification contains many specific implementation details, there should not be construed as limitations on the scope of any disclosures or of what may be claimed, but rather as descriptions of features specific to particular embodiments of the present disclosure. While embodiments of the present disclosure are described herein by way of example, using several illustrative drawings, those skilled in the art will recognize the present disclosure is not limited to the embodiments or drawings described. It should be understood that the drawings, and the detailed description thereto, are not intended to limit the present disclosure to the form disclosed, but to the contrary, the present disclosure is to cover all modification, equivalents and alternatives falling within the spirit and scope of embodiments of the present disclosure as defined by the appended claims.

The headings used herein are for organizational purposes only and are not meant to be used to limit the scope of the description or the claims. As used throughout this application, the word “may” be used in a permissive sense (i.e., meaning having the potential to), rather than the mandatory sense (i.e., meaning must). Similarly, the words “include,” “including,” and “includes” mean including but not limited to. To facilitate understanding, like reference numerals have been used, where possible, to designate like elements common to the figures.

The phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” means A alone, B alone, C alone, A and B together, A and C together, B and C together, or A, B and C together.

The term “a” or “an” entity refers to one or more of that entity. As such, the terms “a” (or “an”), “one or more” and “at least one” can be used interchangeably herein. It is also to be noted the terms “comprising,” “including,” and “having” can be used interchangeably.

Certain features that are described in this specification in the context of separate embodiments can also be implemented in combination in a single embodiment. Conversely, various features that are described in the context of a single embodiment can also be implemented in combination in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while method steps may be depicted in the drawings in a particular order, this should not be understood as requiring that such operations be performed in the particular order shown or in a sequential order, or that all illustrated operations be performed, to achieve desirable results.

Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described. Other embodiments are within the scope of the following claims. In some cases, the actions recited in the claims can be performed in a different order and still achieve desirable results. In addition, the processes depicted in the accompanying figures do not necessarily require the particular order show, or sequential order, to achieve desirable results. In certain implementations, multitasking and parallel processing may be advantageous. Nevertheless, it will be understood that various modifications may be made without departing from the spirit and scope of the claimed disclosure.

1.-41. (canceled)

42. An apparatus for analyzing water closet compliance with a relevant building code, the apparatus comprising:
a controller comprising a processor and a digital storage, the digital storage comprising executable software code, executable upon command to cause the processor to:
receive a design plan of at least a portion of a building;
represent a portion of the design plan as multiple dynamic components, wherein the multiple dynamic components comprise one or more of: a line, a polygon, a vector, a wall symbol, a door symbol, and a fixture symbol;
generate a first interactive user interface comprising at least some of the multiple dynamic components representing the portion of the design plan, each dynamic component including a parameter changeable via the first interactive user interface;
identify a water closet area as a part of the portion of the design plan, wherein the identification comprises recognizing one or more fixtures, including a water closet, and detecting a location and boundaries of the water closet area within the portion of the design plan based on recognizing the one or more fixtures;
ascertain at least one design parameter associated with one or both of:
the water closet area, and the one or more fixtures;
compare the ascertained at least one design parameter against a set of conditions relating to water closet compliance; and
indicate in the first interactive user interface whether the building is in compliance with the set of conditions relating to the water closet, or not in compliance with the set of conditions.

43. The apparatus of claim 42, wherein the processor is further configured to recognize a plurality of fixtures within the water closet area, the plurality of fixtures comprising at least one of: a toilet, a urinal, a hand wash basin, a shower, a bathtub, a grab bar, a soap dispenser, a mirror, a ventilation fixture, a toilet paper dispenser, a bidet, a water jet, and a drainage pipe.

44. The apparatus of claim 42, wherein the processor is further configured to determine a location and orientation of each fixture within the water closet area and to store such information in the digital storage.

45. The apparatus of claim 44, wherein the processor is further configured to determine a height at which each fixture is installed relative to a floor level and to compare the height to a minimum or maximum requirement specified by the relevant building code.

46. The apparatus of claim 45, wherein the processor is further configured to determine a distance of each fixture from an adjacent wall within the water closet area and to compare the distance to a predefined minimum clearance requirement specified by the relevant building code.

47. The apparatus of claim 44, wherein the processor is further configured to determine relative distances between each fixture and other fixtures within the water closet area and to analyze the relative distances for compliance with the relevant building code.

48. The apparatus of claim 44, wherein the processor is further configured to determine a length or a width of a pathway between the water closet area and an egress point or a dwelling space and to compare pathway dimensions to code requirements.

49. The apparatus of claim 42, wherein the processor is further configured to simulate a movement of a virtual person with disabilities within the water closet area to evaluate compliance with accessibility standards.

50. The apparatus of claim 49, wherein the simulation includes varying a size or type of a wheelchair used by the virtual person to evaluate the water closet area for compliance with the accessibility standards.

51. The apparatus of claim 42, wherein the processor is further configured to calculate a clearance distance around the water closet and to compare the clearance distance to a minimum requirement specified by the relevant building code.

52. The apparatus of claim 42, wherein the processor is further configured to receive into the first interactive user interface a command to modify the at least one design parameter involving a fixture within a set distance from the water closet, and to dynamically update the compliance analysis in response to the modification.

53. The apparatus of claim 52, wherein the modification of the at least one design parameter comprises setting a clearance distance to at least 60 inches wide and at least 56 inches long around the water closet.

54. The apparatus of claim 42, wherein the processor is further configured to determine a centerline of the water closet and to ascertain whether a lavatory is within 18 inches from the centerline of the water closet.

55. The apparatus of claim 54, wherein the processor is further configured to indicate in the first interactive user interface a placement and a shape of a wall encompassing the water closet and to determine a width of a path to the water closet.

56. The apparatus of claim 42, wherein the processor is further configured to determine a front clearance space available in front of the water closet, compare the front clearance space to a minimum clearance requirement specified by the relevant building code, and identify an obstruction within the front clearance space, providing an automated suggestion for repositioning a fixture.

57. The apparatus of claim 42, wherein the processor is further configured to determine a geopolitical locality and authority having jurisdiction over a situs of the building, and to include in the set of conditions, requirements specified by a code adopted by the authority having jurisdiction over the situs of the building.

58. The apparatus of claim 42, wherein the processor is further configured to generate a record of the compliance analysis and any modifications made by a user, and to store the record in a database associated with the controller.

59. The apparatus of claim 42, wherein the processor is further configured to generate automated suggestions for corrective actions in the first interactive user interface, the automated suggestions comprising at least one of: repositioning a grab bar, adjusting a height of a toilet, or modifying a width of a doorway.

60. The apparatus of claim 42, wherein the processor is further configured to generate a report summarizing a compliance status of each component in the water closet area, including detailed explanations for any deviations from code requirements, and to export the report in a selectable format.

61. The apparatus of claim 42, wherein the processor is further configured to integrate with a building information modeling (BIM) system, to receive design plans in a BIM-compatible format, and to update a BIM model with a compliance status and suggested modifications.
